(19) United States
(12) Patent Application Publication
(10) Pub. No.: US 2025/0113596 A1
(43) Pub. Date: Apr. 3, 2025

(54) MIXED COMPLEMENTARY FIELD EFFECT AND UNIPOLAR TRANSISTORS AND METHODS OF FORMING THE SAME

(71) Applicant: Taiwan Semiconductor Manufacturing Co., Ltd., Hsinchu (TW)

(72) Inventors: Jui-Chien Huang, Hsinchu (TW); Cheng-Yin Wang, Taipei (TW); Wei-Cheng Lin, Taichung (TW); Kao-Cheng Lin, Taipei (TW); Szuya Liao, Zhubei (TW)

(21) Appl. No.: 18/375,593

(22) Filed: Oct. 2, 2023

(51) Int. Cl. H01L 27/088; H01L 29/08; H01L 29/417; H01L 29/66

(52) U.S. Cl. CPC H10D 84/834; H10D 30/0241; H10D 30/6219; H10D 62/155; H10D 62/159; H10D 64/017

(57) ABSTRACT

Embodiments include mixed complementary field effect and unipolar transistors and methods of forming the same. In an embodiment, a structure includes: a first semiconductor nanostructure; a second semiconductor nanostructure; a first isolation structure interposed between the first semiconductor nanostructure and the second semiconductor nanostructure; a first source/drain region extending laterally from an end of the first semiconductor nanostructure, the first source/drain region having a first conductivity type; a second source/drain region extending laterally from an end of the second semiconductor nanostructure, the second source/drain region having the first conductivity type, the second source/drain region aligned vertically with the first source/drain region; and a first gate structure surrounding the first semiconductor nanostructure and the second semiconductor nanostructure.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional problems arise that should be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-1B illustrate an example of a complementary field-effect transistor (CFET) and a unipolar field-effect transistor (UFET) schematic in a three-dimensional view, in accordance with some embodiments.

FIGS. 2-18C are views of intermediate stages in the manufacturing of CFETs and UFETs, in accordance with some embodiments.

FIGS. 19-31C are views of intermediate stages in the manufacturing of CFETs and UFETS, in accordance with other embodiments.

FIGS. 32-38C are views of intermediate stages in the manufacturing of CFETs and UFETS, in accordance with yet other embodiments.

FIGS. 39A-54C are views of continued intermediate stages in the manufacturing of gate structures in CFETs and UFETs, in accordance with some embodiments.

FIGS. 55-59C are views of intermediate stages in the manufacturing of CFETs and UFETs, in accordance with some other embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

According to various embodiments, stacked FETs are formed. A stacked includes a lower nanostructure-FET and an upper nanostructure-FET. A CFET is a stacked FET where the upper nanostructure-FET and the lower nanostructure-FET have opposite conductivities. For example, the lower nanostructure-FET may be a pFET device, while the upper nanostructure-FET may be an nFET device (or vice versa). CFETs are useful for some device types which require complementary operation, such as an SRAM, however, typically some transistors are used which are not needed to be in a complementary configuration. In such cases, the upper nanostructure-FET or lower nanostructure-FET may be considered a dummy FET and may not be used. Rather than let these be abandoned, however, embodiments provide the ability to form unipolar FETs (UFETs) alongside CFET devices. A UFET is a stacked FET where both the upper nanostructure-FET and the lower nanostructure-FET have the same conductivity type. Thus, both the upper nanostructure-FET and the lower nanostructure-FET may be used. Having both UFETs and CFETs alongside each other results in greater chip density, driving down cost and providing better performance.

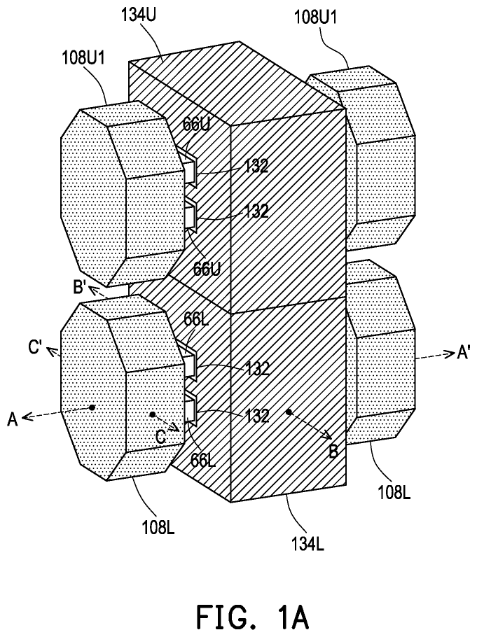

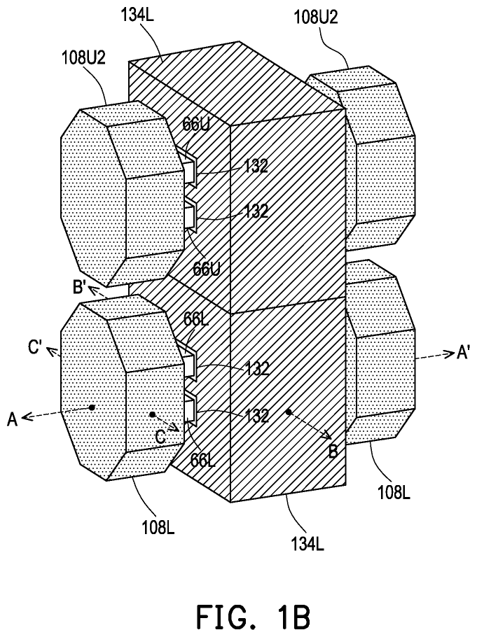

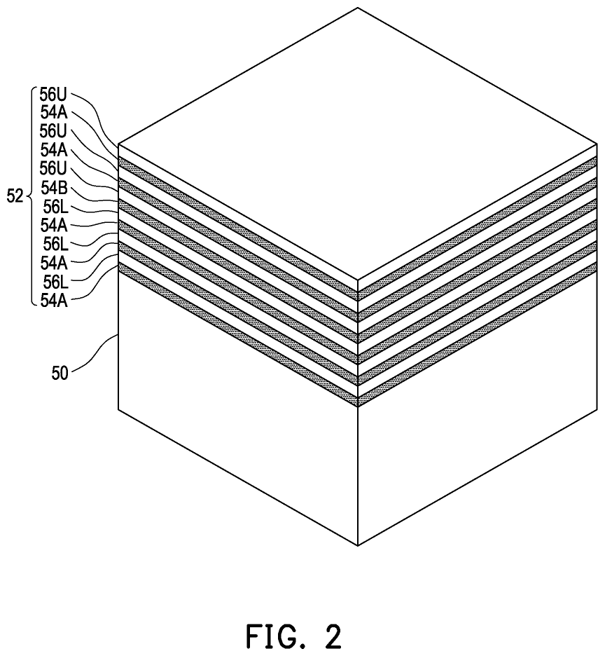

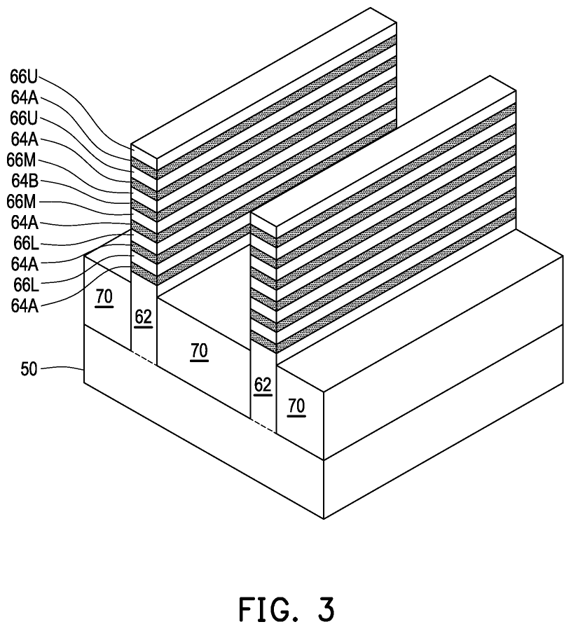

FIGS. 1A-1B illustrate an example of a UFET/CFET schematic, in accordance with some embodiments. FIGS. 1A-1B are three-dimensional views, where some features of the UFETs/CFETs are omitted for illustration clarity. A portion of a CFET, for example, is provided in FIG. 1A and a portion of a UFET, for example, is provided in FIG. 1B.

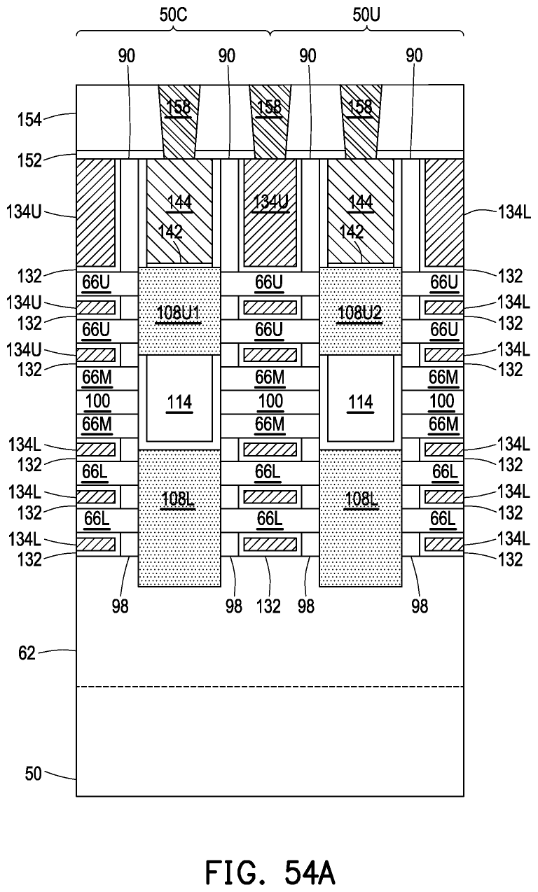

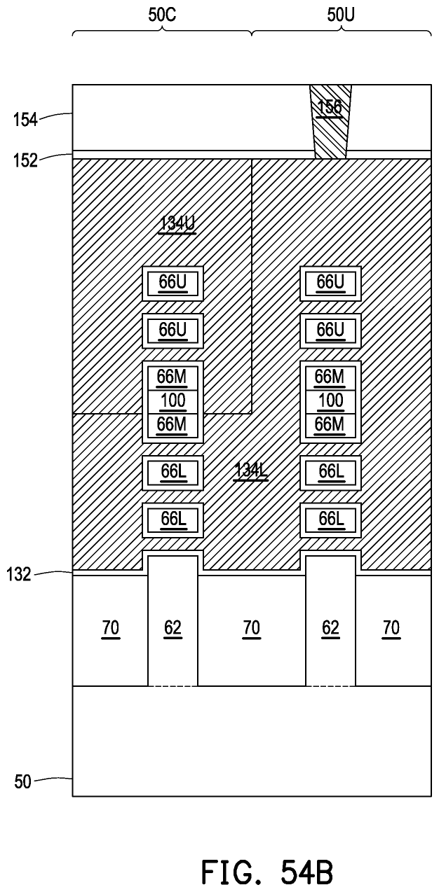

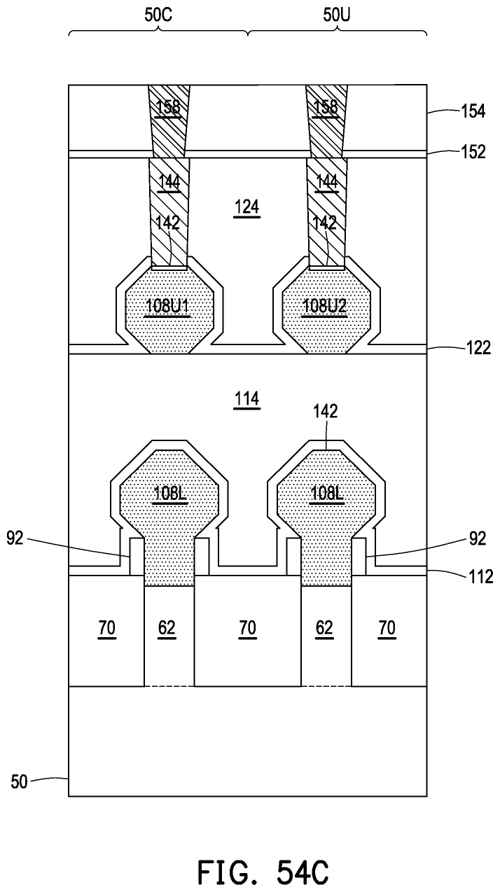

The UFETs/CFETs include multiple vertically stacked nanostructure-FETs (e.g., nanowire FETs, nanosheet FETs, multi bridge channel (MBC) FETs, nanoribbon FETs, gate-all-around (GAA) FETs, or the like). For example, a CFET (see FIG. 1A) may include a lower nanostructure-FET of a first device type (e.g., n-type/p-type) and an upper nanostructure-FET of a second device type (e.g., p-type/n-type) that is opposite the first device type. Specifically, the CFET (see FIG. 1A) may include a lower PMOS transistor and an upper NMOS transistor, or the CFET may include a lower NMOS transistor and an upper PMOS transistor. For example, a UFET (see FIG. 1B) may include a lower nanostructure-FET of a first device type (e.g., n-type/p-type) and an upper nanostructure-FET also of the first device type (e.g., n-type/p-type). Specifically, the UFET (see FIG. 1B) may include a lower PMOS transistor and an upper PMOS transistor, or the UFET may include a lower NMOS transistor and an upper NMOS transistor. Each of the nanostructure-FETs include semiconductor nanostructures 66 (including lower semiconductor nanostructures 66L and upper semiconductor nanostructures 66U), where the semiconductor nanostructures 66 act as channel regions for the nanostructure-FETs. The semiconductor nanostructures 66 may be nanosheets, nanowires, or the like. The lower semiconductor nanostructures 66L are for a lower nanostructure-FET and the upper semiconductor nanostructures 66U are for an upper nanostructure-FET. A channel isolation material (not explicitly illustrated in FIGS. 1A-1B, see FIGS. 54A-54C) may be used to separate and electrically isolate the upper semiconductor nanostructures 66U from the lower semiconductor nanostructures 66L.

Gate dielectrics 132 are along top surfaces, sidewalls, and bottom surfaces of the semiconductor nanostructures 66. Gate electrodes 134 (including a lower gate electrode 134L and an upper gate electrode 134U) are over the gate dielectrics 132 and around the semiconductor nanostructures 66. The gate electrodes 134 for the UFET include the lower gate electrode 134L in the upper position. Source/drain regions 108 (including lower epitaxial source/drain regions 108L and upper epitaxial source/drain regions 108U1 for the CFETs, see FIG. 1A, and lower epitaxial source/drain regions 108L and upper epitaxial source/drain regions 108U2 for the UFETs, see FIG. 1B) are disposed at opposing sides of the gate dielectrics 132 and the gate electrodes 134. Source/drain region(s) 108 may refer to a source or a drain, individually or collectively dependent upon the context. Isolation features may be formed to separate desired ones of the source/drain regions 108 and/or desired ones of the gate electrodes 134. For example, a lower gate electrode 134L may optionally be separated from an upper gate electrode 134U by an isolation layer (not separately illustrated). Alternatively, a lower gate electrode 134L may be coupled to an upper gate electrode 134U. Further, the upper epitaxial source/drain regions 108U may be separated from lower epitaxial source/drain regions 108L by one or more dielectric layers (not explicitly illustrated in FIGS. 1A-1B, see FIGS. 54A-54C). The isolation features between channel regions, gates, and source/drain regions allow for vertically stacked transistors, thereby improving device density. Because of the vertically stacked nature of CFETs, the schematic may also be referred to as stacked transistors or folding transistors.

FIGS. 1A-1B further illustrate reference cross-sections that are used in later figures. Cross-section A-A′ is parallel to a longitudinal axis of the semiconductor nanostructures 66 of a CFET and in a direction of, for example, a current flow between the source/drain regions 108 of the CFET. Cross-section B-B′ is perpendicular to cross-section A-A′ and along a longitudinal axis of a gate electrode 134 of a CFET. Cross-section C-C′ is parallel to cross-section B-B′ and extends through the source/drain regions 108 of the CFETs. Subsequent figures refer to these reference cross-sections for clarity.

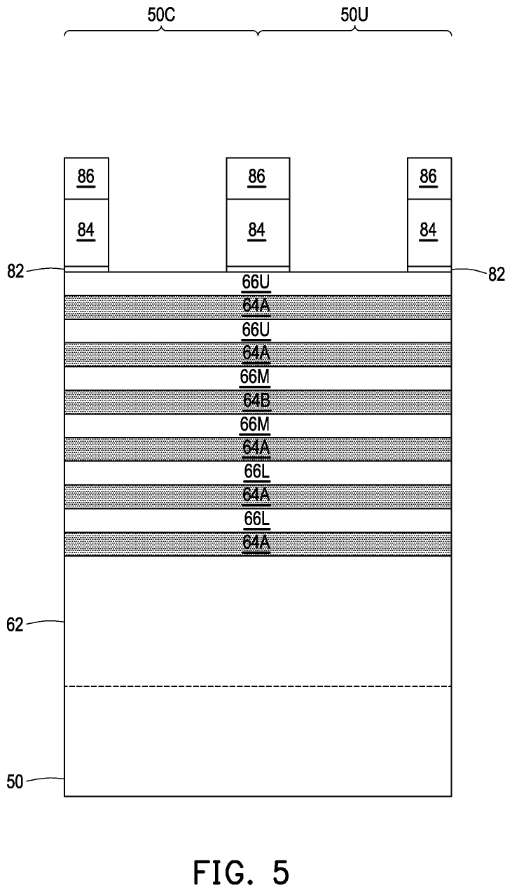

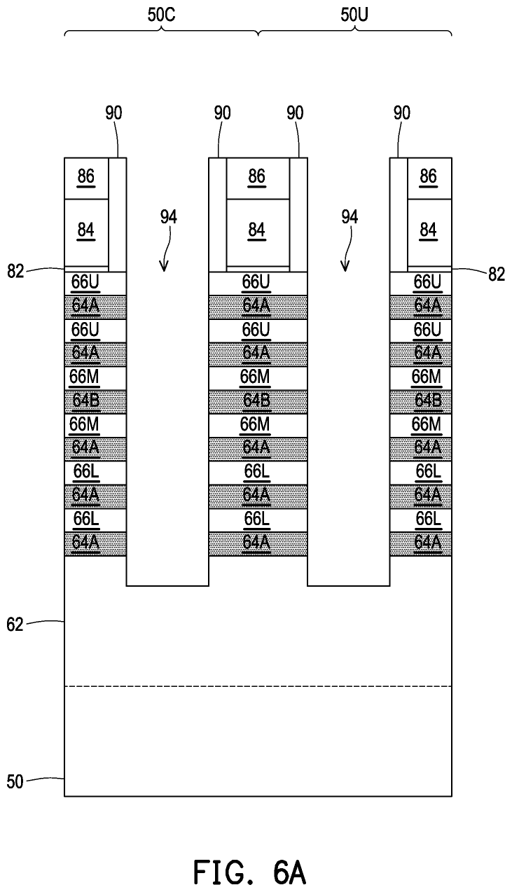

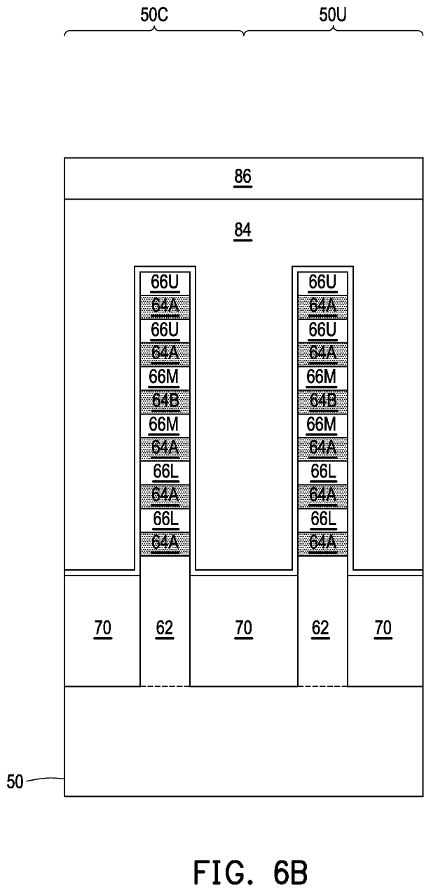

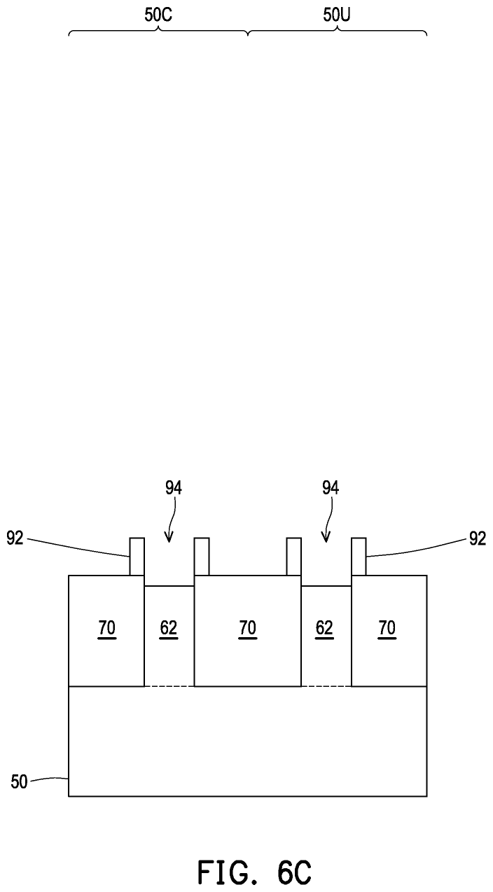

FIGS. 2-54C are views of intermediate stages in the manufacturing of CFETs and formation of metallization patterns to contacts of CFETs, in accordance with some embodiments. FIGS. 2, 3, and 4 are three-dimensional views showing a similar three-dimensional view as FIGS. 1A-1B. FIGS. 5, 6A, 7, 8, 9, 10A, 11, 12A, 13, 14, 15A, 16A, 17A, 18A, 19, 20, 21, 22, 23, 24, 25A, 26, 27A, 28A, 29A, 30A, 31A, 32, 33, 34, 35A, 36A, 37A, 38A, 39A, 40, 41A, 42A, 43A, 44A, 45A, 46A, 47A, 48A, 49A, 50A, 51A, 52A, 53A and 54A illustrate cross-sectional views along a similar cross-section as reference cross-section A-A′ in FIGS. 1A-1B. FIGS. 6B, 10B, 12B, 15B, 16B, 17B, 18B, 25B, 27B, 28B, 29B, 30B, 31B, 35B, 36B, 37B, 38B, 39B, 41B, 42B, 43B, 44B, 45B, 46B, 47B, 48B, 49B, 50B, 51B, 52B, 53B and 54B illustrate cross-sectional views along a similar cross-section as reference cross-section B-B′ in FIGS. 1A-1B. FIGS. 6C, 10C, 12C, 15C, 16C, 17C, 18C, 25C, 27C, 28C, 29C, 30C, 31C, 35C, 36C, 37C, 38C, 39C, 41C, 42C, 43C, 44C, 45C, 46C, 47C, 48C, 49C, 50C, 51C, 52C, 53C and 54C illustrate cross-sectional views along a similar cross-section as reference cross-section C-C′ in FIGS. 1A-1B.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate core, typically a silicon or glass substrate. Other substrates, such as a multi-layered or gradient substrate may also be used. In some embodiments, the semiconductor material of the substrate 50 may include silicon; germanium; a compound semiconductor including carbon-doped silicon, gallium arsenide, gallium phosphide, indium phosphide, indium arsenide, and/or indium antimonide; an alloy semiconductor including silicon-germanium, gallium arsenide phosphide, aluminum indium arsenide, aluminum gallium arsenide, gallium indium arsenide, gallium indium phosphide, and/or gallium indium arsenide phosphide; or combinations thereof. For example, the substrate 50 may be a multi-layered substrate that includes a layer of a semiconductor material formed on a silicon-germanium layer, where the silicon-germanium layer is provided on a substrate core, typically a silicon or glass substrate.

A multi-layer stack 52 is formed over the substrate 50. The multi-layer stack 52 includes alternating dummy layers 54 (including first dummy layers 54A and a second dummy layer 54B) and semiconductor layers 56 (including lower semiconductor layers 56L and upper semiconductor layers 56U). The lower semiconductor layers 56L and a subset of the first dummy layers 54A are disposed below the second dummy layer 54B. The upper semiconductor layers 56U and another subset of the first dummy layers 54A are disposed above the second dummy layer 54B. As subsequently described in greater detail, the dummy layers 54 will be removed and the semiconductor layers 56 will be patterned to form channel regions of CFETs/UFETs. Specifically, the lower semiconductor layers 56L will be patterned to form channel regions of the lower nanostructure-FETs of the CFETs/UFETs, and the upper semiconductor layers 56U will be patterned to form channel regions of the upper nanostructure-FETs of the CFETs/UFETs.

The multi-layer stack 52 is illustrated as including a specific number of the dummy layers 54 and a specific number of the semiconductor layers 56. It should be appreciated that the multi-layer stack 52 may include any number of the dummy layers 54 and the semiconductor layers 56. Each layer of the multi-layer stack 52 may be grown by a process such as vapor phase epitaxy (VPE) or molecular beam epitaxy (MBE), deposited by a process such as chemical vapor deposition (CVD) or atomic layer deposition (ALD), or the like.

The first dummy layers 54A are formed of a first semiconductor material, and the second dummy layer 54B is formed of a second semiconductor material. The first and second semiconductor materials may be selected from the candidate semiconductor materials of the substrate 50. The semiconductor materials of the first dummy layers 54A and the second dummy layer 54B will be subsequently described in greater detail. The first and second semiconductor materials have a high etching selectivity to one another. As such, the material of the second dummy layer 54B may be removed at a faster rate than the material of the first dummy layers 54A in subsequent processing.

The semiconductor layers 56 (including the lower semiconductor layers 56L and upper semiconductor layers 56U) are formed of one or more semiconductor material(s). The semiconductor material(s) may be selected from the candidate semiconductor materials of the substrate 50. The lower semiconductor layers 56L and the upper semiconductor layers 56U may be formed of the same semiconductor material, or may be formed of different semiconductor materials. In some embodiments, the lower semiconductor layers 56L and the upper semiconductor layers 56U are both be formed of a semiconductor material suitable for p-type devices and n-type devices, such as silicon. In some embodiments, the lower semiconductor layers 56L are formed of a semiconductor material suitable for p-type devices, such as germanium or silicon-germanium, and the upper semiconductor layers 56U are formed of a semiconductor material suitable for n-type devices, such as silicon or carbon-doped silicon. The semiconductor material(s) of the semiconductor layers 56 will be subsequently described in greater detail. The semiconductor material(s) of the semiconductor layers 56 have a high etching selectivity to the semiconductor materials of the dummy layers 54. As such, the materials of the dummy layers 54 may be removed at a faster rate than the material of the semiconductor layers 56 in subsequent processing.

Some layers of the multi-layer stack 52 may be thicker than other layers of the multi-layer stack 52. The thickness of the second dummy layer 54B may be different (e.g., greater or less) than the thickness of each of the first dummy layers 54A. Additionally, the thickness of each of the semiconductor layers 56 may be different (e.g., greater or less) than the thickness(es) of each of the dummy layers 54.

In some embodiments, the first dummy layers 54A are formed of silicon-germanium (Ge percent between 20% and 30%), the second dummy layer 54B is formed of high germanium concentration silicon-germanium (Ge percent between 40% and 60%), and the semiconductor layers 56 are formed of silicon. The silicon of the semiconductor layers 56 may be undoped or lightly doped at this step of processing, with such impurities as appropriate for each layer, such as n-type impurities for upper semiconductor layers 56U and p-type impurities for lower semiconductor layers 56L, or vice versa. The n-type impurities may be phosphorus, arsenic, antimony, or the like. The p-type impurities may be boron, boron fluoride, indium, or the like. Utilizing high concentration germanium silicon-germanium for the second dummy layer 54B allows it to have a high etching selectivity to the first dummy layers 54A and the semiconductor layers 56. For example, the second dummy layer 54B may be at least partially replaced with an isolation structure. As part of the replacement process, the second dummy layer 54B may be removed with an etchant that is selective to the germanium enriched second dummy layer 54B. Accordingly, the second dummy layer 54B may be removed at a faster rate than the first dummy layers 54A and the semiconductor layers 56.

In FIG. 3, fins 62 are formed in the substrate 50. Additionally, nanostructures 64, 66 (including first dummy nanostructures 64A, second dummy nanostructures 64B, lower semiconductor nanostructures 66L, middle semiconductor nanostructures 66M, and upper semiconductor nanostructures 66U) are formed in the multi-layer stack 52. In some embodiments, the nanostructures 64, 66 and the fins 62 may be formed in the multi-layer stack 52 and the substrate 50, respectively, by etching trenches in the multi-layer stack 52 and the substrate 50. The etching may be any acceptable etch process, such as a reactive ion etch (RIE), neutral beam etch (NBE), the like, or a combination thereof. The etching may be anisotropic. Forming the nanostructures 64, 66 by etching the multi-layer stack 52 may define the first dummy nanostructures 64A from the first dummy layers 54A, the second dummy nanostructures 64B from the second dummy layer 54B, the lower semiconductor nanostructures 66L from some of the lower semiconductor layers 56L, the upper semiconductor nanostructures 66U from some of the upper semiconductor layers 56U, and the middle semiconductor nanostructures 66M from some of the lower semiconductor layers 56L and some of the upper semiconductor layers 56U. The first dummy nanostructures 64A and the second dummy nanostructures 64B may further be collectively referred to as the dummy nanostructures 64. The lower semiconductor nanostructures 66L and the upper semiconductor nanostructures 66U may further be collectively referred to as the semiconductor nanostructures 66.

As subsequently described in greater detail, various one of the nanostructures 64, 66 will be removed to form channel regions of CFETs/UFETs. Specifically, the lower semiconductor nanostructures 66L will act as channel regions for lower nanostructure-FETs of the CFETs/UFETs. Additionally, the upper semiconductor nanostructures 66U will act as channel regions for upper nanostructure-FETs of the CFETs/UFETs.

The middle semiconductor nanostructures 66M are the semiconductor nanostructures 66 that are directly above/below (e.g., in contact with) the second dummy nanostructures 64B. Depending on the heights of subsequently formed source/drain regions, the middle semiconductor nanostructures 66M may or may not adjoin any source/drain regions and may or may not act as functional channel regions for the CFETs/UFETs. The second dummy nanostructures 64B will be subsequently replaced with isolation structures. The isolation structures and the middle semiconductor nanostructures 66M may define boundaries of the lower nanostructure-FETs and the upper nanostructure-FETs.

The fins 62 and the nanostructures 64, 66 may be patterned by any suitable method. For example, the fins 62 and the nanostructures 64, 66 may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins 62 and the nanostructures 64, 66. In some embodiments, a mask (or other layer) may remain on the nanostructures 64, 66.

Although each of the fins 62 and the nanostructures 64, 66 are illustrated as having a constant width throughout, in other embodiments, the fins 62 and/or the nanostructures 64, 66 may have tapered sidewalls such that a width of each of the fins 62 and/or the nanostructures 64, 66 continuously increases in a direction towards the substrate 50. In such embodiments, each of the nanostructures 64, 66 may have a different width and be trapezoidal in shape.

Further, isolation regions 70 are formed over the substrate 50 and between adjacent fins 62. The isolation regions 70 may include a liner and a fill material over the liner. Each of the liner and the fill material may include a dielectric material such as an oxide (e.g., silicon oxide), a nitride (e.g., silicon nitride), the like, or a combination thereof. The formation of the isolation regions 70 may include depositing the dielectric material(s), and performing a planarization process such as a chemical mechanical polish (CMP) process, a mechanical polishing process, or the like to remove excess portions of the dielectric material(s), such as portions over the nanostructures 64, 66. The deposition processes may include ALD, high-density plasma chemical vapor deposition (HDP-CVD), flowable chemical vapor deposition (FCVD), the like, or a combination thereof. In some embodiments, the isolation regions 70 include silicon oxide formed by an FCVD process, followed by an anneal process. Then, the dielectric material(s) are recessed to define the isolation regions 70. The dielectric material(s) maybe recessed such that upper portions of the fins 62 and the nanostructures 64, 66 extend higher than the isolation regions 70.

The previously described process is just one example of how the fins 62 and the nanostructures 64, 66 may be formed. In some embodiments, the fins 62 and/or the nanostructures 64, 66 may be formed using a mask and an epitaxial growth process. For example, a dielectric layer can be formed over a top surface of the substrate 50, and trenches can be etched through the dielectric layer to expose the underlying substrate 50. Epitaxial structures can be epitaxially grown in the trenches, and the dielectric layer can be recessed such that the epitaxial structures protrude from the dielectric layer to form the fins 62 and/or the nanostructures 64, 66. The epitaxial structures may comprise the previously described alternating semiconductor materials. In some embodiments where epitaxial structures are epitaxially grown, the epitaxially grown materials may be in situ doped during growth, which may obviate prior and/or subsequent implantations, although in situ and implantation doping may be used together.

Further, appropriate wells (not separately illustrated) may be formed in the semiconductor nanostructures 66. For example, an n-type impurity implant and/or a p-type impurity implant may be performed, or the semiconductor materials may be in situ doped during growth. The n-type impurities may be any of those referenced above or the like at a concentration in a range from 10¹⁷ atoms/cm³ to 10¹⁹ atoms/cm³. The p-type impurities may be any of those referenced above or the like at a concentration in a range from 10¹⁷ atoms/cm³ to 10¹⁹ atoms/cm³. The wells in the lower semiconductor nanostructures 66L have a conductivity type opposite from a conductivity type of lower source/drain regions that will be subsequently formed adjacent the lower semiconductor nanostructures 66L. The wells in the upper semiconductor nanostructures 66U have a conductivity type opposite from a conductivity type of upper source/drain regions that will be subsequently formed adjacent the upper semiconductor nanostructures 66U.

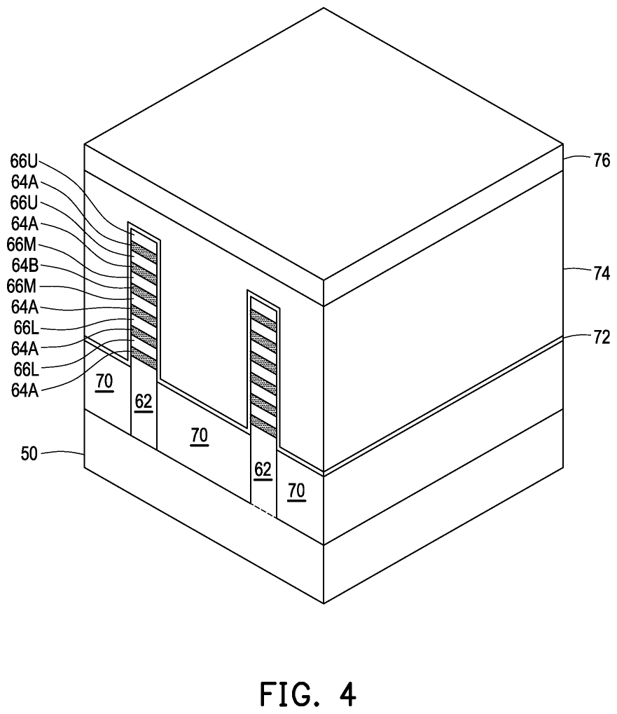

In FIG. 4, a dummy dielectric layer 72 is formed on the fins 62 and/or the nanostructures 64, 66. The dummy dielectric layer 72 may be, for example, silicon oxide, silicon nitride, a combination thereof, or the like, and may be deposited or thermally grown according to acceptable techniques. A dummy gate layer 74 is formed over the dummy dielectric layer 72, and a mask layer 76 is formed over the dummy gate layer 74. The dummy gate layer 74 may be deposited over the dummy dielectric layer 72 and then planarized, such as by a CMP. The mask layer 76 may be deposited over the dummy gate layer 74. The dummy gate layer 74 may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 74 may be deposited by physical vapor deposition (PVD), CVD, sputter deposition, or other techniques for depositing the selected material. The dummy gate layer 74 may be formed of other materials that have a high etching selectivity to insulating materials. The mask layer 76 may include, for example, silicon nitride, silicon oxynitride, or the like. In the illustrated embodiment, the dummy dielectric layer 72 covers the isolation regions 70, such that the dummy dielectric layer 72 extends between the dummy gate layer 74 and the isolation regions 70. In another embodiment, the dummy dielectric layer 72 covers only the fins 62 and/or the nanostructures 64, 66.

In FIG. 5, the mask layer 76 may be patterned using acceptable photolithography and etching techniques to form masks 86. The pattern of the masks 86 then may be transferred to the dummy gate layer 74 and to the dummy dielectric layer 72 to form dummy gates 84 and dummy dielectrics 82, respectively. The dummy gates 84 cover respective channel regions of the nanostructures 64, 66. The pattern of the masks 86 may be used to physically separate each of the dummy gates 84 from adjacent dummy gates 84. The dummy gates 84 may also have a lengthwise direction substantially perpendicular to the lengthwise direction of respective fins 62. The masks 86 can optionally be removed after patterning, such as by any acceptable etching technique.

In FIGS. 6A-6C, gate spacers 90 are formed over the nanostructures 64, 66 and on exposed sidewalls of the masks 86 (if present), the dummy gates 84, and the dummy dielectrics 82. The gate spacers 90 may be formed by conformally forming one or more dielectric material(s) and subsequently etching the dielectric material(s). Acceptable dielectric materials may include silicon oxide, silicon nitride, silicon oxynitride, silicon oxycarbonitride, or the like, which may be formed by a deposition process such as chemical vapor deposition (CVD), atomic layer deposition (ALD), or the like. Other dielectric materials formed by any acceptable process may be used. Any acceptable etch process, such as a dry etch, may be performed to pattern the dielectric material(s). The etching may be anisotropic. The dielectric material(s), when etched, have portions left on the sidewalls of the dummy gates 84 (thus forming the gate spacers 90). As will be subsequently described in greater detail, the dielectric material(s), when etched, may also have portions left on the sidewalls of the fins 62 and/or the nanostructures 64, 66 (thus forming fin spacers 92, see FIG. 6C).

Further, implants for lightly doped source/drain (LDD) regions (not separately illustrated) may be performed. The LDD implants may be performed before the gate spacers 90 are formed. Appropriate type impurities may be implanted into the nanostructures 64, 66 to a desired depth. The LDD regions may have a same conductivity type as a conductivity type of source/drain regions that will be subsequently formed adjacent the semiconductor nanostructures 66. Additionally, the LDD regions in the lower semiconductor nanostructures 66L may have a conductivity type opposite from a conductivity type of the LDD regions in the upper semiconductor nanostructures 66U. In some embodiments, the lower semiconductor nanostructures 66L have p-type LDD regions and the upper semiconductor nanostructures 66U have n-type LDD regions. In some embodiments, the lower semiconductor nanostructures 66L have n-type LDD regions and the upper semiconductor nanostructures 66U have p-type LDD regions. The n-type impurities may be the any of the n-type impurities previously discussed, and the p-type impurities may be the any of the p-type impurities previously discussed. The lightly doped source/drain regions may have a concentration of impurities in a range from 10¹⁷ atoms/cm³ to 10²⁰ atoms/cm³. An anneal may be used to repair implant damage and to activate the implanted impurities. In some embodiments, the grown materials of the nanostructures 64, 66 may be in situ doped during growth, which may obviate the implantations, although in situ and implantation doping may be used together.

It is noted that the previous disclosure generally describes a process of forming spacers and LDD regions. Other processes and sequences may be used. For example, fewer or additional spacers may be utilized, different sequence of steps may be utilized, additional spacers may be formed and removed, and/or the like.

Source/drain recesses 94 are formed in the fins 62, the nanostructures 64, 66, and the substrate 50. Epitaxial source/drain regions will be subsequently formed in the source/drain recesses 94. The source/drain recesses 94 may extend through the nanostructures 64, 66 and into the substrate 50. The fins 62 may be etched such that bottom surfaces of the source/drain recesses 94 are disposed above, below, or level with the top surfaces of the isolation regions 70. In the illustrated example, the top surfaces of the isolation regions 70 are above the bottom surfaces of the source/drain recesses 94. The source/drain recesses 94 may be formed by etching the fins 62, the nanostructures 64, 66, and the substrate 50 using anisotropic etching processes, such as RIE, NBE, or the like. The gate spacers 90 and the dummy gates 84 mask portions of the fins 62, the nanostructures 64, 66, and the substrate 50 during the etching processes used to form the source/drain recesses 94. A single etch process or multiple etch processes may be used to etch each layer of the nanostructures 64, 66 and/or the fins 62. Timed etch processes may be used to stop the etching of the source/drain recesses 94 after the source/drain recesses 94 reach a desired depth.

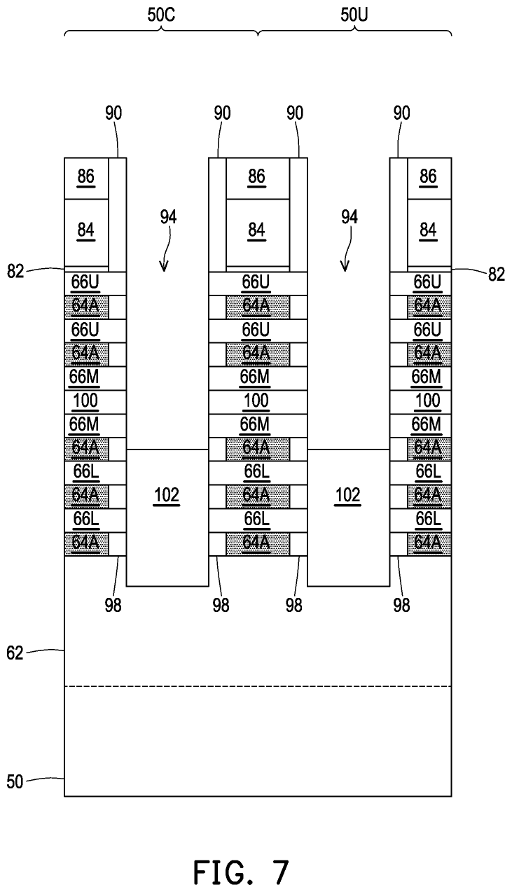

In FIG. 7, inner spacers 98 are formed on the sidewalls of the remaining portions of the first dummy nanostructures 64A. As subsequently described in greater detail, source/drain regions will be subsequently formed in the source/drain recesses 94, and the first dummy nanostructures 64A will be replaced with corresponding gate structures. The inner spacers 98 act as isolation features between the subsequently formed source/drain regions and the subsequently formed gate structures. Further, the inner spacers 98 may be used to prevent damage to the subsequently formed source/drain regions by subsequent etch processes, such as etch processes used to form gate structures. Additionally, the second dummy nanostructures 64B are replaced with isolation structures 100, which are between the middle semiconductor nanostructures 66M. The isolation structures 100 and the middle semiconductor nanostructures 66M will define the boundaries of the lower nanostructure-FETs and the upper nanostructure-FETs. The isolation structures 100 may have similar dimensions as the second dummy nanostructures 64B they replaced.

As an example to form the inner spacers 98 and the isolation structures 100, the sidewalls of the first dummy nanostructures 64A exposed by the source/drain recesses 94 are recessed to form sidewall recesses. Additionally, the second dummy nanostructures 64B are removed to form openings between the middle semiconductor nanostructures 66M, e.g., between the lower semiconductor nanostructures 66L (collectively) and the upper semiconductor nanostructures 66U (collectively). The sidewall recesses may be formed by recessing the sidewalls of the first dummy nanostructures 64A with any acceptable etch process. The etching is selective to the first dummy nanostructures 64A (e.g., selectively etches the material of the first dummy nanostructures 64A at a faster rate than the material of the semiconductor nanostructures 66). The etching may be isotropic. Although sidewalls of the first dummy nanostructures 64A are illustrated as being straight after the etching, the sidewalls may be concave or convex. The openings between the middle semiconductor nanostructures 66M may be formed by removing the second dummy nanostructures 64B with any acceptable etch process. The etching is selective to the second dummy nanostructures 64B (e.g., selectively etches the material of the second dummy nanostructures 64B at a faster rate than the material of the semiconductor nanostructures 66). The etching may be isotropic. The dummy gates 84 may adhere to and support the upper semiconductor nanostructures 66U so that the upper semiconductor nanostructures 66U do not collapse after the formation of the openings between the middle semiconductor nanostructures 66M. The middle semiconductor nanostructures 66M are exposed by the openings. In some embodiments, the etching process thins the middle semiconductor nanostructures 66M. Accordingly, the thickness of the middle semiconductor nanostructures 66M may be different (e.g., less than) the thickness of the lower semiconductor nanostructures 66L and the thickness of the upper semiconductor nanostructures 66U.

In some embodiments, the same etching process is used to recess the sidewalls of the first dummy nanostructures 64A and to remove the second dummy nanostructures 64B. For example, the second dummy nanostructures 64B may be completely removed without completely removing the first dummy nanostructures 64A, and the first dummy nanostructures 64A may be recessed without significantly recessing the semiconductor nanostructures 66. The etching process has selectivity among the materials of the first dummy nanostructures 64A, the second dummy nanostructures 64B, and the semiconductor nanostructures 66. Specifically, the etching process selectively etches the material of the first dummy nanostructures 64A at a faster rate than the material of the semiconductor nanostructures 66, and also selectively etches the material of the second dummy nanostructures 64B at a faster rate than the selectively etches the material of the first dummy nanostructures 64A. Thus, the etch rate of the first dummy nanostructures 64A is less than the etch rate of the second dummy nanostructures 64B and is greater than the etch rate of the semiconductor nanostructures 66.

An insulating material is then conformally formed in the source/drain recesses 94, the sidewall recesses, and the openings between the middle semiconductor nanostructures 66M, and subsequently etched. The insulating material may be a carbon-containing dielectric material, such as silicon oxycarbonitride, silicon oxycarbide, silicon oxynitride, or the like. Other low-dielectric constant (low-k) materials having a k-value less than about 3.5 may be utilized. The insulating material may be formed by a deposition process, such as ALD, CVD, or the like. The etching of the insulating material may be anisotropic. For example, the etch process may be a dry etch such as a RIE, a NBE, or the like. The insulating material, when etched, has portions remaining in the sidewall recesses (thus forming the inner spacers 98) and has portions remaining in the openings between the middle semiconductor nanostructures 66M (thus forming the isolation structures 100).

Although outer sidewalls of the inner spacers 98 and the isolation structures 100 are illustrated as being flush with sidewalls of the semiconductor nanostructures 66, the outer sidewalls of the inner spacers 98 and the isolation structures 100 may extend beyond or be recessed from sidewalls of the semiconductor nanostructures 66. Thus, the inner spacers 98 and the isolation structures 100 may partially fill, completely fill, or overfill the sidewall recesses and the openings between the middle semiconductor nanostructures 66M, respectively. Moreover, although the sidewalls of the inner spacers 98 and the isolation structures 100 are illustrated as being straight, those sidewalls may be concave or convex.

Further, a sacrificial dielectric 102 is formed in the lower portions of the source/drain recesses 94. The sacrificial dielectric 102 is disposed on the sidewalls of the lower semiconductor nanostructures 66L and some of the inner spacers 98. The sacrificial dielectric 102 may be formed by conformally forming a dielectric material and subsequently recessing the dielectric material. Acceptable dielectric materials may include silicon oxide, silicon nitride, silicon oxynitride, silicon oxycarbonitride, combinations thereof, or the like, which may be formed by a deposition process such as chemical vapor deposition (CVD), atomic layer deposition (ALD), or the like. Other dielectric materials formed by any acceptable process may be used. The dielectric material of the sacrificial dielectric 102 has a high etching selectivity to the dielectric material of the isolation structures 100. Any acceptable etch process, such as a dry etch, a wet etch, the like, or a combination thereof, may be performed to recess the dielectric material. The etching may be isotropic, such as an etch-back process that removes the dielectric material from the upper portions of the source/drain recesses 94. The dielectric material, when etched, has portions left in the lower portions of the source/drain recesses 94 (thus forming the sacrificial dielectric 102).

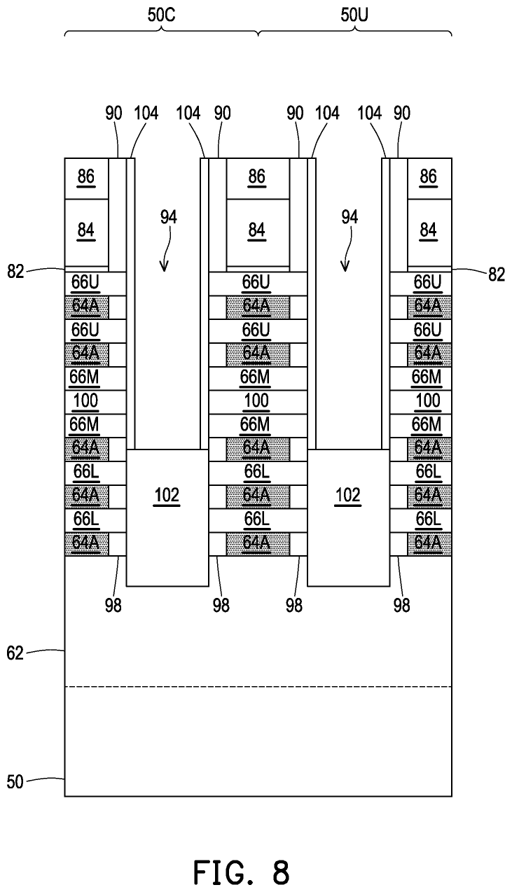

In FIG. 8, dummy spacers 104 are formed over the sacrificial dielectric 102 and in the upper portions of the source/drain recesses 94. The dummy spacers 104 are disposed on the sidewalls of the upper semiconductor nanostructures 66U, the middle semiconductor nanostructures 66M, the gate spacers 90, the isolation structures 100, and some of the inner spacers 98. The dummy spacers 104 may be formed by conformally forming a dielectric material and subsequently etching the dielectric material. Acceptable dielectric materials may include silicon oxide, silicon nitride, silicon oxynitride, silicon oxycarbonitride, aluminum oxide, combinations thereof, or the like, which may be formed by a deposition process such as chemical vapor deposition (CVD), atomic layer deposition (ALD), or the like. Other dielectric materials formed by any acceptable process may be used. The dielectric material of the dummy spacers 104 has a high etching selectivity to the dielectric materials of the sacrificial dielectric 102 and the isolation regions 70. In some embodiments, the dummy spacers and/or the sacrificial dielectric 102 each comprise silicon oxycarbonitride, and an amount of carbon in each of the dummy spacers 104 and the sacrificial dielectric 102 may be selected to tune an etching selectivity of the dummy spacers 104 and/or the sacrificial dielectric 102. Further, although the dummy spacers 104 are each illustrated as a single layer having a uniform material composition, the dummy spacers 104 may have a multilayer structure including different layers of different dielectric materials. Any acceptable etch process, such as a dry etch, may be performed to pattern the dielectric material. The etching may be anisotropic. The etching is selective to the dummy spacers 104 (e.g., selectively etches the material of the dummy spacers 104 at a faster rate than the material of the sacrificial dielectric 102). The dielectric material, when etched, has portions left on the sidewalls of the upper semiconductor nanostructures 66U, the middle semiconductor nanostructures 66M, the gate spacers 90, the isolation structures 100, and some of the inner spacers 98 (thus forming the dummy spacers 104).

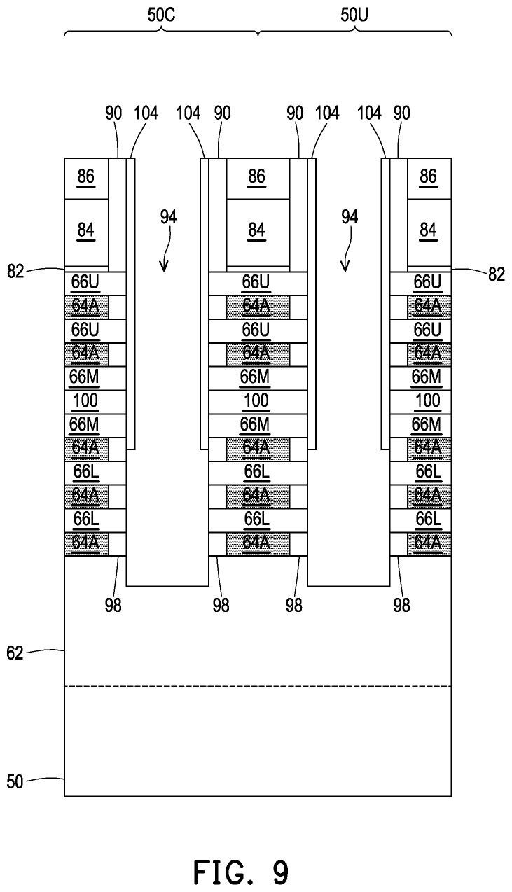

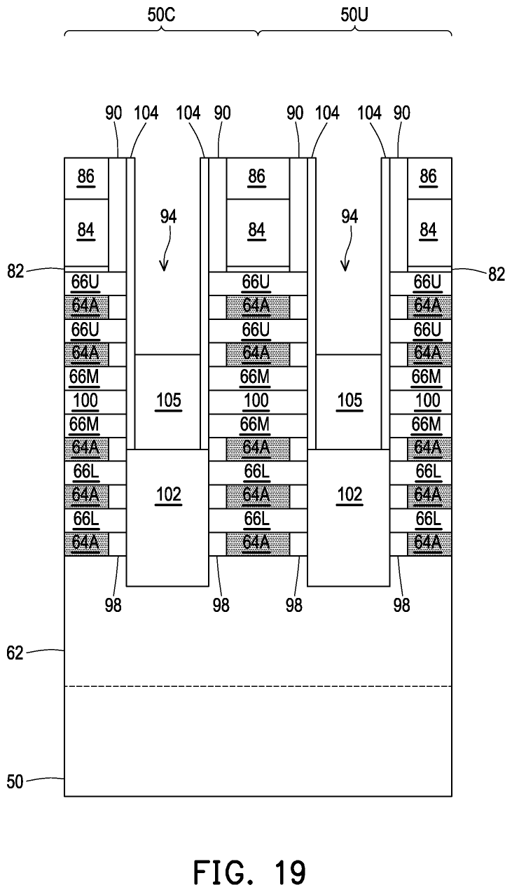

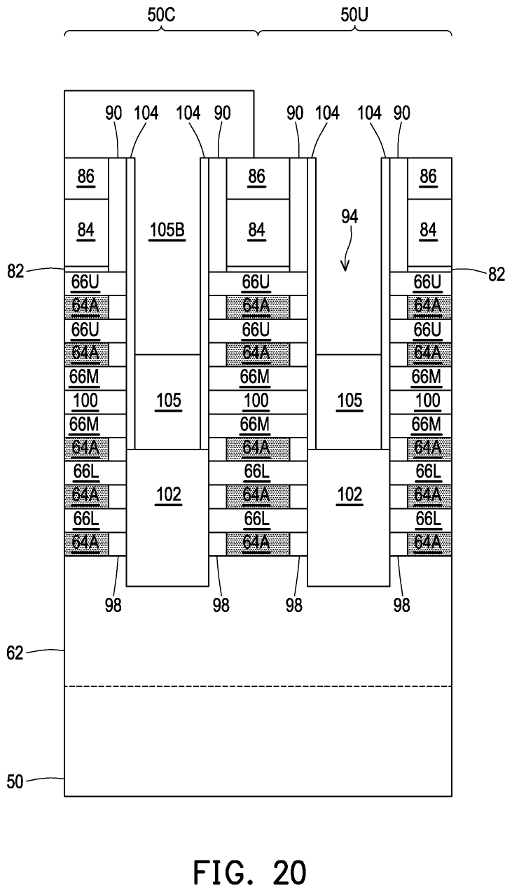

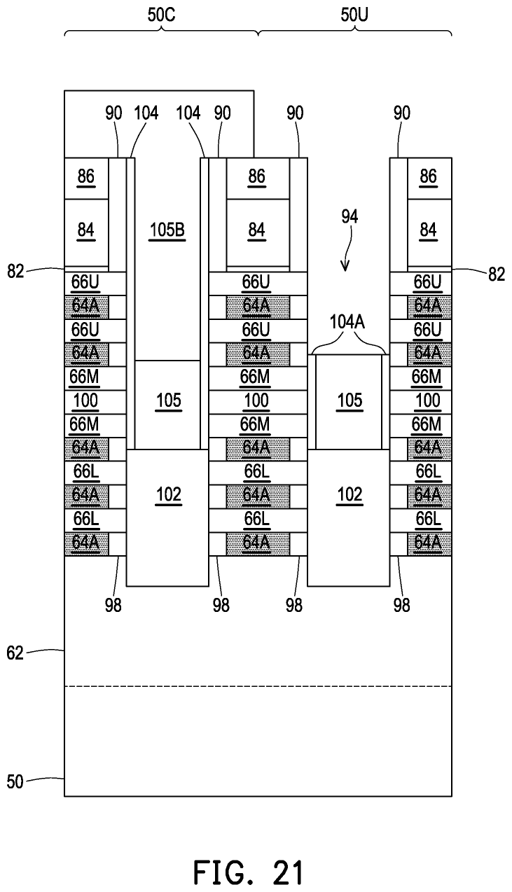

FIGS. 9-18C illustrate one process for forming source/drain regions for a CFET alongside source/drain regions for a UFET, in accordance with some embodiments. FIGS. 19-31C illustrate another process for forming source/drain regions for a CFET alongside source/drain regions for a UFET, in accordance with other embodiments. FIGS. 32-38C illustrate another process for forming source/drain regions for a CFET alongside source/drain regions for a UFET, in accordance with other embodiments. The source/drain regions for CFETs are formed in a CFET region 50C, while the source/drain regions for UFETs are formed in a UFET region 50U. Although not separately illustrated, the CFET region 50C may be separated from the UFET region 50U. Any components may be disposed between the CFET region 50C and the UFET region 50U.

In FIG. 9, the sacrificial dielectric 102 is removed from the source/drain recesses 94. Any acceptable etch process, such as a dry etch, a wet etch, the like, or a combination thereof, may be performed to remove the sacrificial dielectric 102. The etching may be isotropic. The etching is selective to the sacrificial dielectric 102 (e.g., selectively etches the material of the sacrificial dielectric 102 at a faster rate than the materials of the nanostructures 64, 66, the inner spacers 98, and the dummy spacers 104). Removing the sacrificial dielectric 102 exposes the sidewalls of the lower semiconductor nanostructures 66L, while the sidewalls of the upper semiconductor nanostructures 66U remain covered by the dummy spacers 104. In the illustrated embodiments, the dummy spacers 104 also cover sidewalls of the middle semiconductor nanostructures 66M. In other embodiments, depending on a desired height of subsequently formed source/drain regions, a height of the sacrificial dielectric 102 may be adjust so that the dummy spacers 104 may expose sidewalls of one or more of the middle semiconductor nanostructures 66M.

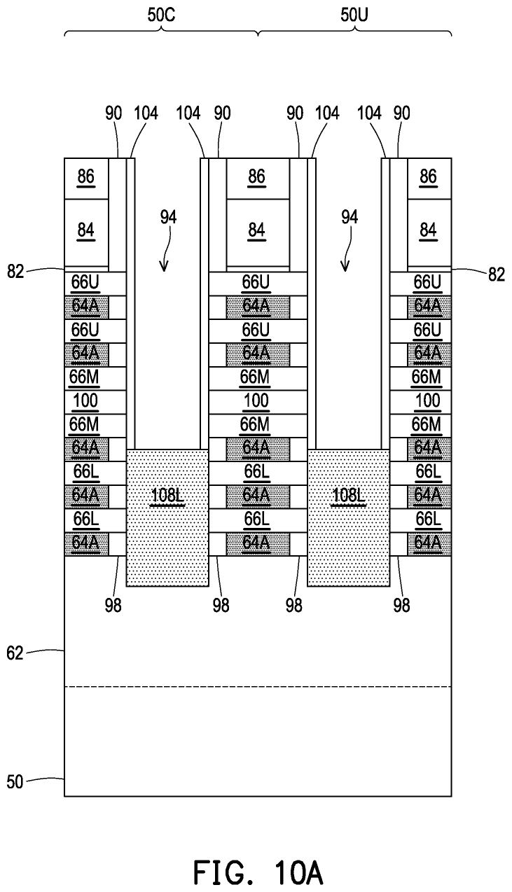

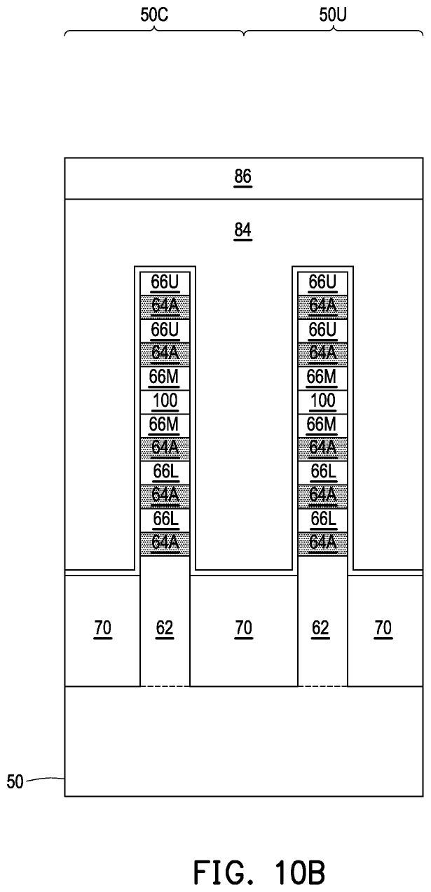

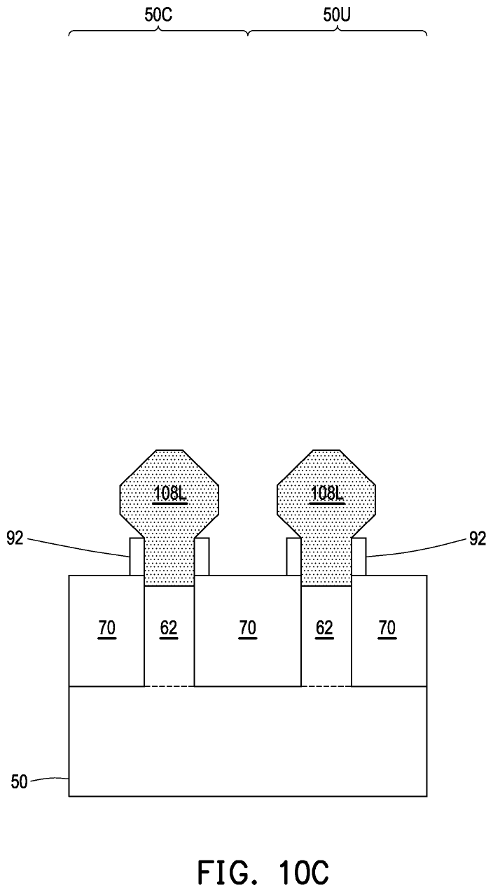

In FIGS. 10A-10C, lower epitaxial source/drain regions 108L are formed in the lower portions of the source/drain recesses 94. The lower epitaxial source/drain regions 108L only partially fill the source/drain recesses 94, such that the lower epitaxial source/drain regions 108L are in contact with the lower semiconductor nanostructures 66L and are not in contact with the upper semiconductor nanostructures 66U. The dummy spacers 104 may mask the middle semiconductor nanostructures 66M and/or the upper semiconductor nanostructures 66U, so that the lower epitaxial source/drain regions 108L only partially fill the source/drain recesses 94 and are not formed on the upper semiconductor nanostructures 66U.

In some embodiments, the lower epitaxial source/drain regions 108L exert stress in the respective channel regions of the lower semiconductor nanostructures 66L, thereby improving performance. The lower epitaxial source/drain regions 108L are formed in the source/drain recesses 94 such that each stack of the lower semiconductor nanostructures 66L is disposed between respective neighboring pairs of the lower epitaxial source/drain regions 108L. In some embodiments, the inner spacers 98 are used to separate the lower epitaxial source/drain regions 108L from the first dummy nanostructures 64A by an appropriate lateral distance so that the lower epitaxial source/drain regions 108L do not short out with subsequently formed gates of the resulting devices.

The lower epitaxial source/drain regions 108L are epitaxially grown in the lower portions of the source/drain recesses 94. The lower epitaxial source/drain regions 108L have a conductivity type that is suitable for the device type of the lower nanostructure-FETs. In some embodiments, the lower epitaxial source/drain regions 108L are n-type source/drain regions. For example, if the lower semiconductor nanostructures 66L are silicon, the lower epitaxial source/drain regions 108L may include materials exerting a tensile strain on the lower semiconductor nanostructures 66L, such as silicon, carbon-doped silicon, phosphorous-doped silicon, silicon phosphide, silicon arsenide, or the like. In some embodiments, the lower epitaxial source/drain regions 108L are p-type source/drain regions. For example, if the lower semiconductor nanostructures 66L are silicon-germanium, the lower epitaxial source/drain regions 108L may include materials exerting a compressive strain on the lower semiconductor nanostructures 66L, such as silicon-germanium, boron-doped silicon-germanium, boron-doped silicon, germanium, germanium tin, or the like. The lower epitaxial source/drain regions 108L may have surfaces raised from respective upper surfaces of the lower semiconductor nanostructures 66L and may have facets.

The lower epitaxial source/drain regions 108L may be implanted with dopants to form source/drain regions, similar to the process previously discussed for forming lightly-doped source/drain regions, followed by an anneal. The source/drain regions may have an impurity concentration in the range of 10¹⁹ atoms/cm³ and 10²¹ atoms/cm³. The n-type and/or p-type impurities for source/drain regions may be any of the impurities previously discussed. In some embodiments, the lower epitaxial source/drain regions 108L are in situ doped during growth.

As a result of the epitaxy processes used to form the lower epitaxial source/drain regions 108L, upper surfaces of the lower epitaxial source/drain regions 108L have facets which expand laterally outward beyond sidewalls of the nanostructures 64, 66. In some embodiments, adjacent lower epitaxial source/drain regions 108L remain separated after the epitaxy process is completed as illustrated by FIG. 10C. In other embodiments, these facets cause adjacent lower epitaxial source/drain regions 108L of a same nanostructure-FET to merge (not separately illustrated). In the illustrated embodiments, the fin spacers 92 are formed on a top surface of the isolation regions 70, thereby blocking the epitaxial growth. In some other embodiments, the fin spacers 92 may cover portions of the sidewalls of the nanostructures 64, 66 and/or the fins 62, further blocking the epitaxial growth. In another embodiment, the spacer etch used to form the gate spacers 90 is adjusted to not form the fin spacers 92, so as to allow the lower epitaxial source/drain regions 108L to extend to the surface of the isolation regions 70.

The lower epitaxial source/drain regions 108L may comprise one or more semiconductor material layers. For example, the lower epitaxial source/drain regions 108L may comprise a first semiconductor material layer, a second semiconductor material layer, and a third semiconductor material layer. Any number of semiconductor material layers may be used for the lower epitaxial source/drain regions 108L. Each of the first semiconductor material layer, the second semiconductor material layer, and the third semiconductor material layer may be formed of different semiconductor materials and may be doped to different dopant concentrations. In some embodiments, the first semiconductor material layer may have a dopant concentration less than the second semiconductor material layer and greater than the third semiconductor material layer. In embodiments in which the lower epitaxial source/drain regions 108L comprise three semiconductor material layers, the first semiconductor material layer may be grown on a lower semiconductor layer (e.g., the lower semiconductor nanostructures 66L), the second semiconductor material layer may be grown on the first semiconductor material layer, and the third semiconductor material layer may be grown on the second semiconductor material layer.

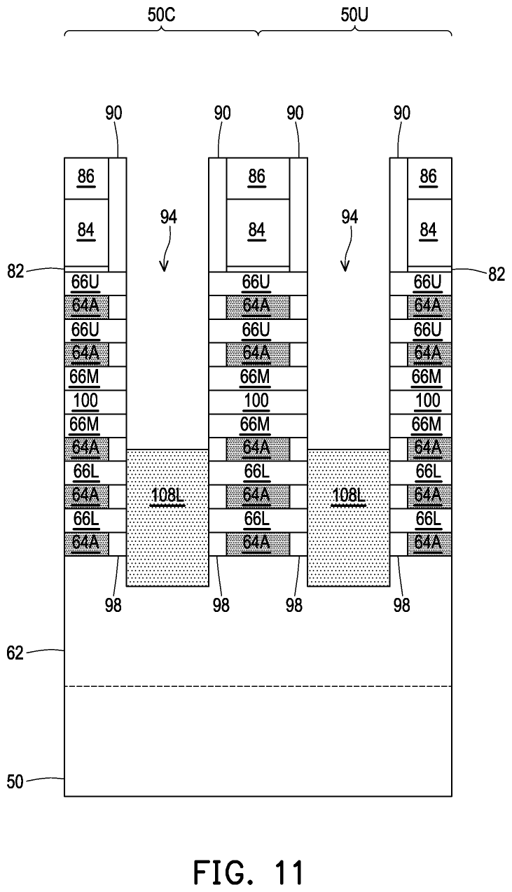

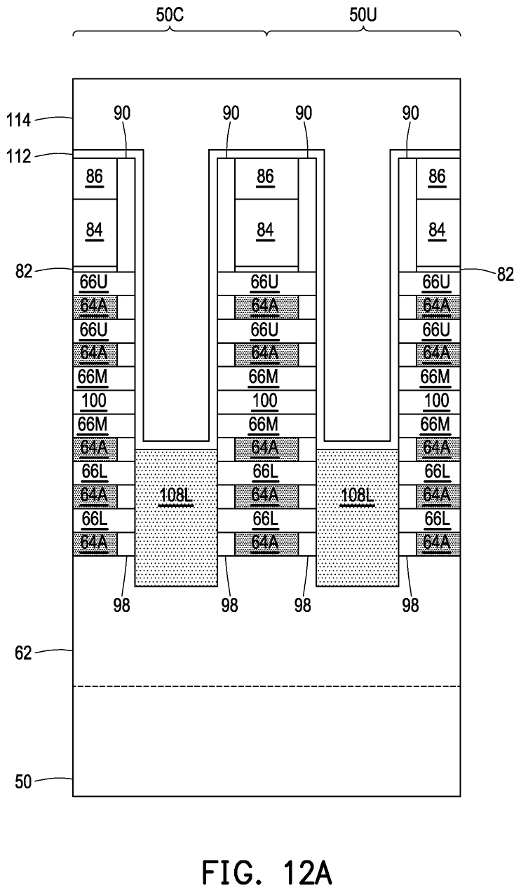

In FIG. 11, the dummy spacers 104 are removed from the source/drain recesses 94. Any acceptable etch process, such as a dry etch, a wet etch, the like, or a combination thereof, may be performed to remove the dummy spacers 104. The etching may be isotropic. The etching is selective to the dummy spacers 104 (e.g., selectively etches the material of the dummy spacers 104 at a faster rate than the materials of the lower epitaxial source/drain regions 108L and the isolation structures 100). Removing the dummy spacers 104 exposes the sidewalls of the upper semiconductor nanostructures 66U.

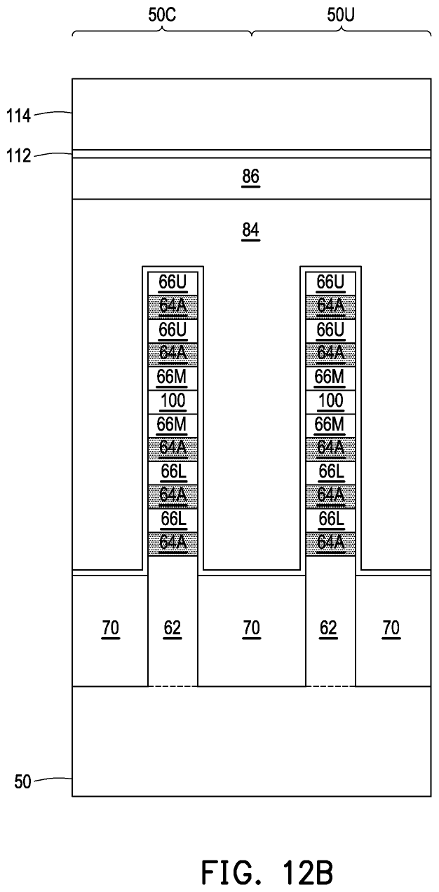

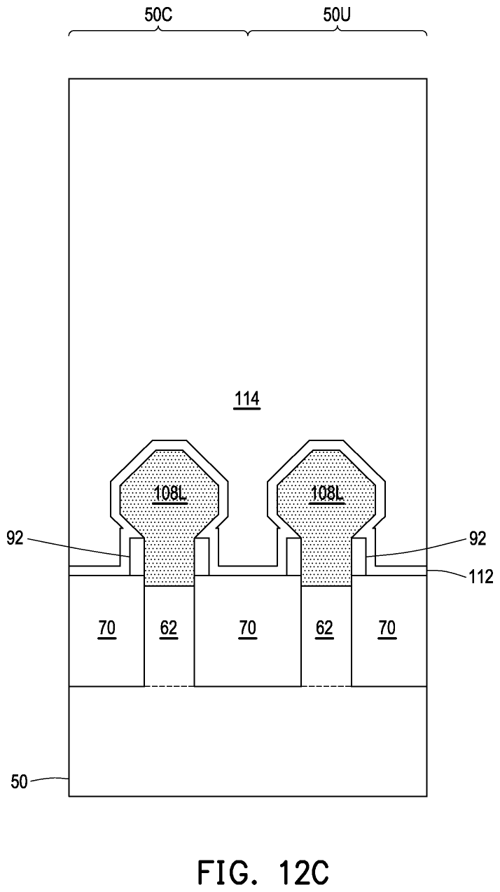

In FIGS. 12A-12C, a first inter-layer dielectric (ILD) 114 is formed over the lower epitaxial source/drain regions 108L, the gate spacers 90, the masks 86 (if present) or the dummy gates 84, and the isolation regions 70. The first ILD 114 may be formed of a dielectric material, which may be deposited by any suitable method, such as CVD, plasma-enhanced chemical vapor deposition (PECVD), or FCVD. Dielectric materials may include phospho-silicate glass (PSG), boro-silicate glass (BSG), boron-doped phospho-silicate glass (BPSG), undoped silicate glass (USG), or the like. Other dielectric materials formed by any acceptable process may be used.

In some embodiments, a first contact etch stop layer (CESL) 112 is formed between the first ILD 114 and the lower epitaxial source/drain regions 108L, the gate spacers 90, the masks 86 (if present) or the dummy gates 84, and the isolation regions 70. The first CESL 112 may be formed of a dielectric material having a high etching selectivity to the dielectric material of the first ILD 114, such as silicon nitride, silicon oxide, silicon oxynitride, or the like, which may be formed by any suitable deposition process, such as CVD, ALD, or the like.

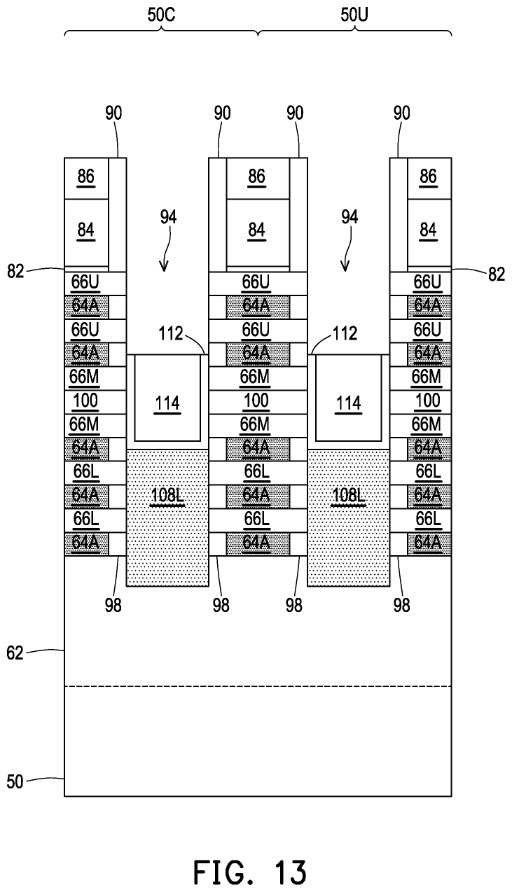

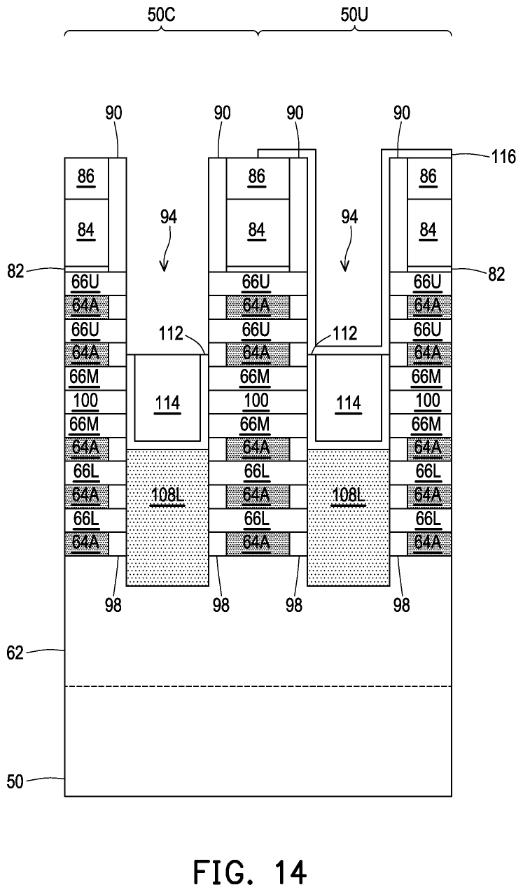

In FIG. 13, the first ILD 114 and the first CESL 112 are recessed such that they are removed from the upper portions of the source/drain recesses 94. After the recessing, the first ILD 114 only partially fills the source/drain recesses 94, such that the sidewalls of the upper semiconductor nanostructures 66U are exposed. The first ILD 114 and the first CESL 112 may be recessed using an etching process. The etching exposes the sidewalls of the upper semiconductor nanostructures 66U. In some embodiments, the first ILD 114 is etched using the first CESL 112 as an etch stop layer, and the first CESL 112 is then etched using the first ILD 114 as an etching mask.

In FIG. 14, a blocking liner 116 is formed over regions of the device which UFETs are to be formed and the regions of the device which CFETs are to be formed remain exposed. The blocking liner 116 may be formed by conformally forming a dielectric material and subsequently etching the dielectric material to remove the portion of the dielectric material in the CFET region 50C. Acceptable dielectric materials may include silicon oxide, silicon nitride, silicon oxynitride, silicon oxycarbonitride, aluminum oxide, combinations thereof, or the like, which may be formed by a deposition process such as chemical vapor deposition (CVD), atomic layer deposition (ALD), or the like. Other dielectric materials formed by any acceptable process may be used. After deposition of the dielectric material of the blocking liner 116, the dielectric material may be patterned by forming a photomask over the UFET region 50U, developing the photomask to expose the dielectric material in the CFET region 50C, and then etching the dielectric material to remove the dielectric material in the CFET region 50C, thereby forming the blocking liner 116 in the UFET region 50U. The photomask may then be removed for example by an ashing technique. The blocking liner 116 may have an etch selectivity similar to the dummy spacers 104, discussed above.

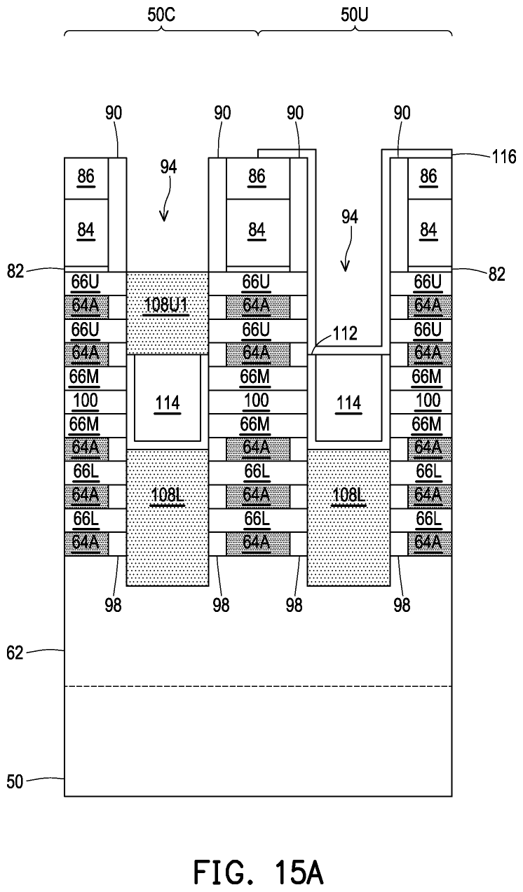

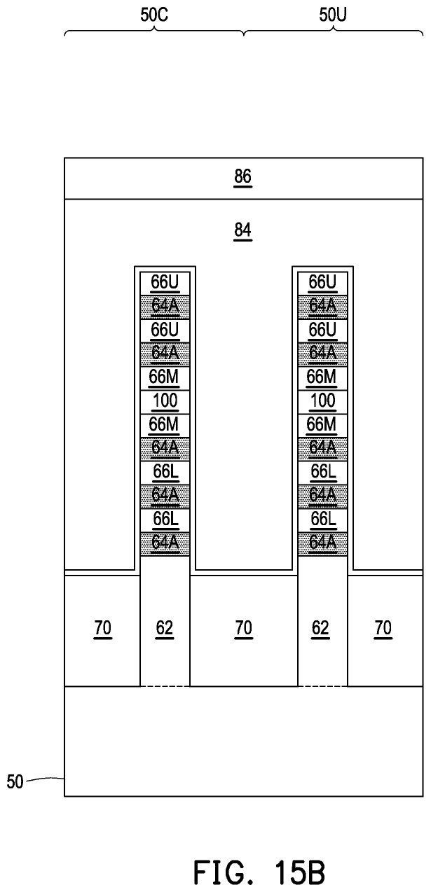

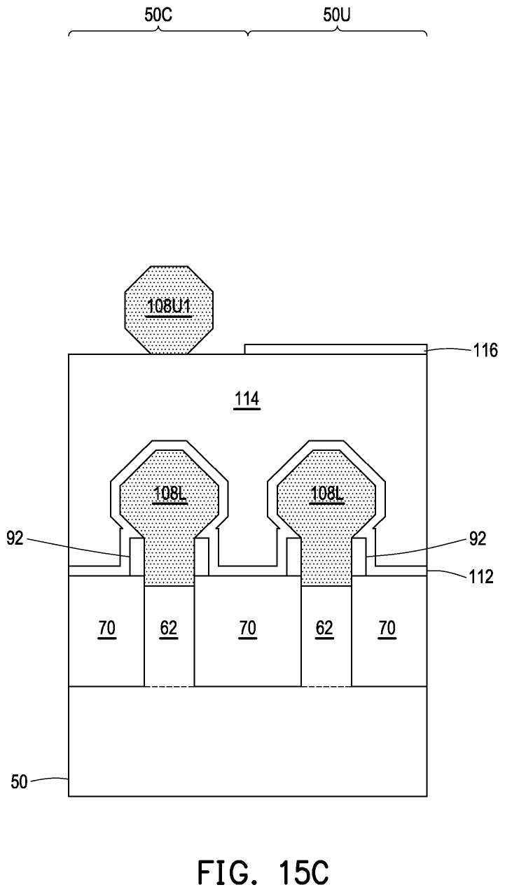

In FIGS. 15A-15C, upper epitaxial source/drain regions 108U1 are formed in the upper portions of the source/drain recesses 94 in the CFET region 50C. The blocking liner 116, on the other hand, prevents growth from occurring in the UFET region 50U. The upper epitaxial source/drain regions 108U1 only partially fill the source/drain recesses 94, such that the upper epitaxial source/drain regions 108U1 are in contact with the upper semiconductor nanostructures 66U and are not in contact with the lower semiconductor nanostructures 66L. The first ILD 114 may provide isolation between the upper epitaxial source/drain regions 108U1 and the lower epitaxial source/drain regions 108L.

In some embodiments, the upper epitaxial source/drain regions 108U1 exert stress in the respective channel regions of the upper semiconductor nanostructures 66U, thereby improving performance. The upper epitaxial source/drain regions 108U1 are formed in the source/drain recesses 94 such that each stack of the upper semiconductor nanostructures 66U is disposed between respective neighboring pairs of the upper epitaxial source/drain regions 108U1. In some embodiments, the inner spacers 98 are used to separate the upper epitaxial source/drain regions 108U1 from the first dummy nanostructures 64A by an appropriate lateral distance so that the upper epitaxial source/drain regions 108U1 do not short out with subsequently formed gates of the resulting devices.

The upper epitaxial source/drain regions 108U1 are epitaxially grown in the upper portions of the source/drain recesses 94 in the CFET region 50C. For example, the upper epitaxial source/drain regions 108U1 may be grown laterally from exposed sidewalls of the upper semiconductor nanostructures 66U. As the upper epitaxial source/drain regions 108U1 grow in the source/drain recesses 94, facets may form and adjoining growth may merge together to form the upper epitaxial source/drain regions 108U1. The upper epitaxial source/drain regions 108U1 have a conductivity type that is suitable for the device type of the upper nanostructure-FETs. The conductivity type of the upper epitaxial source/drain regions 108U1 may be opposite the conductivity type of the lower epitaxial source/drain regions 108L. Put another way, the upper epitaxial source/drain regions 108U1 may be oppositely doped from the lower epitaxial source/drain regions 108L. In some embodiments, the upper epitaxial source/drain regions 108U1 are n-type source/drain regions. For example, if the upper semiconductor nanostructures 66U are silicon, the upper epitaxial source/drain regions 108U1 may include materials exerting a tensile strain on the upper semiconductor nanostructures 66U, such as silicon, carbon-doped silicon, phosphorous-doped silicon, silicon phosphide, silicon arsenide, or the like. In some embodiments, the upper epitaxial source/drain regions 108U1 are p-type source/drain regions. For example, if the upper semiconductor nanostructures 66U are silicon-germanium, the upper epitaxial source/drain regions 108U1 may include materials exerting a compressive strain on the upper semiconductor nanostructures 66U, such as silicon-germanium, boron-doped silicon-germanium, boron-doped silicon, germanium, germanium tin, or the like. The upper epitaxial source/drain regions 108U1 may have surfaces raised from respective upper surfaces of the upper semiconductor nanostructures 66U and may have facets.

The upper epitaxial source/drain regions 108U1 may be implanted with dopants to form source/drain regions, similar to the process previously discussed for forming lightly-doped source/drain regions, followed by an anneal. The anneal may be performed after deposition of the upper epitaxial source/drain regions 108U2, discussed below, in some embodiments. The source/drain regions may have an impurity concentration in the range of 10¹⁹ atoms/cm³ and 10²¹ atoms/cm³. The n-type and/or p-type impurities for source/drain regions may be any of the impurities previously discussed. In some embodiments, the upper epitaxial source/drain regions 108U1 are in situ doped during growth. In the illustrated embodiments, the upper epitaxial source/drain regions 108U1 extend to the surface of the first ILD 114.

As a result of the epitaxy processes used to form the upper epitaxial source/drain regions 108U1, upper surfaces of the upper epitaxial source/drain regions 108U1 have facets which expand laterally outward beyond sidewalls of the nanostructures 64, 66. In some embodiments, adjacent upper epitaxial source/drain regions 108U1 remain separated after the epitaxy process is completed as illustrated by FIG. 15C. In other embodiments, these facets cause adjacent upper epitaxial source/drain regions 108U1 of a same nanostructure-FET to merge (not separately illustrated), for example with adjacent upper epitaxial source/drain regions 108U1 (not separately illustrated).

The upper epitaxial source/drain regions 108U1 may comprise one or more semiconductor material layers. For example, the upper epitaxial source/drain regions 108U1 may comprise a first semiconductor material layer, a second semiconductor material layer, and a third semiconductor material layer. Any number of semiconductor material layers may be used for the upper epitaxial source/drain regions 108U1. Each of the first semiconductor material layer, the second semiconductor material layer, and the third semiconductor material layer may be formed of different semiconductor materials and may be doped to different dopant concentrations. In some embodiments, the first semiconductor material layer may have a dopant concentration less than the second semiconductor material layer and greater than the third semiconductor material layer. In embodiments in which the upper epitaxial source/drain regions 108U1 comprise three semiconductor material layers, the first semiconductor material layer may be grown over the first ILD 114, the second semiconductor material layer may be grown on the first semiconductor material layer, and the third semiconductor material layer may be grown on the second semiconductor material layer.

The source/drain recesses 94 in the CFET region 50C thus contain the upper epitaxial source/drain regions 108U1, the first ILD 114, and the lower epitaxial source/drain regions 108L. The first ILD 114 is between the upper epitaxial source/drain regions 108U1 and the lower epitaxial source/drain regions 108L. The lower epitaxial source/drain regions 108L are for lower nanostructure-FETs of the CFETs, and the upper epitaxial source/drain regions 108U1 are for upper nanostructure-FETs of the CFETs. The first ILD 114 thus acts as isolation regions to prevent shorting of the lower and upper nanostructure-FETs. The source/drain recesses 94 in the UFET region 50U contain the first ILD 114 and the lower epitaxial source/drain regions 108L. Upper epitaxial source/drain regions 108U2 are described for the UFET region 50U below.

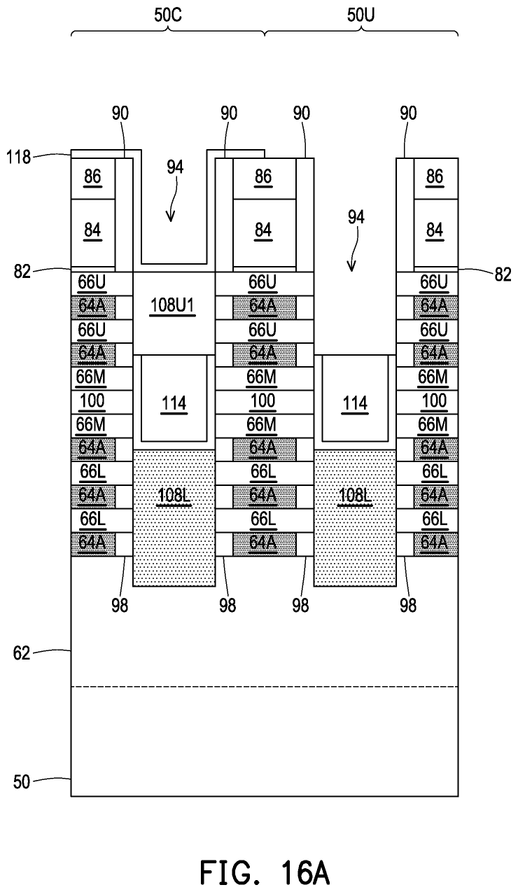

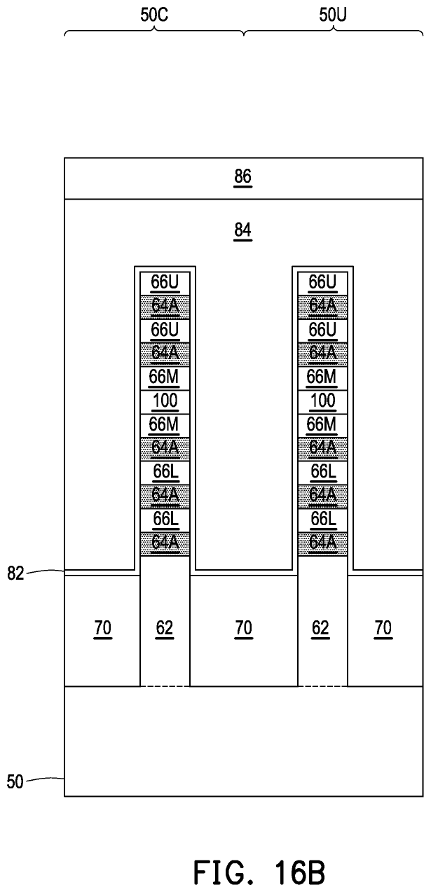

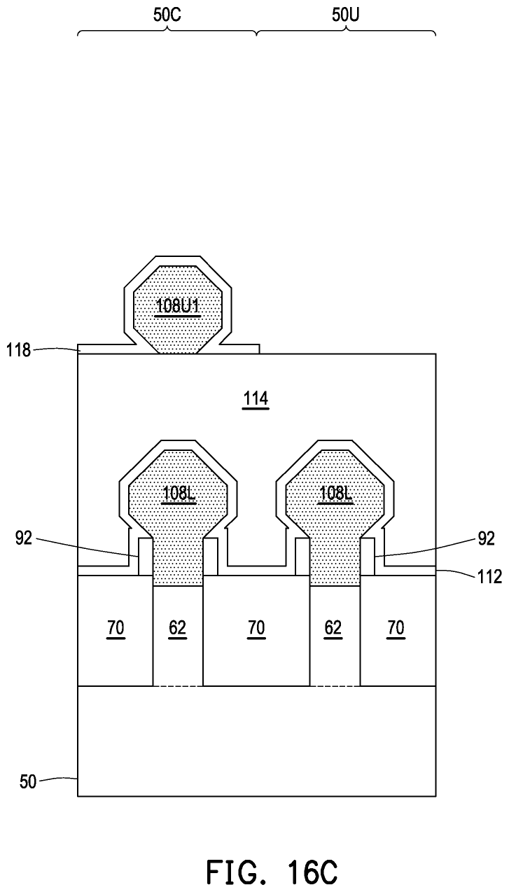

In FIGS. 16A-16C, the blocking liner 116 is removed from the source/drain recesses 94 in the UFET region 50U. Any acceptable etch process, such as a dry etch, a wet etch, the like, or a combination thereof, may be performed to remove the blocking liner 116. The etching may be isotropic. The etching is selective to the blocking liner 116 Removing the blocking liner 116 exposes the sidewalls of the upper semiconductor nanostructures 66U in the UFET region 50U.

After removing the blocking liner 116, a blocking liner 118 is formed over the upper epitaxial source/drain regions 108U1 in the CFET region 50C. The blocking liner 118 prevents additional epitaxial growth of the upper epitaxial source/drain regions 108U1 during deposition of the upper epitaxial source/drain regions 108U2, described below. The blocking liner 118 may be formed by depositing a dielectric material, then patterning the dielectric material to expose the ends of the upper semiconductor nanostructures 66U in the UFET region 50U. The blocking liner 118 may be deposited and patterned using processes and materials similar to the blocking liner 116.

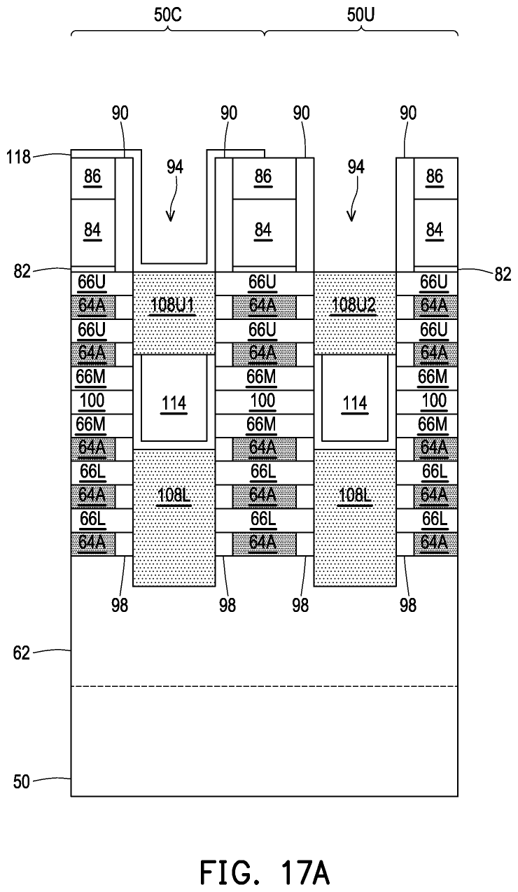

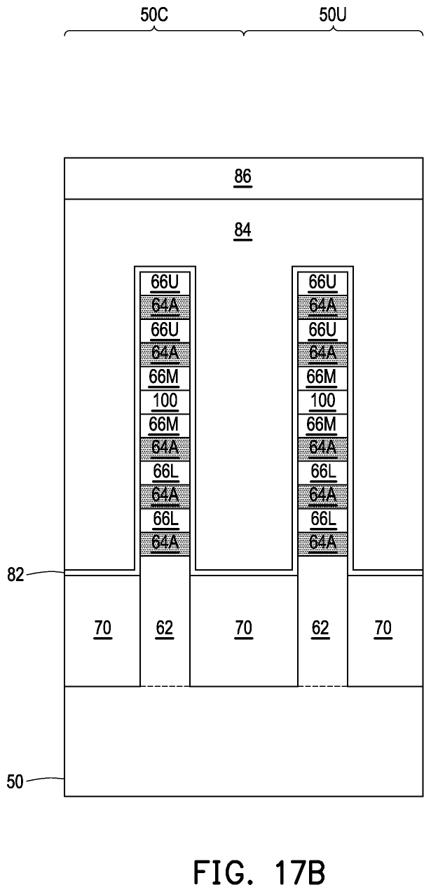

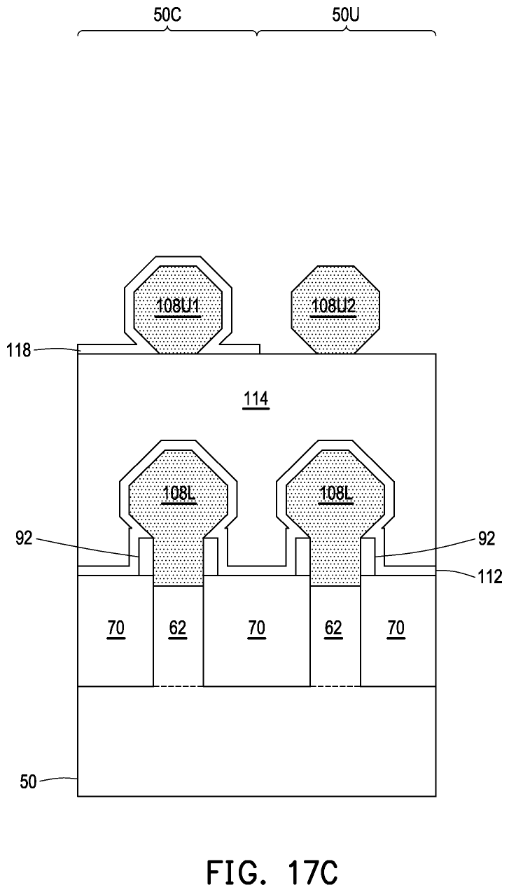

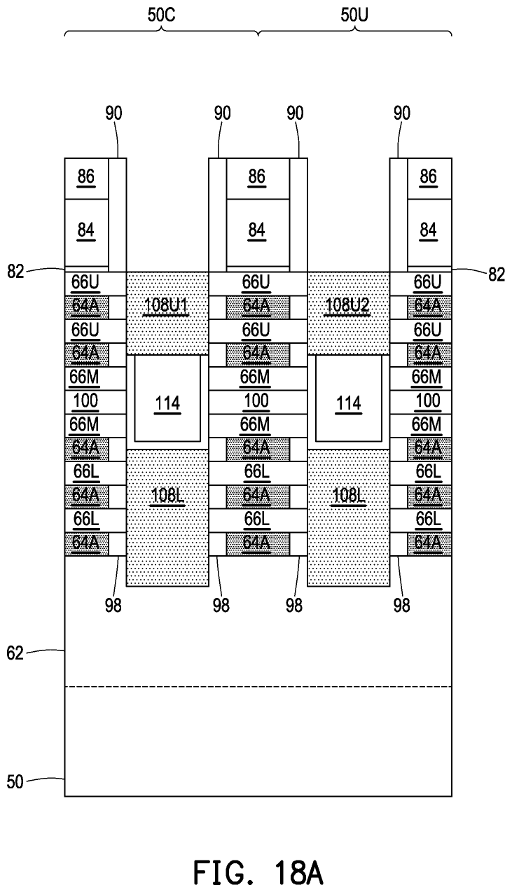

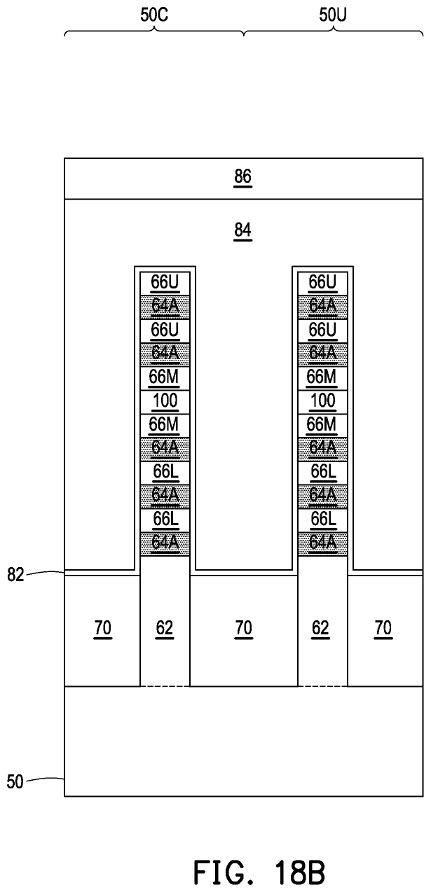

In FIGS. 17A-17C, upper epitaxial source/drain regions 108U2 are formed in the upper portions of the source/drain recesses 94 in the UFET region 50U. The blocking liner 118, on the other hand, prevents growth from occurring in the CFET region 50C. The upper epitaxial source/drain regions 108U2 only partially fill the source/drain recesses 94, such that the upper epitaxial source/drain regions 108U2 are in contact with the upper semiconductor nanostructures 66U and are not in contact with the lower semiconductor nanostructures 66L. The first ILD 114 may provide isolation between the upper epitaxial source/drain regions 108U2 and the lower epitaxial source/drain regions 108L.

In some embodiments, the upper epitaxial source/drain regions 108U2 exert stress in the respective channel regions of the upper semiconductor nanostructures 66U, thereby improving performance. The upper epitaxial source/drain regions 108U2 are formed in the source/drain recesses 94 such that each stack of the upper semiconductor nanostructures 66U is disposed between respective neighboring pairs of the upper epitaxial source/drain regions 108U2. In some embodiments, the inner spacers 98 are used to separate the upper epitaxial source/drain regions 108U2 from the first dummy nanostructures 64A by an appropriate lateral distance so that the upper epitaxial source/drain regions 108U2 do not short out with subsequently formed gates of the resulting devices.

The upper epitaxial source/drain regions 108U2 are epitaxially grown in the upper portions of the source/drain recesses 94 in the UFET region 50U. For example, the upper epitaxial source/drain regions 108U2 may be grown laterally from exposed sidewalls of the upper semiconductor nanostructures 66U. As the upper epitaxial source/drain regions 108U2 grow in the source/drain recesses 94, facets may form and adjoining growth may merge together to form the upper epitaxial source/drain regions 108U2. The upper epitaxial source/drain regions 108U2 have a conductivity type that is suitable for the device type of the upper nanostructure-FETs. Because the UFET region 50U provides unipolar stacked transistors, the conductivity type of the upper epitaxial source/drain regions 108U2 are the same as the conductivity type of the lower epitaxial source/drain regions 108L. Put another way, the upper epitaxial source/drain regions 108U2 may be doped with the same conductivity type as the lower epitaxial source/drain regions 108L. In some embodiments, the upper epitaxial source/drain regions 108U2 are n-type source/drain regions. For example, if the upper semiconductor nanostructures 66U are silicon, the upper epitaxial source/drain regions 108U2 may include materials exerting a tensile strain on the upper semiconductor nanostructures 66U, such as silicon, carbon-doped silicon, phosphorous-doped silicon, silicon phosphide, silicon arsenide, or the like. In some embodiments, the upper epitaxial source/drain regions 108U2 are p-type source/drain regions. For example, if the upper semiconductor nanostructures 66U are silicon-germanium, the upper epitaxial source/drain regions 108U1 may include materials exerting a compressive strain on the upper semiconductor nanostructures 66U, such as silicon-germanium, boron-doped silicon-germanium, boron-doped silicon, germanium, germanium tin, or the like. The upper epitaxial source/drain regions 108U2 may have surfaces raised from respective upper surfaces of the upper semiconductor nanostructures 66U and may have facets.

The upper epitaxial source/drain regions 108U2 may be implanted with dopants to form source/drain regions, similar to the process previously discussed for forming lightly-doped source/drain regions, followed by an anneal. The source/drain regions may have an impurity concentration in the range of 10¹⁹ atoms/cm³ and 10²¹ atoms/cm³. The n-type and/or p-type impurities for source/drain regions may be any of the impurities previously discussed. In some embodiments, the upper epitaxial source/drain regions 108U2 are in situ doped during growth. In the illustrated embodiments, the upper epitaxial source/drain regions 108U2 extend to the surface of the first ILD 114.

As a result of the epitaxy processes used to form the upper epitaxial source/drain regions 108U2, upper surfaces of the upper epitaxial source/drain regions 108U2 have facets which expand laterally outward beyond sidewalls of the nanostructures 64, 66. In some embodiments, adjacent upper epitaxial source/drain regions 108U2 remain separated after the epitaxy process is completed as illustrated by FIG. 17C. In other embodiments, these facets cause adjacent upper epitaxial source/drain regions 108U2 of a same nanostructure-FET to merge (not separately illustrated), for example, with adjacent upper epitaxial source/drain regions 108U2.

Similar to the upper epitaxial source/drain regions 108U1, discussed above, the upper epitaxial source/drain regions 108U2 may comprise one or more semiconductor material layers, the description of which is not repeated.

The source/drain recesses 94 in the UFET region 50U thus contain the upper epitaxial source/drain regions 108U2, the first ILD 114, and the lower epitaxial source/drain regions 108L. The first ILD 114 is between the upper epitaxial source/drain regions 108U2 and the lower epitaxial source/drain regions 108L. The lower epitaxial source/drain regions 108L are for lower nanostructure-FETs of the UFETs, and the upper epitaxial source/drain regions 108U2 are for upper nanostructure-FETs of the UFETs. The first ILD 114 thus may acts as isolation regions to prevent shorting of the lower and upper nanostructure-FETs. On the other hand, as illustrated and discussed below, the upper epitaxial source/drain regions 108U2 and the lower epitaxial source/drain regions 108L may later by electrically coupled together.

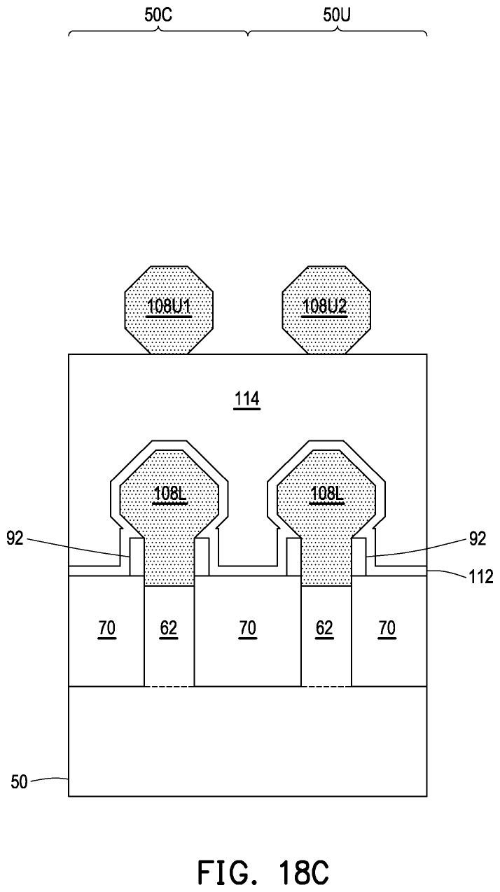

In FIGS. 18A-18C, the blocking liner 118 is removed from the source/drain recesses 94 in the CFET region 50C. Any acceptable etch process, such as a dry etch, a wet etch, the like, or a combination thereof, may be performed to remove the blocking liner 118. The etching may be isotropic. The etching is selective to the blocking liner 118 After removing the blocking liner 118, outer surfaces of the upper epitaxial source/drain regions 108U1 and the upper epitaxial source/drain regions 108U2 are exposed.

FIGS. 9-18C illustrate one process for forming the upper epitaxial source/drain regions 108U2 for the UFETs in the UFET region 50U where the upper epitaxial source/drain regions 108U2 is formed in a separate process from the lower epitaxial source/drain regions 108L. FIGS. 19-31C illustrate another process for forming the upper epitaxial source/drain regions 108U2 for the UFETs in the UFET region 50U where the lower epitaxial source/drain regions 108L are formed in the same process as forming the upper epitaxial source/drain regions 108U2. FIG. 19 follows from the structure illustrated in FIG. 8.

In FIG. 19, following the formation of the dummy spacers 104, a sacrificial dielectric 105 is formed over the sacrificial dielectric 102. The sacrificial dielectric 105 is disposed on the sidewalls of the lower portion of the dummy spacers 104, adjacent the middle semiconductor nanostructures 66M and may overlap some of the inner spacers 98. The sacrificial dielectric 105 may be formed by conformally forming a dielectric material and subsequently recessing the dielectric material. Acceptable dielectric materials may include silicon oxide, silicon nitride, silicon oxynitride, silicon oxycarbonitride, combinations thereof, or the like, which may be formed by a deposition process such as chemical vapor deposition (CVD), atomic layer deposition (ALD), or the like. Other dielectric materials formed by any acceptable process may be used. The dielectric material of the sacrificial dielectric 105 has etch selectivity with respect to the dummy spacers 104. The dielectric material of the sacrificial dielectric 105 may be the same material as or a different material from the sacrificial dielectric 102. Any acceptable etch process, such as a dry etch, a wet etch, the like, or a combination thereof, may be performed to recess the dielectric material. The etching may be isotropic, such as an etch-back process that removes the dielectric material from the upper portions of the source/drain recesses 94. The dielectric material, when etched, has portions left in the lower portions of the source/drain recesses 94 (thus forming the sacrificial dielectric 105). Portions of the dummy spacers 104 above the sacrificial dielectric 105 are exposed by recessing the dielectric material of the sacrificial dielectric 105.

In FIG. 20, a masking structure 105B is formed over the CFET region 50C to protect the dummy spacers 104. In the UFET region 50U, the dummy spacers 104 will be recessed in a subsequent process. The masking structure 105B may be any suitable mask, including a photoresist mask or a multi-layered structure, including a photoresist mask and an upper hard mask, such as an inorganic material such as an oxide or nitride of silicon or aluminum. In some embodiments, the masking structure 105B is a dielectric material having etch selectivity with respect to the dummy spacers 104. The masking structure 105B may be formed using a spin on process, patterned, and developed to remain only in the CFET region 50C to protect the dummy spacers 104. Thus, the masking structure 105B is removed from the UFET region 50U. The masking structure 105B may be formed using other processes as well, such as by CVD, PVD, ALD, and so forth, or combinations thereof. Then, portions of the masking structure 105B may be removed from the UFET region 50U by an etching process.

In FIG. 21, the exposed portions of the dummy spacers 104 are removed from the source/drain recesses 94 in the UFET region 50U, leaving behind lower dummy spacers 104A. Any acceptable etch process, such as a dry etch, a wet etch, the like, or a combination thereof, may be performed to remove the upper portion of the dummy spacers 104. The etching may be isotropic. The etching is selective to the material of the dummy spacers 104 (e.g., selectively etches the material of the dummy spacers 104 at a faster rate than the materials of the sacrificial dielectric 105). The etching may also remove some of the sacrificial dielectric 105, for example, such that the upper surface is concaved or dished. Removing the upper portion of the dummy spacers 104 in the UFET region 50U exposes the sidewalls of the upper semiconductor nanostructures 66U.

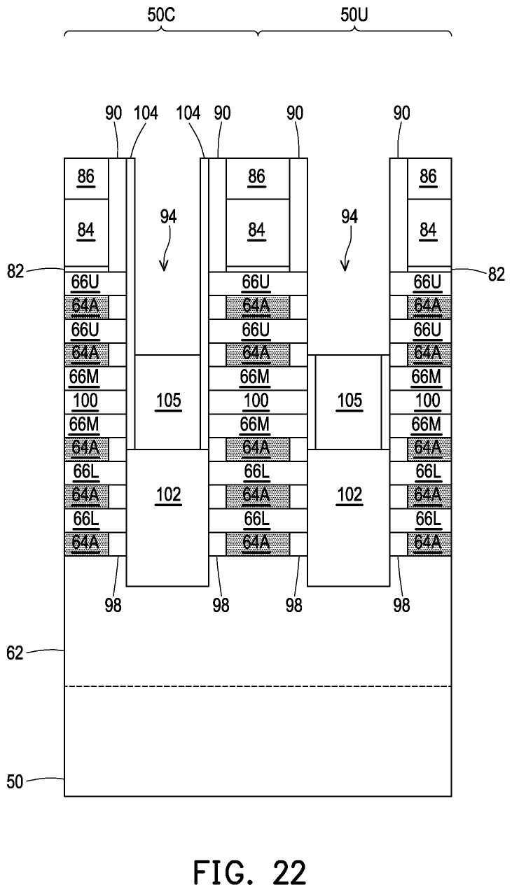

In FIG. 22, the masking structure 105B is removed. It may be removed by any acceptable technique, such as an etching process if the masking structure 105B is a dielectric material, or by an ashing process if the masking structure 105B is a photoresist.

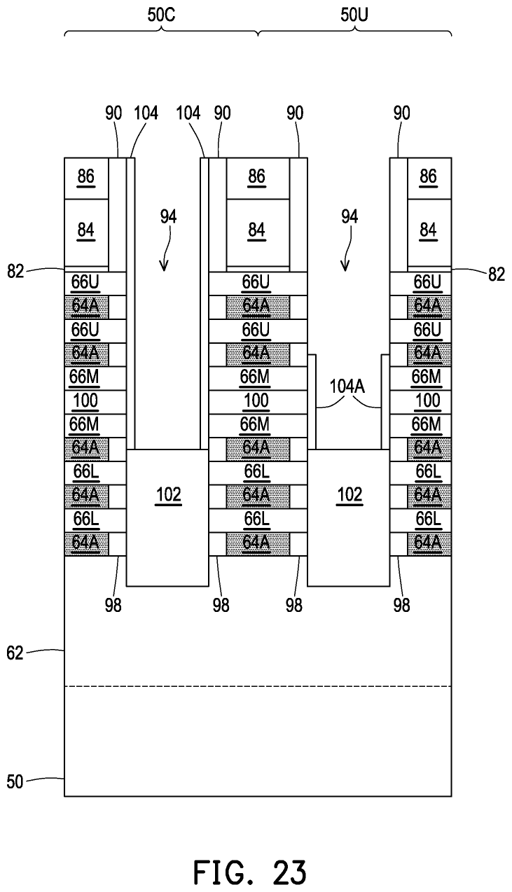

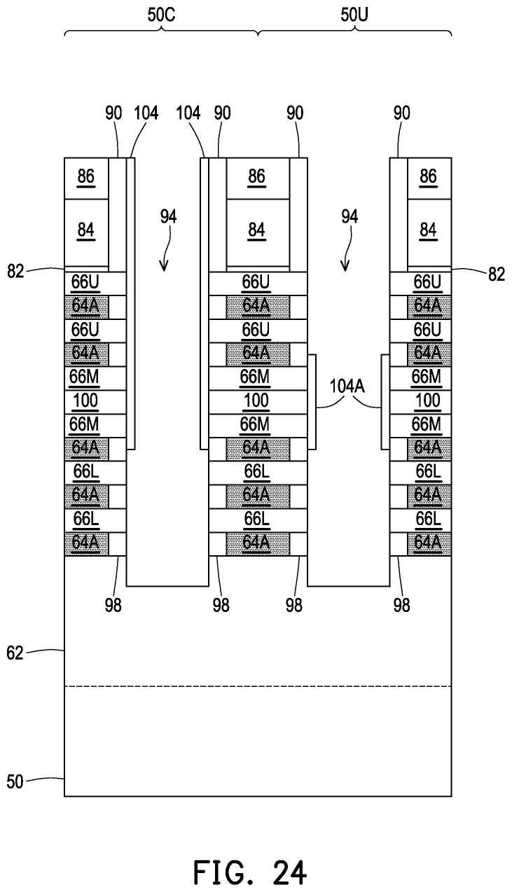

In FIG. 23, the sacrificial dielectric 105 is removed from the source/drain recesses 94. Any acceptable etch process, such as a dry etch, a wet etch, the like, or a combination thereof, may be performed to remove the sacrificial dielectric 105. The etching may be isotropic. The etching is selective to the sacrificial dielectric 105 (e.g., selectively etches the material of the sacrificial dielectric 105 at a faster rate than the materials of the dummy spacers 104). Removing the sacrificial dielectric 105 the lower portion of the dummy spacers 104.

In FIG. 24, the sacrificial dielectric 102 is removed from the source/drain recesses 94. In some embodiments, the removal of the sacrificial dielectric 102 may be the same process as the removal process of the sacrificial dielectric 105, while in other embodiments, the removal of the sacrificial dielectric 102 may be a different process, such as by using different etchants. Any acceptable etch process, such as a dry etch, a wet etch, the like, or a combination thereof, may be performed to remove the sacrificial dielectric 102. The etching may be isotropic. The etching is selective to the sacrificial dielectric 102 (e.g., selectively etches the material of the sacrificial dielectric 102 at a faster rate than the materials of the nanostructures 64, 66, the inner spacers 98, and the dummy spacers 104). Removing the sacrificial dielectric 102 exposes the sidewalls of the lower semiconductor nanostructures 66L, while the sidewalls of the upper semiconductor nanostructures 66U and middle semiconductor nanostructures 66M in the CFET region 50C remain covered by the dummy spacers 104 and the sidewalls of the middle semiconductor nanostructures 66M in the UFET region 50U remain covered by the dummy spacers 104A. In the illustrated embodiments, the dummy spacers 104 also cover sidewalls of the middle semiconductor nanostructures 66M. In other embodiments, depending on a desired height of subsequently formed source/drain regions, a height of the sacrificial dielectric 102 and/or sacrificial dielectric 105 may be adjusted so that the dummy spacers 104 may expose sidewalls of one or more of the middle semiconductor nanostructures 66M.

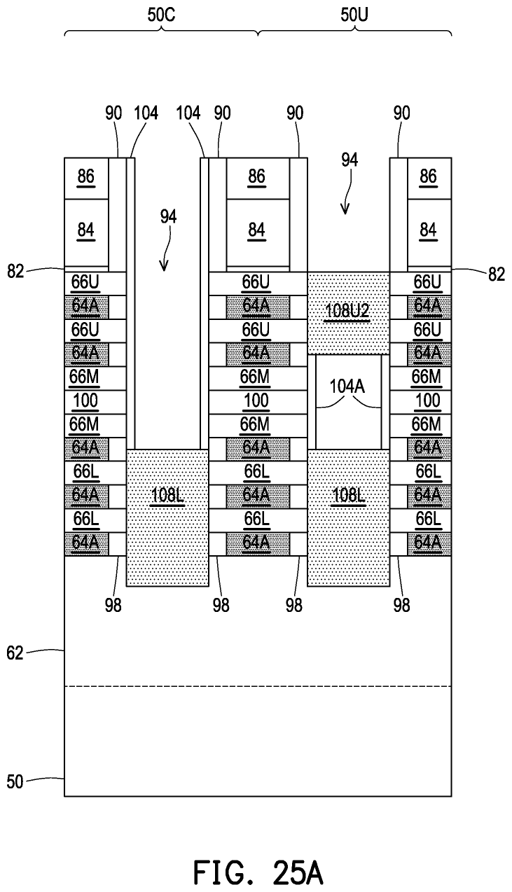

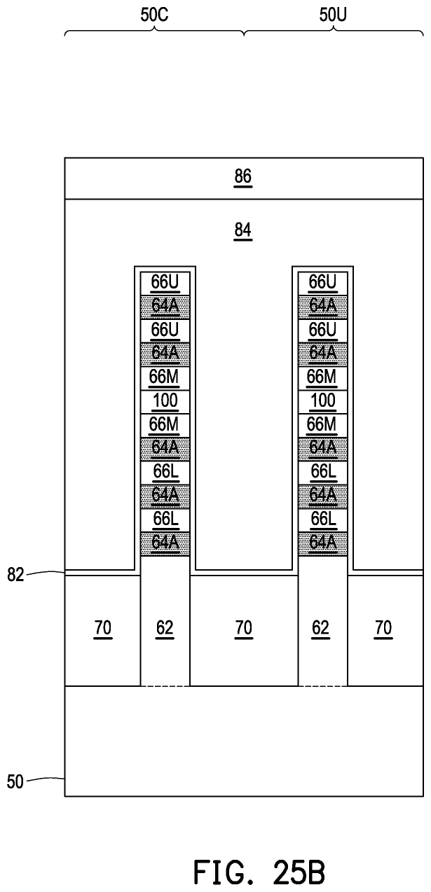

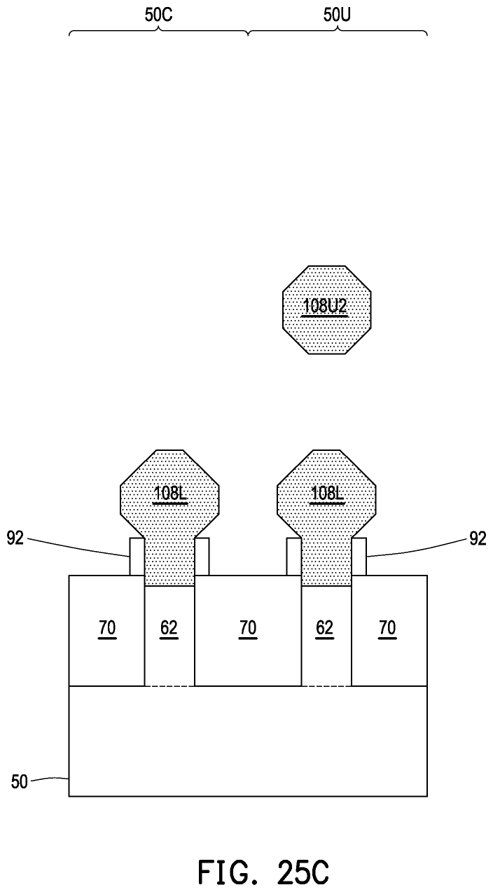

In FIGS. 25A-25C, the lower epitaxial source/drain regions 108L are formed in the lower portions of the source/drain recesses 94 in both the CFET region 50C and the UFET region 50U and the upper epitaxial source/drain regions 108U2 are simultaneously formed in the upper portions of the source/drain recesses 94 in the UFET region 50U. The dummy spacers 104 prevent growth from occurring in the CFET region 50C and the dummy spacers 104A prevent growth from occurring in the UFET region 50U for the middle semiconductor nanostructures 66M. The lower epitaxial source/drain regions 108L and the upper epitaxial source/drain regions 108U2 may be grown using materials and processes discussed above, which are not repeated. It should be noted, however, that in the CFET region 50C only the lower semiconductor nanostructures 66L are exposed, thus growth will be from those, while in the UFET region 50U, both the lower semiconductor nanostructures 66L and the upper semiconductor nanostructures 66U are exposed, thus growth will occur from both. The lower epitaxial source/drain regions 108L and the upper epitaxial source/drain regions 108U2 may include doping, as discussed respectively, above. Also, they may have respective facets, and exert compressive or tensile force on the channel regions, as discussed above. Other features and properties of the lower epitaxial source/drain regions 108L and the upper epitaxial source/drain regions 108U2 also apply.

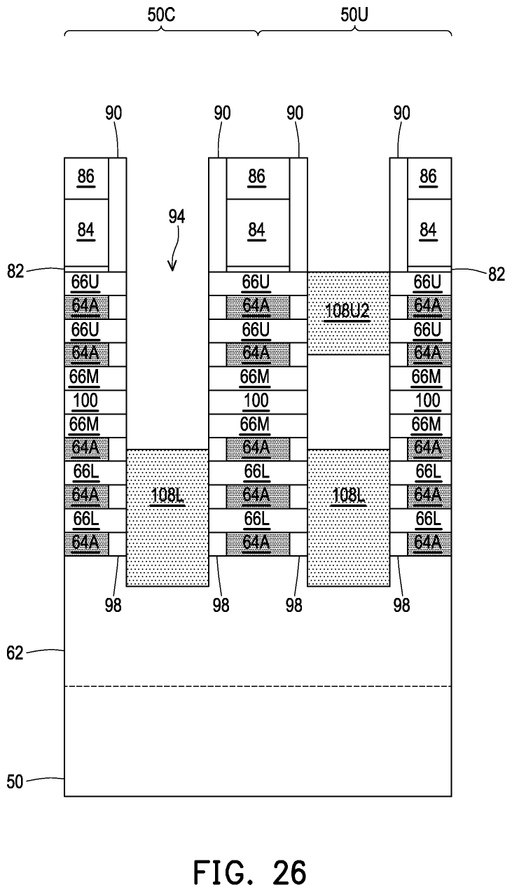

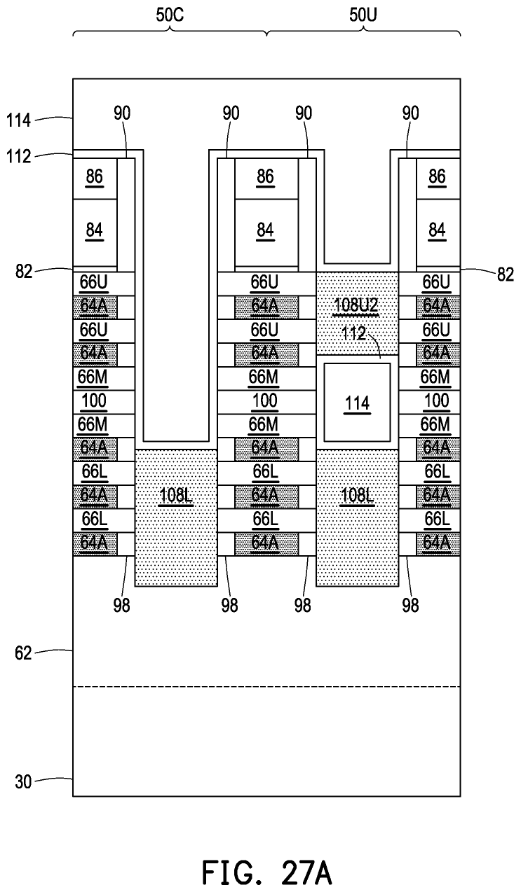

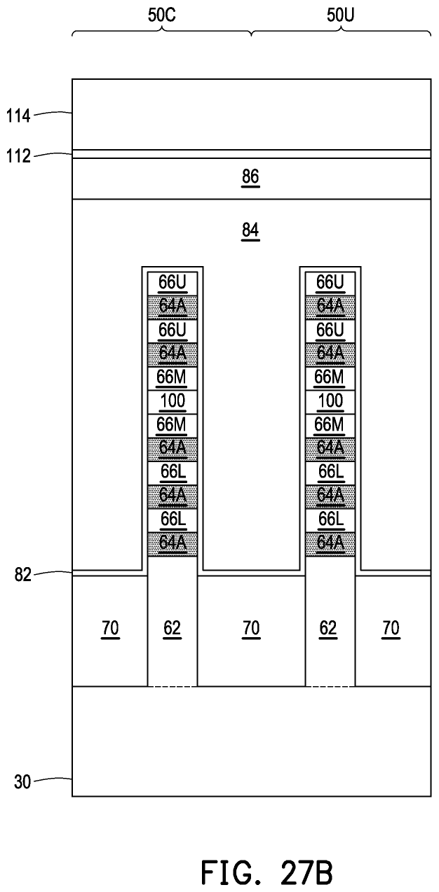

In FIG. 26, the dummy spacers 104 and dummy spacers 104A are removed. Any acceptable etch process, such as a dry etch, a wet etch, the like, or a combination thereof, may be performed to remove the dummy spacers 104 and dummy spacers 104A. The etching may be isotropic. The etching is selective to the material of the dummy spacers 104 and 104A (e.g., selectively etches the material of the dummy spacers 104 and 104A at a faster rate than the materials of the semiconductor nanostructures 66 and inner spacers 98). Removing the dummy spacers 104 and 104A exposes the sidewalls of the upper semiconductor nanostructures 66U in the CFET region 50C.

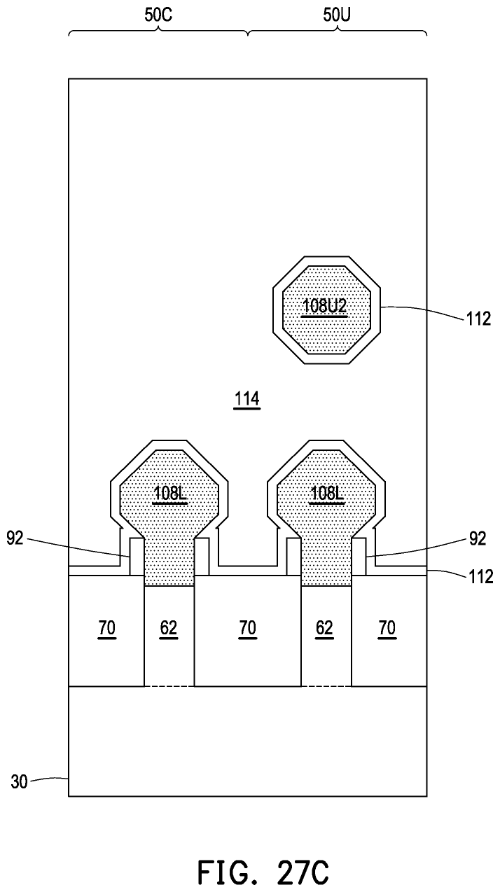

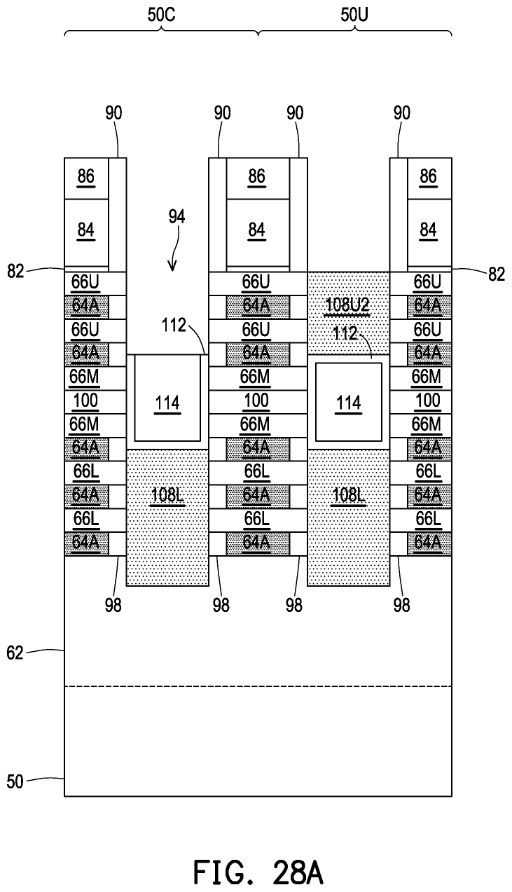

In FIGS. 27A-27C, a first inter-layer dielectric (ILD) 114 is formed over the lower epitaxial source/drain regions 108L, the gate spacers 90, the masks 86 (if present) or the dummy gates 84, and the isolation regions 70. The first ILD 114 may be formed using processes and materials similar to those described above with respect to the first ILD 114 of FIGS. 12A-12C. Likewise, a first CESL 112 may be formed between the first ILD 114 and the lower epitaxial source/drain regions 108L, the gate spacers 90, the masks 86 (if present) or the dummy gates 84, and the isolation regions 70. The second CESL 122 may be formed using processes and materials similar to those described above with respect to the first CESL 112 of FIGS. 12A-12C. It should be noted, however, that the first CESL 112 surrounds sides, tops, and bottoms of the upper epitaxial source/drain regions 108U2.

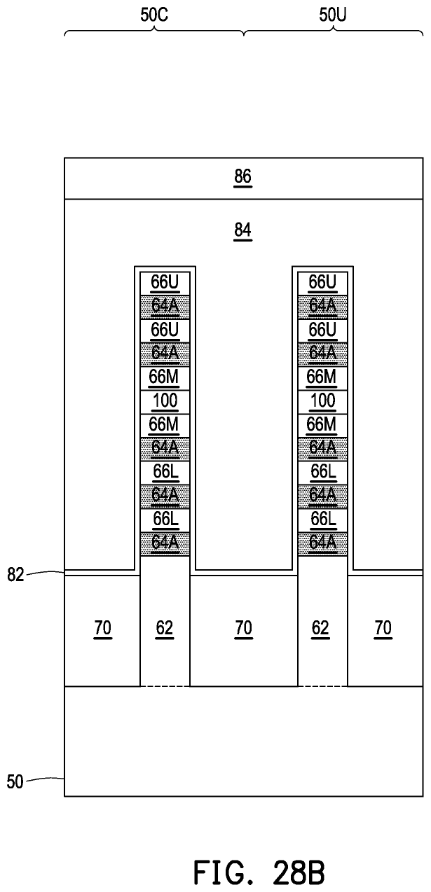

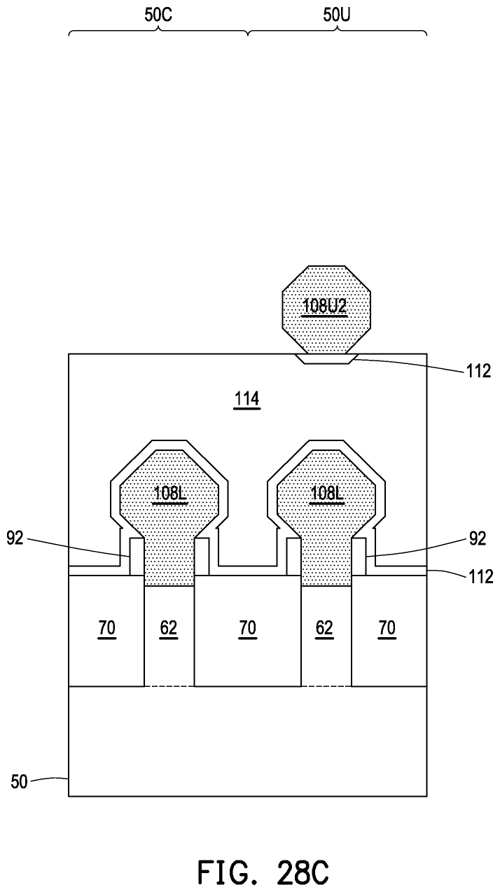

In FIG. 28A-28C, the first ILD 114 and the first CESL 112 are recessed such that they are removed from the upper portions of the source/drain recesses 94. After the recessing, the first ILD 114 only partially fills the source/drain recesses 94, such that the sidewalls of the upper semiconductor nanostructures 66U are exposed in the CFET region 50C. The first ILD 114 and the first CESL 112 may be recessed using an etching process. The etching exposes the sidewalls of the upper semiconductor nanostructures 66U. In some embodiments, the first ILD 114 is etched using the first CESL 112 as an etch stop layer, and the first CESL 112 is then etched using the first ILD 114 as an etching mask. Notably, following recessing of the first ILD 114 and the first CESL 112, a portion of the first CESL 112 remains disposed below and in contact with a lower surface of the upper epitaxial source/drain regions 108U2. This portion is embedded in an upper surface of the first ILD 114.

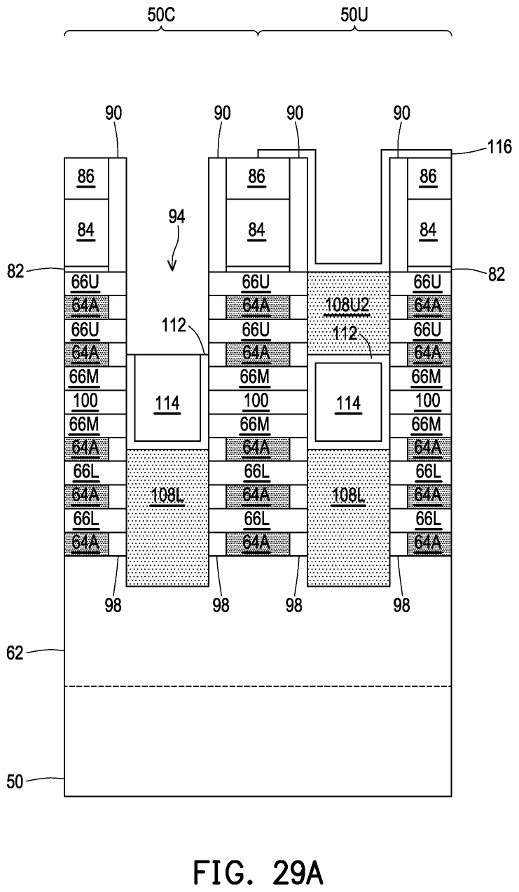

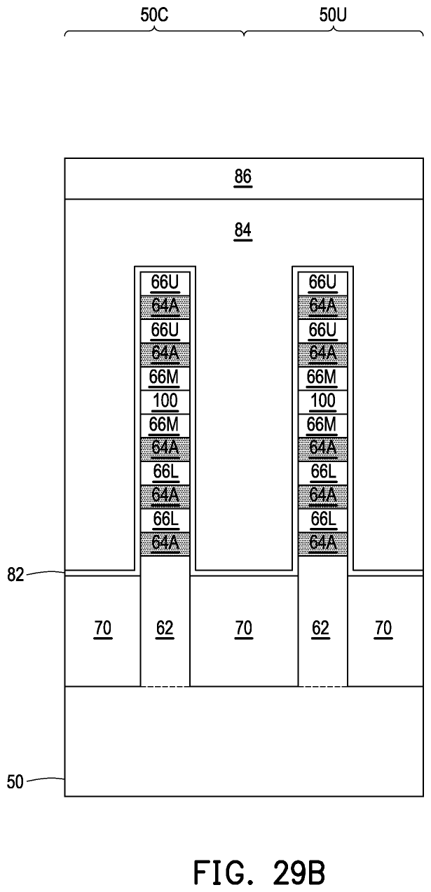

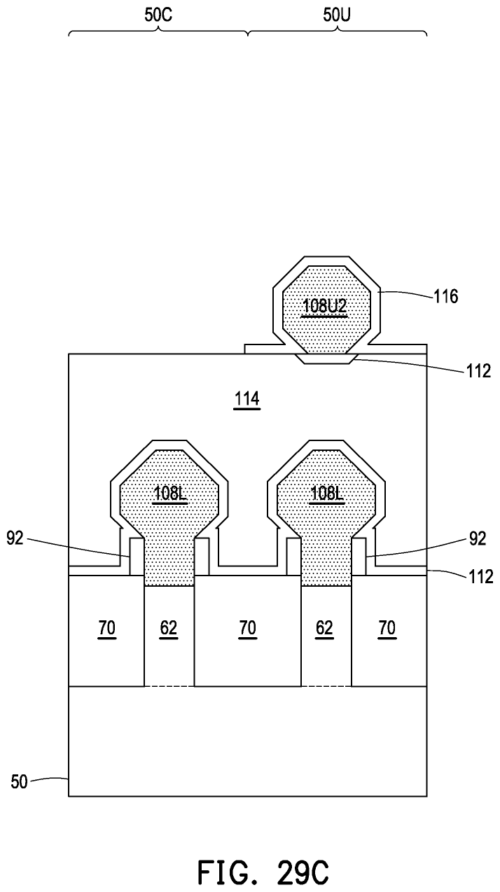

In FIGS. 29A-29C, a blocking liner 116 is formed over the UFET region 50U while the CFET region 50C is exposed. In particular, the blocking liner 116 is formed over the upper epitaxial source/drain regions 108U2 to prevent further epitaxial growth during the deposition of the upper epitaxial source/drain regions 108U1, described below. The blocking liner 116 may be formed using processes and materials similar to those discussed above with respect to FIGS. 15A-15C. In particular, after deposition of the dielectric material of the blocking liner 116, the dielectric material may be patterned by forming a photomask over the UFET region 50U, developing the photomask to expose the dielectric material in the CFET region 50C, and then etching the dielectric material to remove the dielectric material in the CFET region 50C, thereby forming the blocking liner 116 in the UFET region 50U. The photomask may then be removed for example by an ashing technique. The blocking liner 116 may have an etch selectivity similar to the dummy spacers 104, discussed above.

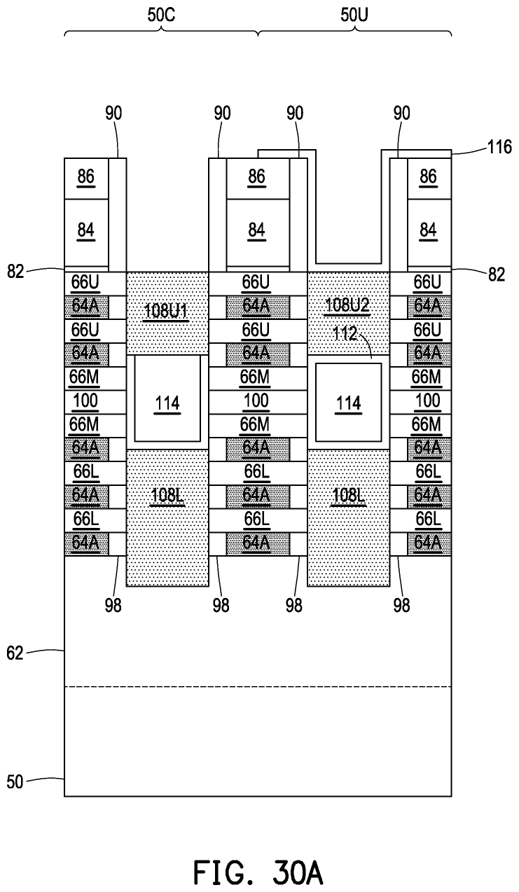

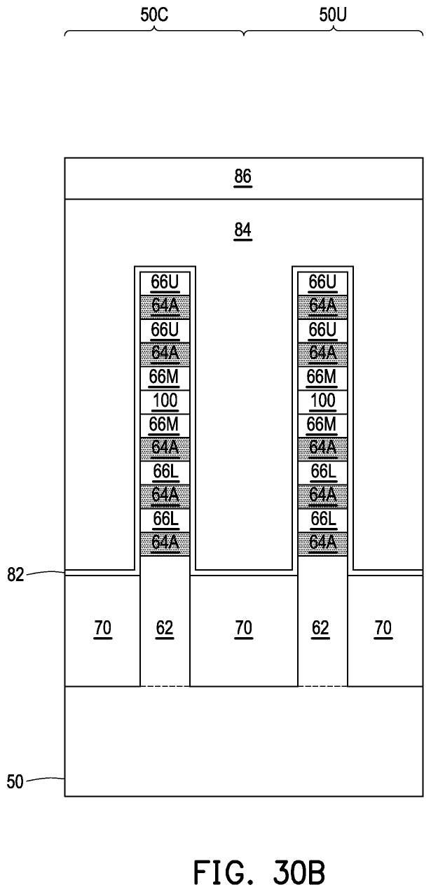

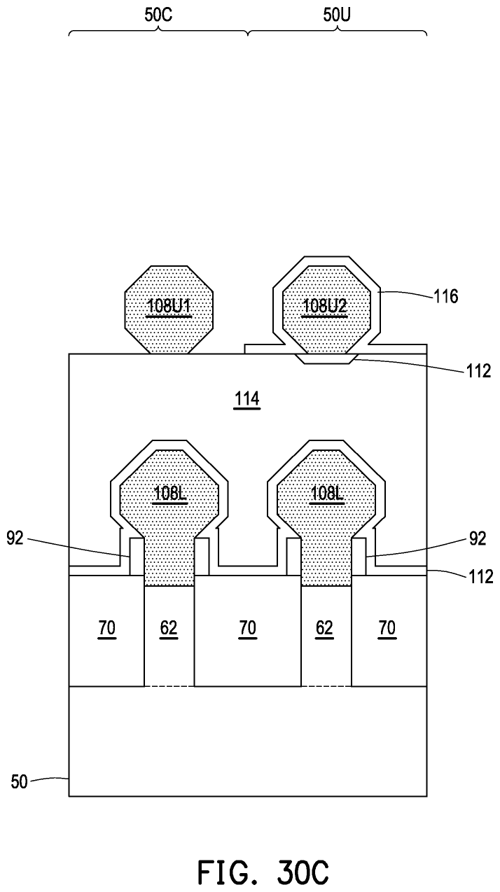

In FIGS. 30A-30C, the upper epitaxial source/drain regions 108U1 are formed in the upper portions of the source/drain recesses 94 in the CFET region 50C. The blocking liner 116, on the other hand, prevents growth from occurring in the UFET region 50U. The upper epitaxial source/drain regions 108U1 only partially fill the source/drain recesses 94, such that the upper epitaxial source/drain regions 108U1 are in contact with the upper semiconductor nanostructures 66U and are not in contact with the lower semiconductor nanostructures 66L. The first ILD 114 may provide isolation between the upper epitaxial source/drain regions 108U1 and the lower epitaxial source/drain regions 108L. The upper epitaxial source/drain regions 108U1 may be grown using materials and processes discussed above, which are not repeated. It should be noted, however, that in the CFET region 50C only the upper semiconductor nanostructures 66U are exposed, thus growth will be from those. The upper epitaxial source/drain regions 108U1 may include doping, as discussed above. Also, they may have respective facets, and exert compressive or tensile force on the channel regions, as discussed above. Other features and properties of the upper epitaxial source/drain regions 108U1 also apply.

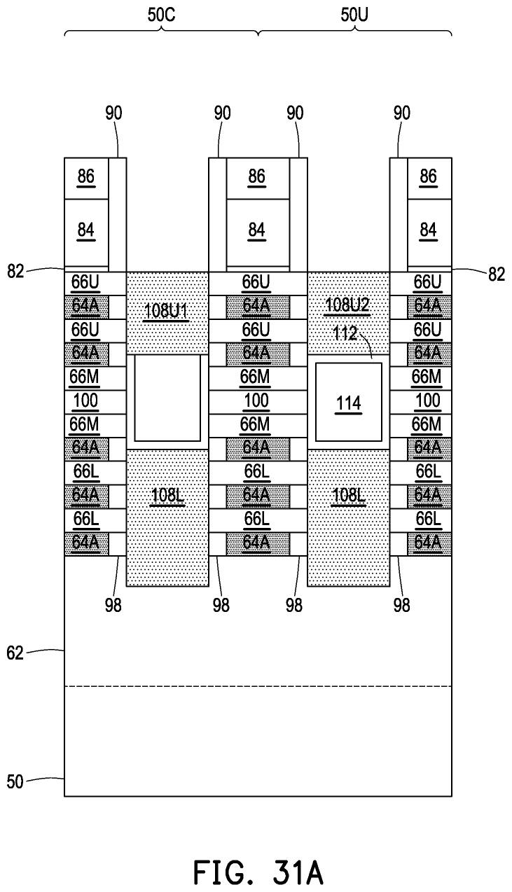

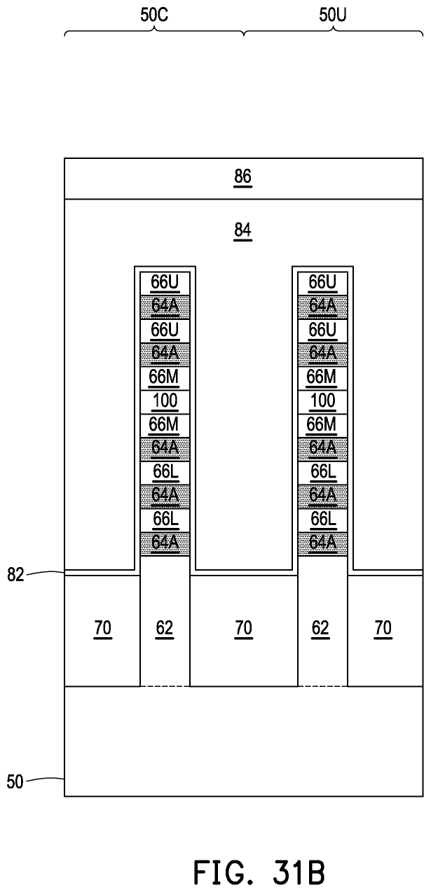

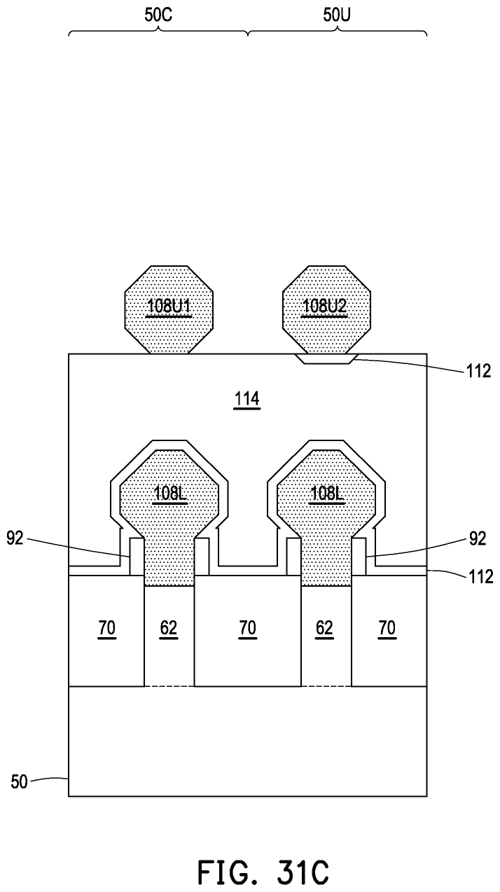

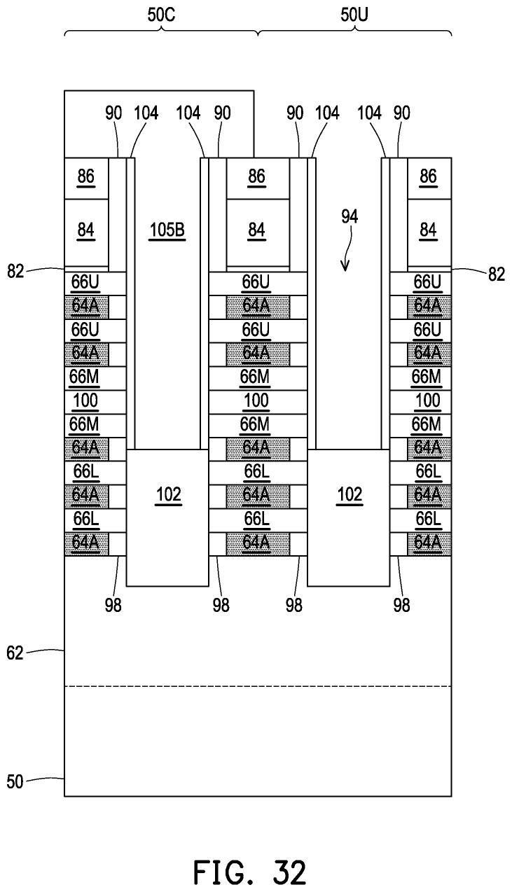

In FIGS. 31A-31C, the blocking liner 116 is removed from the source/drain recesses 94 in the UFET region 50U. Any acceptable etch process, such as a dry etch, a wet etch, the like, or a combination thereof, may be performed to remove the blocking liner 116. The etching may be isotropic. The etching is selective to the blocking liner 116 After removing the blocking liner 116, outer surfaces of the upper epitaxial source/drain regions 108U1 and the upper epitaxial source/drain regions 108U2 are exposed.

FIGS. 32-38C illustrate another process for forming the upper epitaxial source/drain regions 108U2 for the UFETs in the UFET region 50U where the lower epitaxial source/drain regions 108L are formed in the same process as forming the upper epitaxial source/drain regions 108U2. FIG. 32 follows from the structure illustrated in FIG. 8. The process corresponding to FIGS. 32-38C is similar to the process corresponding to FIGS. 19-31C, except the dummy spacers 104A are not formed. This allows the lower epitaxial source/drain regions 108L and upper epitaxial source/drain regions 108U2 to grow from the middle semiconductor nanostructures 66M in the UFET region 50U, thereby forming larger epitaxial source/drain regions in the UFET region 50U. Like references are used for like structures.

In FIG. 32, a masking structure 105B is formed over the CFET region 50C to protect the dummy spacers 104. The dummy spacers 104 in the UFET region 50U are exposed from the masking structure 105B. The masking structure 105B may be formed using materials and processes described above with respect to FIG. 20.

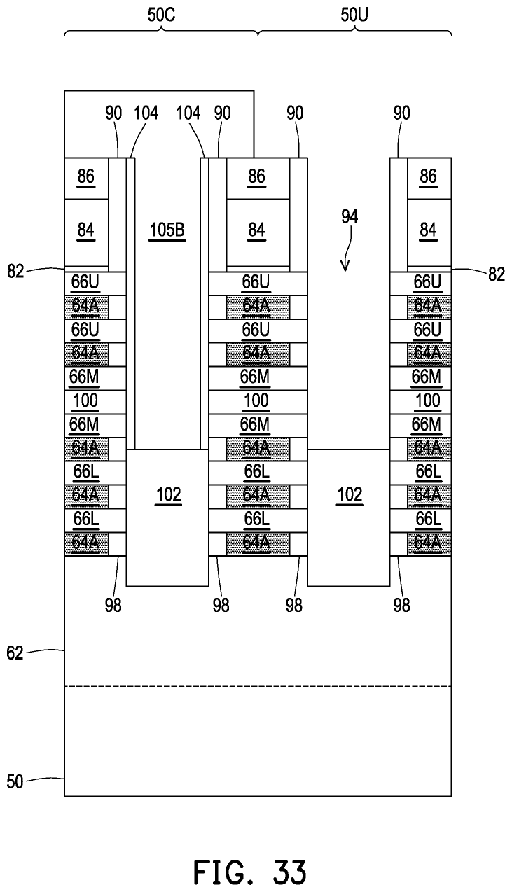

In FIG. 33, the dummy spacers 104 are removed in the UFET region 50U, thereby exposing the upper semiconductor nanostructures 66U, the middle semiconductor nanostructures 66M, and the lower semiconductor nanostructures 66L. The dummy spacers 104 in the UFET region 50U may be removed using processes and materials similar to those discussed above with respect to FIG. 21.

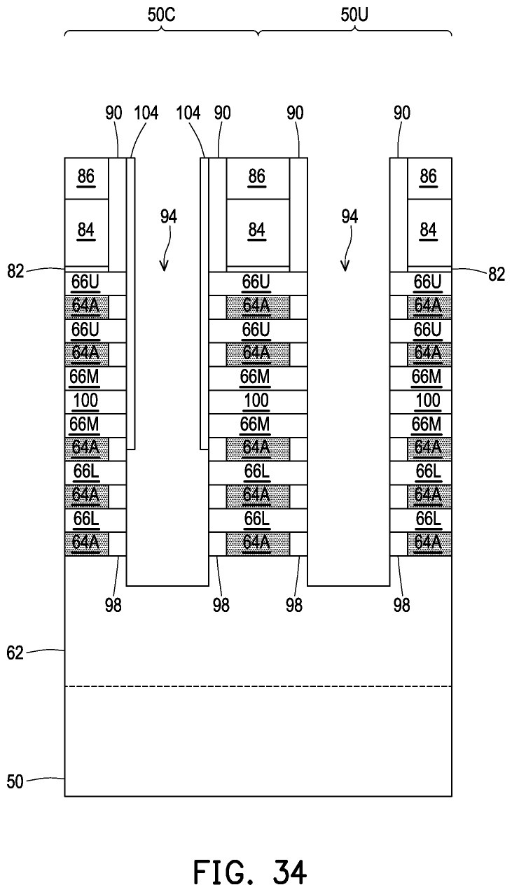

In FIG. 34, the masking structure 105B and sacrificial dielectric 102 are removed, the dummy spacers 104 remaining in the CFET region 50C. The masking structure 105B may be removed using processes and materials similar to those discussed above with respect to FIG. 22. The sacrificial dielectric 102 may be removed using processes and materials similar to those discussed above with respect to FIG. 24.

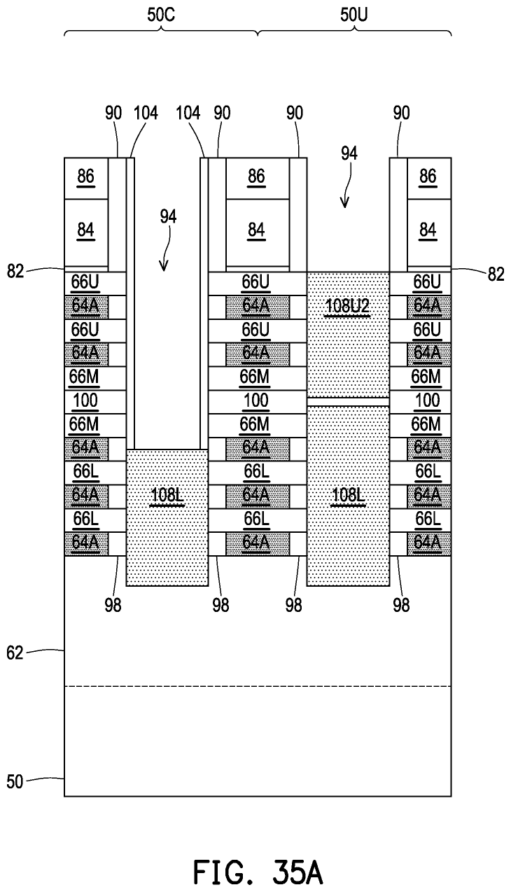

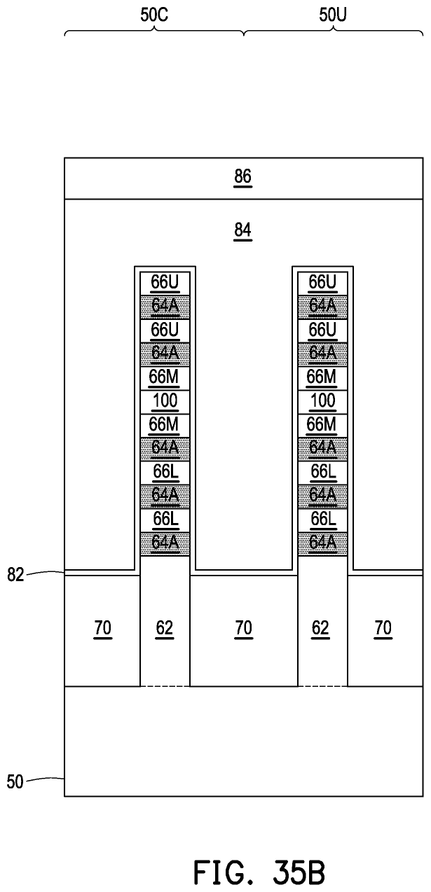

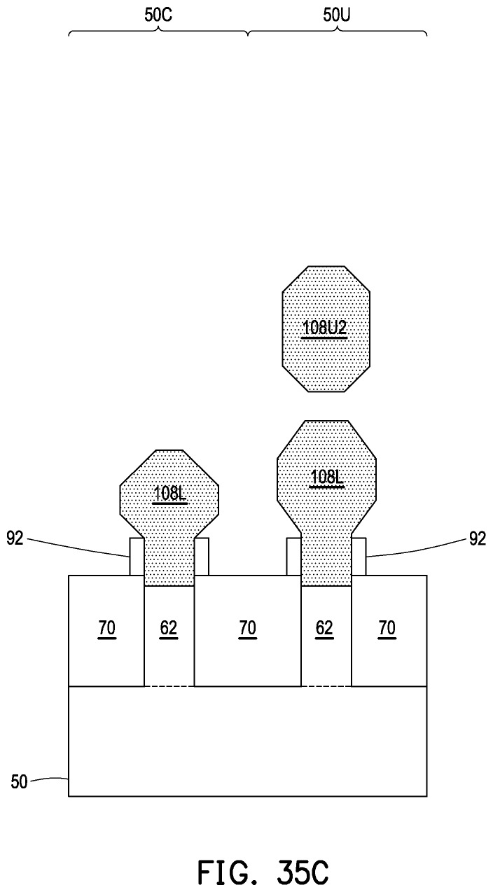

In FIGS. 35A-35C, the lower epitaxial source/drain regions 108L are formed in the lower portions of the source/drain recesses 94 in both the CFET region 50C and the UFET region 50U, and the upper epitaxial source/drain regions 108U2 are simultaneously formed in the upper portions of the source/drain recesses 94 in the UFET region 50U. The dummy spacers 104 prevent growth from occurring in the CFET region 50C. The lower epitaxial source/drain regions 108L and the upper epitaxial source/drain regions 108U2 may be grown using materials and processes discussed above, which are not repeated. It should be noted, however, that in the CFET region 50C, as illustrated only the lower semiconductor nanostructures 66L are exposed, thus growth will be from those. However, the length of the dummy spacers 104 may be altered so that the middle semiconductor nanostructures 66M below the isolation structures 100 may also be exposed. In the UFET region 50U, both the lower semiconductor nanostructures 66L and the upper semiconductor nanostructures 66U are exposed along with the middle semiconductor nanostructures 66M, thus growth may occur from each of the upper semiconductor nanostructures 66U, middle semiconductor nanostructures 66M, and lower semiconductor nanostructures 66L. The lower epitaxial source/drain regions 108L and the upper epitaxial source/drain regions 108U2 may include doping, as discussed respectively, above. Also, they may have respective facets, and exert compressive or tensile force on the channel regions, as discussed above. Other features and properties of the lower epitaxial source/drain regions 108L and the upper epitaxial source/drain regions 108U2 also apply.

Further, as illustrated, the lower epitaxial source/drain regions 108L may be larger in the UFET region 50U than in the CFET region 50C, because the middle semiconductor nanostructures 66M are used. It is also noted that, in some embodiments, the lower epitaxial source/drain regions 108L in the UFET region 50U may merge vertically with the upper epitaxial source/drain regions 108U2.

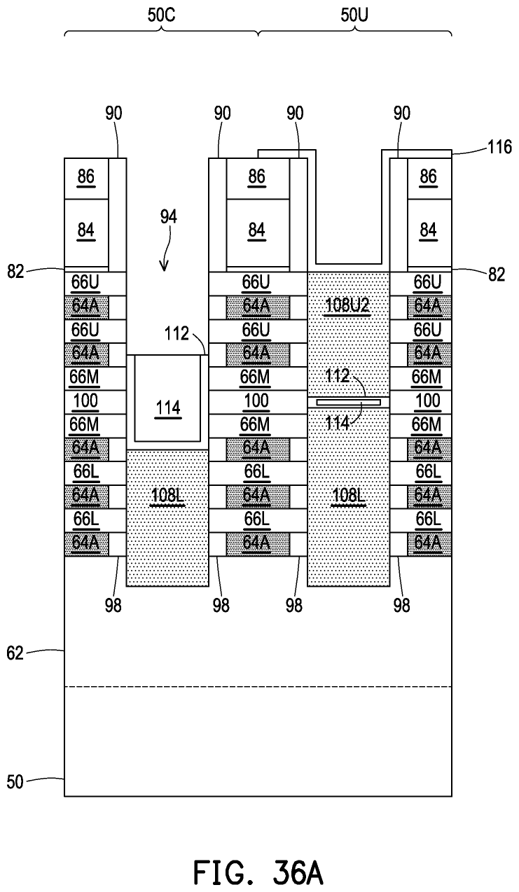

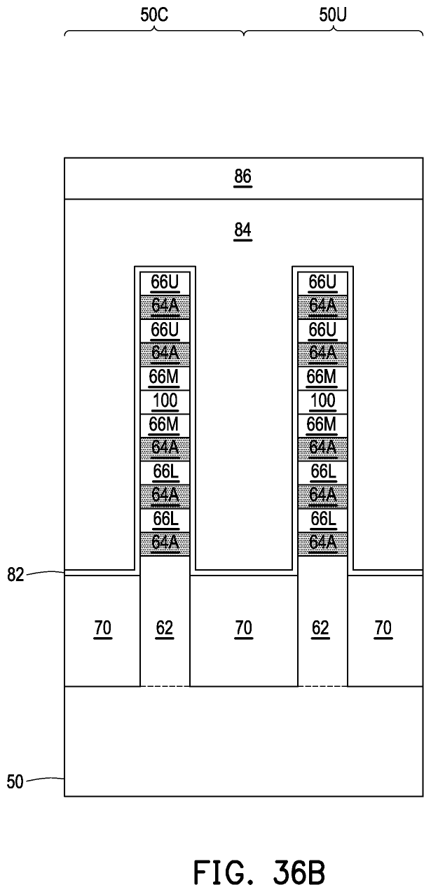

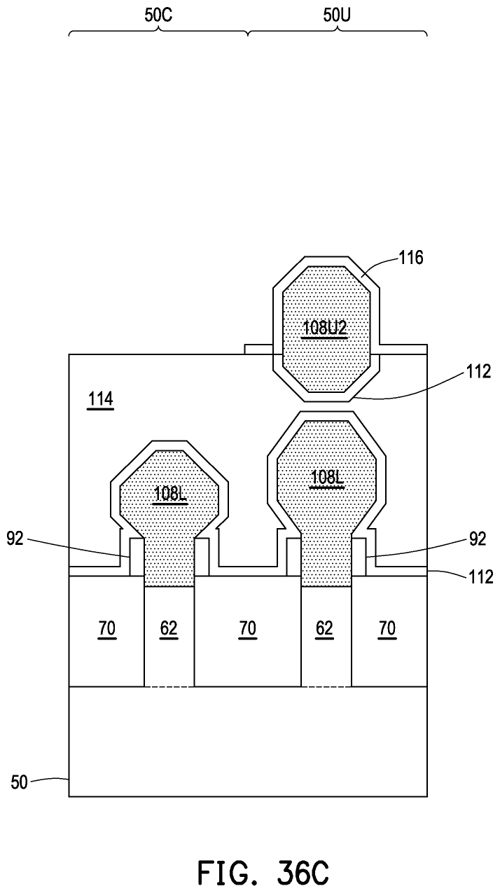

In FIGS. 36A-36B, following the formation of the lower epitaxial source/drain regions 108L and the upper epitaxial source/drain regions 108U2, the dummy spacers 104 may be removed using processes and similar to those described above with respect to the dummy spacers 104 of other embodiments.

Next, the first ILD 114 is formed and recessed. The first CESL 112 may also be formed and recessed between the first ILD 114 and the lower epitaxial source/drain regions 108L and between the first ILD 114 and the side structures, such as the inner spacers 98, the isolation structure 100, the semiconductor nanostructures 66, and the gate spacers 90. The first ILD 114 and first CESL 112 may be formed using processes and materials similar to those discussed above, for example, with respect to FIGS. 27A-27C. Following the formation of the first ILD 114 and first CESL 112, the first ILD 114 and first CESL 112 may be recessed to expose the upper semiconductor nanostructures 66U in the CFET region 50C. The recessing of the first ILD 114 and first CESL 112 may be performed using processes and materials similar to those discussed above with respect to FIGS. 28A-28C.

Still referring to FIG. 36A-36C, a blocking liner 116 is formed over the UFET region 50U while the CFET region 50C is exposed. The blocking liner 116 may be formed using processes and materials similar to those discussed above with respect to FIGS. 29A-29C. Notably, a portion of the first CESL 112 remains disposed beneath the upper epitaxial source/drain regions 108U2.

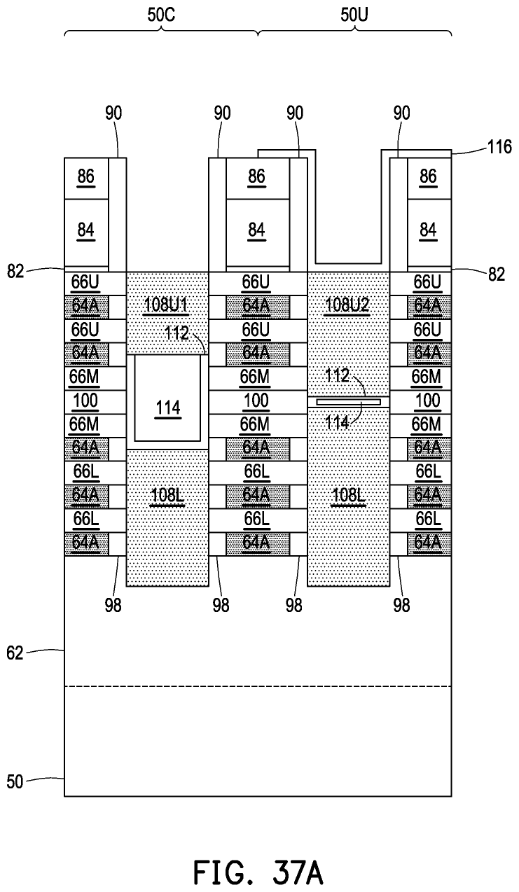

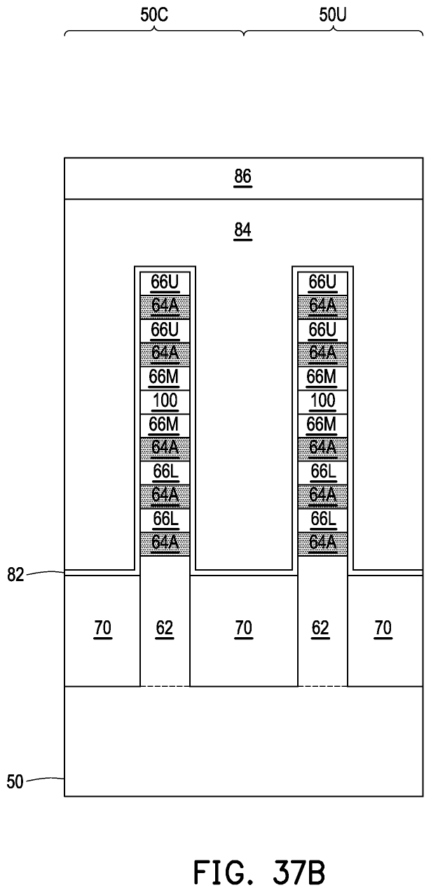

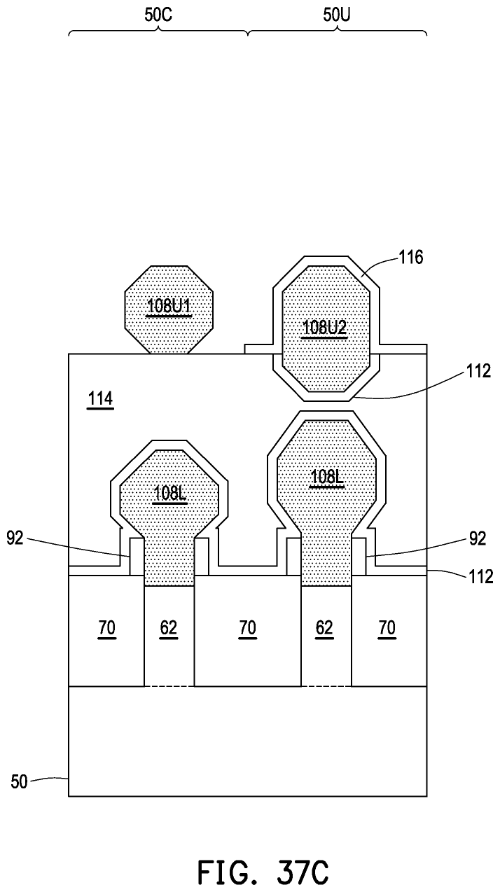

In FIGS. 37A-37C, the upper epitaxial source/drain regions 108U1 are formed in the upper portions of the source/drain recesses 94 in the CFET region 50C. The blocking liner 116, on the other hand, prevents growth from occurring in the UFET region 50U. The upper epitaxial source/drain regions 108U1 only partially fill the source/drain recesses 94, such that the upper epitaxial source/drain regions 108U1 are in contact with the upper semiconductor nanostructures 66U and are not in contact with the lower semiconductor nanostructures 66L. The first ILD 114 may provide isolation between the upper epitaxial source/drain regions 108U1 and the lower epitaxial source/drain regions 108L. The upper epitaxial source/drain regions 108U1 may be grown using materials and processes discussed above, which are not repeated. It should be noted, however, that in the CFET region 50C only the upper semiconductor nanostructures 66U are exposed, thus growth will be from those. In some embodiments, the first ILD 114 and the first CESL 112 may optionally be further reduced to expose portions of the middle semiconductor nanostructures 66M, which would result in growth therefrom and potentially larger upper epitaxial source/drain regions 108U1. The upper epitaxial source/drain regions 108U1 may include doping, as discussed above. Also, they may have respective facets, and exert compressive or tensile force on the channel regions, as discussed above. Other features and properties of the upper epitaxial source/drain regions 108U1 also apply.

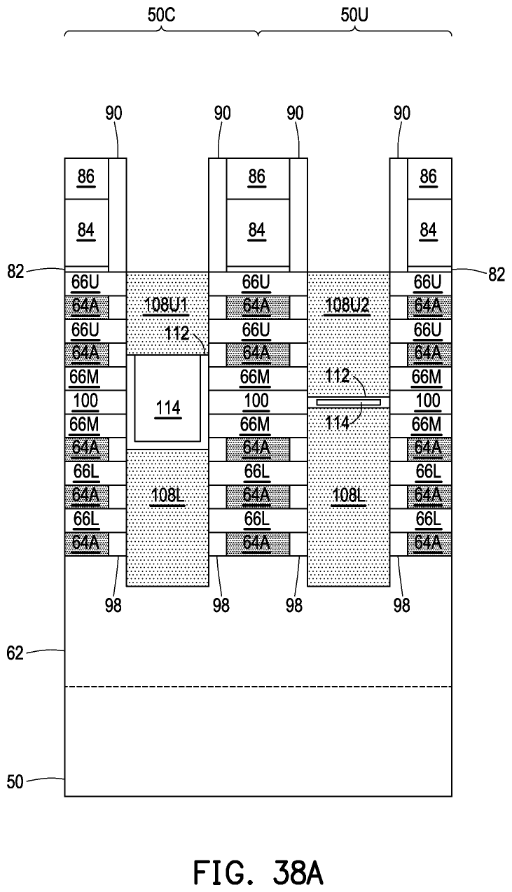

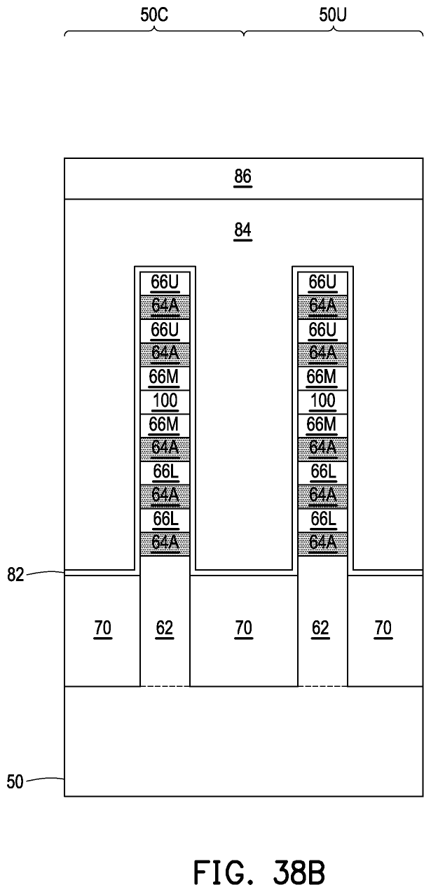

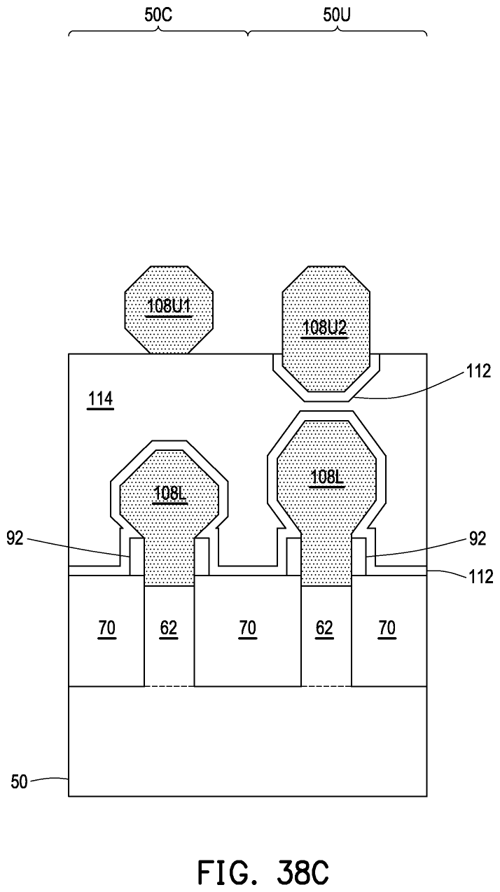

In FIGS. 38A-38C, the blocking liner 116 is removed from the source/drain recesses 94 in the UFET region 50U. Processes and materials similar to those discussed above with respect to FIGS. 31A-31C may be used to remove the blocking liner 116.

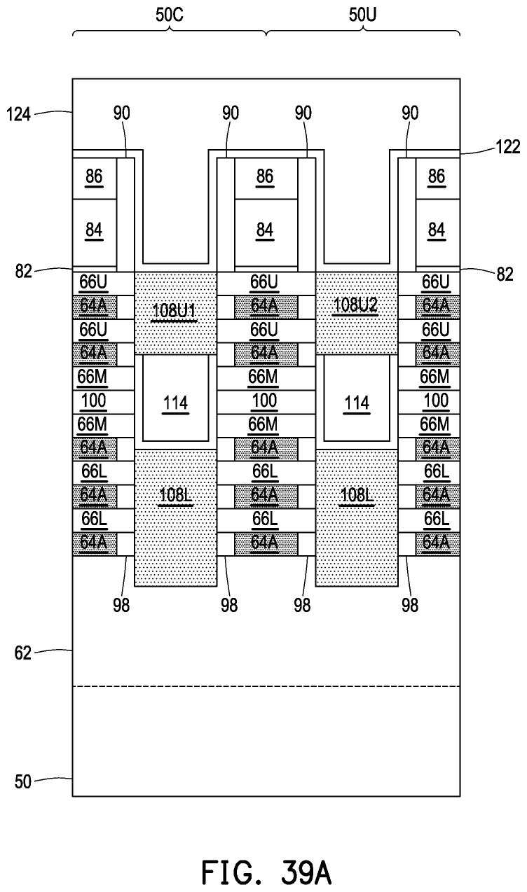

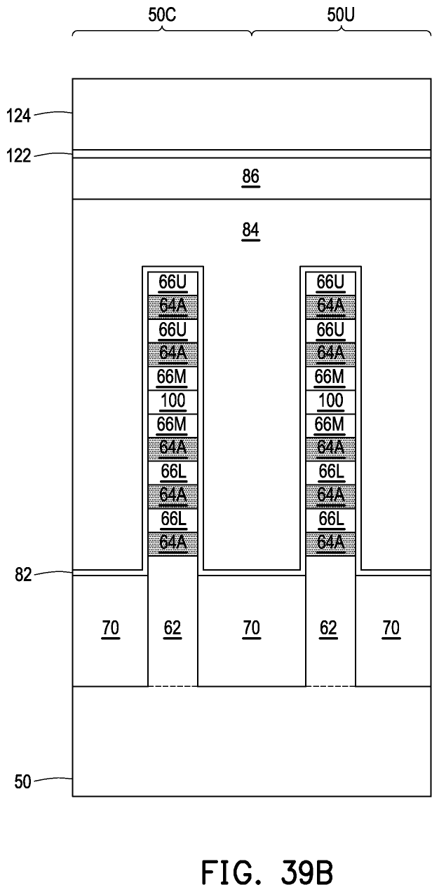

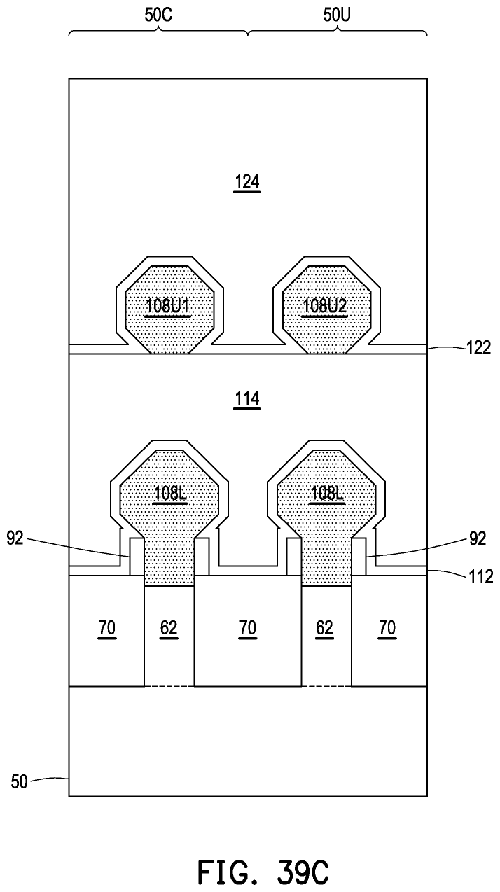

FIGS. 39A-54C illustrate continuing processes on the structures of FIG. 18A-18C, 31A-31C, or 38A-38C. The portion of the first CESL 112 beneath the upper epitaxial source/drain regions 108U2 of FIGS. 31A-31C is not specifically illustrated, however, it can be substituted in the illustrated embodiments as appropriate. Similarly, the larger upper epitaxial source/drain regions 108U2 of FIGS. 38A-38C are not specifically illustrated, however, they can be substituted in the illustrated embodiments as appropriate.

In FIGS. 39A-39C, a second ILD 124 is deposited over the upper epitaxial source/drain regions 108U, the first ILD 114, the gate spacers 90, and the masks 86 (if present) or the dummy gates 84. The second ILD 124 may be formed of a dielectric material, which may be deposited by any suitable method, such as CVD, plasma-enhanced chemical vapor deposition (PECVD), or FCVD. Dielectric materials may include phospho-silicate glass (PSG), boro-silicate glass (BSG), boron-doped phospho-silicate glass (BPSG), undoped silicate glass (USG), or the like. Other dielectric materials formed by any acceptable process may be used.

In some embodiments, second CESL 122 is formed between the second ILD 124 and the upper epitaxial source/drain regions 108U, the first ILD 114, the gate spacers 90, and the masks 86 (if present) or the dummy gates 84. The second CESL 122 may be formed of a dielectric material having a high etching selectivity to the dielectric material of the second ILD 124, such as, silicon nitride, silicon oxide, silicon oxynitride, or the like, which may be formed by any suitable deposition process, such as CVD, ALD, or the like.

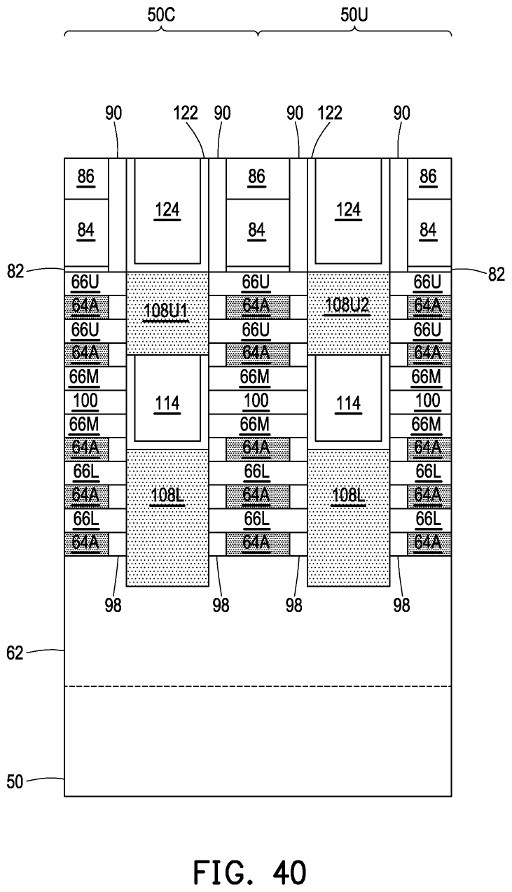

In FIG. 40, a removal process is performed to level the top surfaces of the second ILD 124 with the top surfaces of the gate spacers 90 and the masks 86 (if present) or the dummy gates 84. In some embodiments, a planarization process such as a chemical mechanical polish (CMP), an etch-back process, combinations thereof, or the like may be utilized. The planarization process may also remove the masks 86 on the dummy gates 84, and portions of the gate spacers 90 along sidewalls of the masks 86. After the planarization process, top surfaces of the second ILD 124, the gate spacers 90, and the masks 86 (if present) or the dummy gates 84 are substantially coplanar (within process variations). Accordingly, the top surfaces of the masks 86 (if present) or the dummy gates 84 are exposed through the second ILD 124. In the illustrated embodiment, the masks 86 remain after the removal process. In other embodiments, the masks 86 are removed such that the top surfaces of the dummy gates 84 are exposed through the second ILD 124.

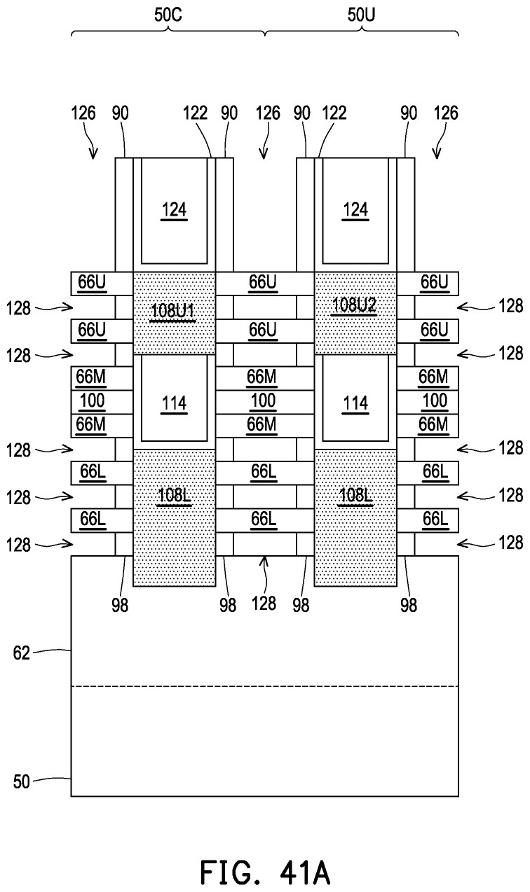

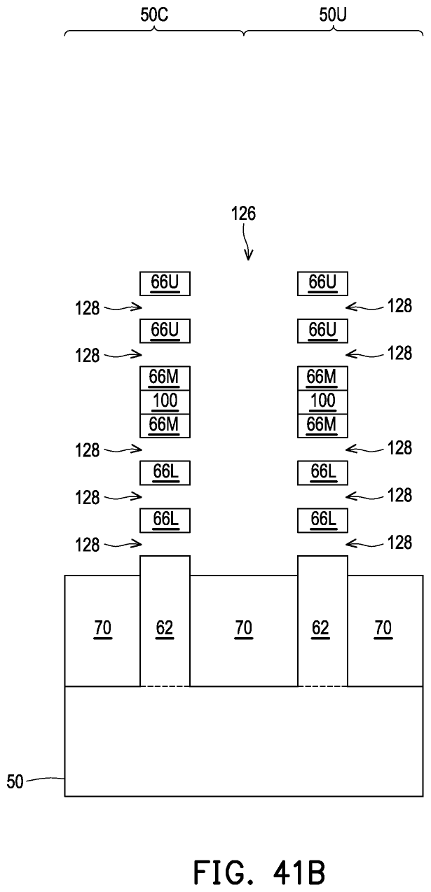

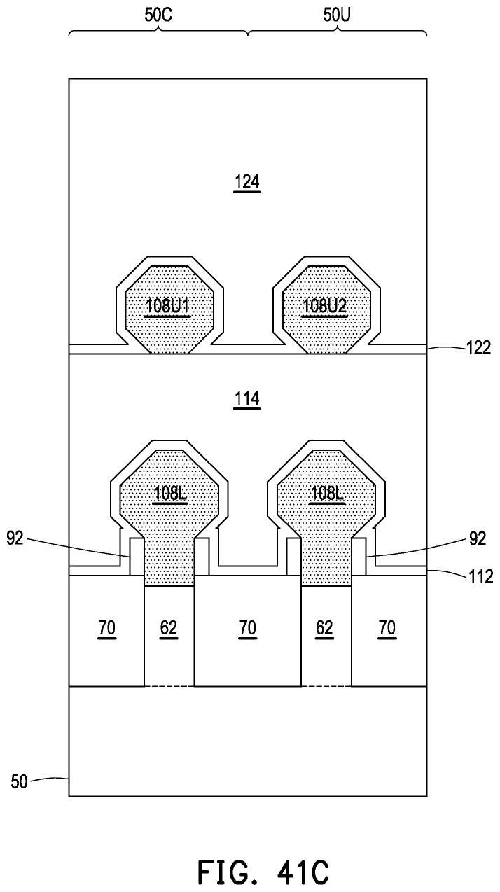

In FIGS. 41A-41C, the dummy gates 84 are removed in one or more etching steps, so that recesses 126 are formed between the gate spacers 90. Portions of the dummy dielectrics 82 in the recesses 126 are also removed. In some embodiments, the dummy gates 84 and the dummy dielectrics 82 are removed by an anisotropic dry etch process. For example, the etching process may include a dry etch process using reaction gas(es) that selectively etch the material of the dummy gates 84 at a faster rate than the materials of the second ILD 124, the isolation structures 100, the inner spacers 98, and the gate spacers 90. Each recesses 126 exposes and/or overlies portions of nanostructures 64, 66 which act as the channel regions in the resulting devices. The portions of the nanostructures 64, 66 which act as the channel regions are disposed between neighboring pairs of the lower epitaxial source/drain regions 108L or between neighboring pairs of the upper epitaxial source/drain regions 108U. During the removal, the dummy dielectrics 82 may be used as etch stop layers when the dummy gates 84 are etched. The dummy dielectrics 82 may then be removed after the removal of the dummy gates 84.

The remaining portions of the first dummy nanostructures 64A are then removed to form openings 128 in regions between the semiconductor nanostructures 66. The remaining portions of the first dummy nanostructures 64A can be removed by any acceptable etch process that selectively etches the material of the first dummy nanostructures 64A at a faster rate than the materials of the semiconductor nanostructures 66, the inner spacers 98, and the isolation structures 100. The etching may be isotropic. For example, when the first dummy nanostructures 64A are formed of silicon-germanium, the semiconductor nanostructures 66 are formed of silicon, the inner spacers 98 are formed of silicon oxycarbonitride, and the isolation structures 100 are formed of silicon oxycarbonitride, the etch process may be a wet etch using tetramethylammonium hydroxide (TMAH), ammonium hydroxide (NH₄OH), or the like. In some embodiments, a trim process (not separately illustrated) is performed to decrease the thicknesses of the exposed portions of the semiconductor nanostructures 66 and expand the openings 128.

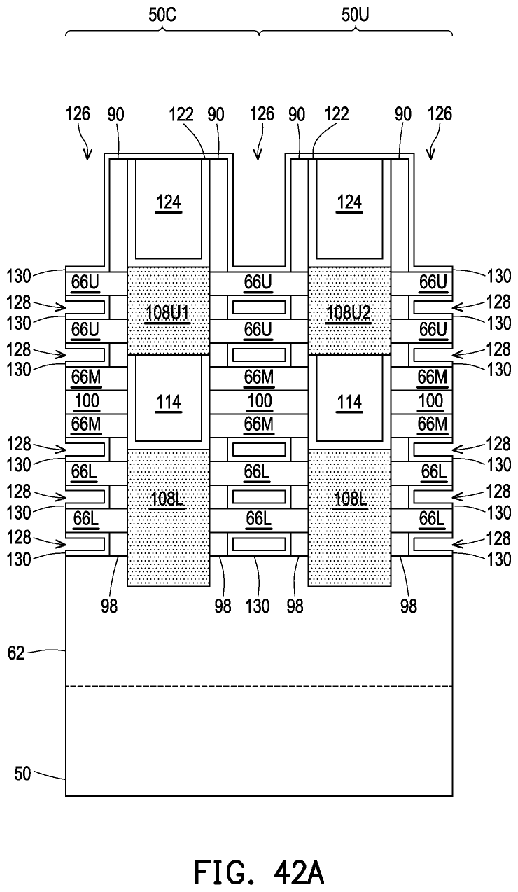

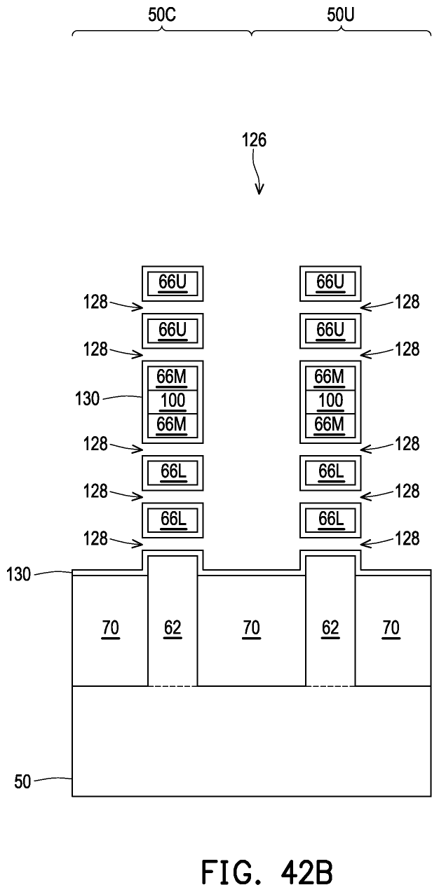

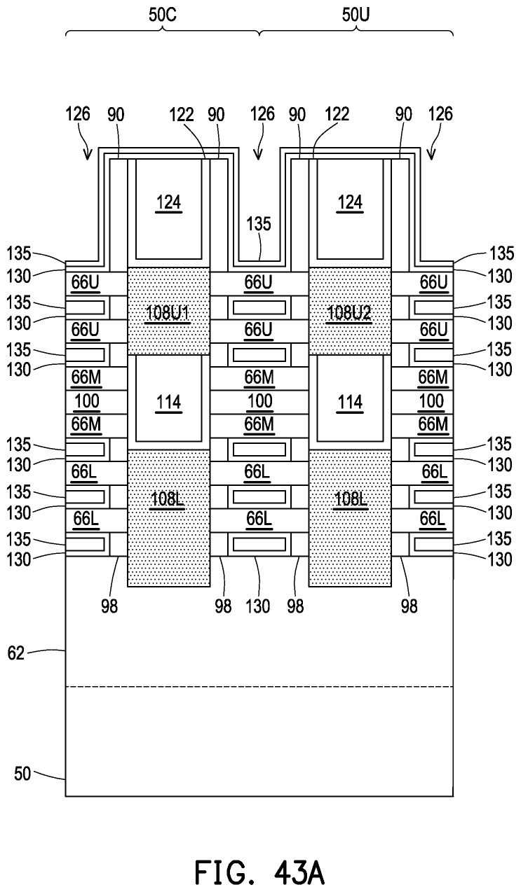

In FIGS. 42A-42B, a gate dielectric layer 130 is conformally formed on the channel regions of the semiconductor nanostructures 66, such that it conformally lines the recesses 126 and the openings 128. Specifically, the gate dielectric layer 130 is formed on the top surfaces of the fins 62; on the top surfaces, the sidewalls, and the bottom surfaces of the semiconductor nanostructures 66; and on the sidewalls of the gate spacers 90. The gate dielectric layer 130 wraps around all (e.g., four) sides of the semiconductor nanostructures 66. The gate dielectric layer 130 may also be formed on the top surfaces of the second ILD 124 and the gate spacers 90, and may be formed on the sidewalls of the fins 62 (e.g., in embodiments where the top surfaces of the isolation regions 70 are below the top surfaces of the fins 62). The gate dielectric layer 130 may include an oxide such as silicon oxide or a metal oxide, a silicate such as a metal silicate, combinations thereof, multi-layers thereof, or the like. The gate dielectric layer 130 may include a high-dielectric constant (high-k) material having a k-value greater than about 7.0, such as a metal oxide or a silicate of hafnium, aluminum, zirconium, lanthanum, manganese, barium, titanium, lead, and combinations thereof. The formation methods of the gate dielectric layer 130 may include molecular-beam deposition (MBD), ALD, PECVD, and the like. Although a single-layered gate dielectric layer 130 is illustrated, the gate dielectric layer 130 may include multiple layers, such as an interfacial layer and an overlying high-k dielectric layer.

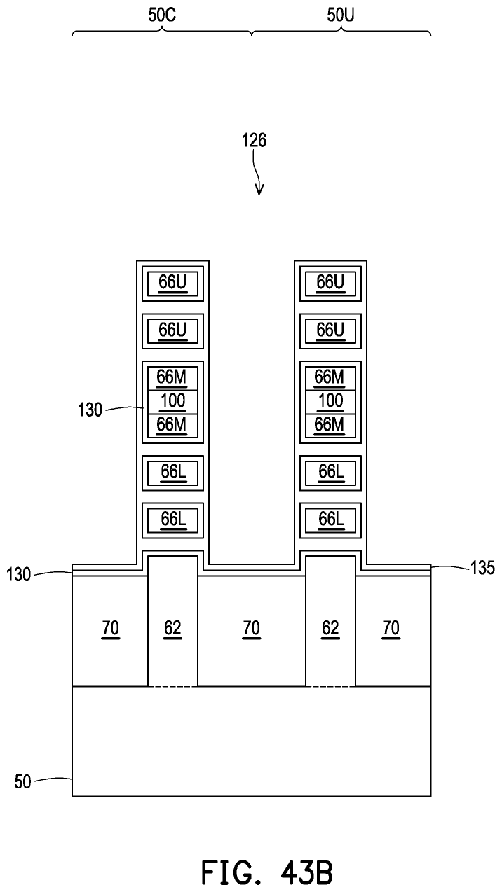

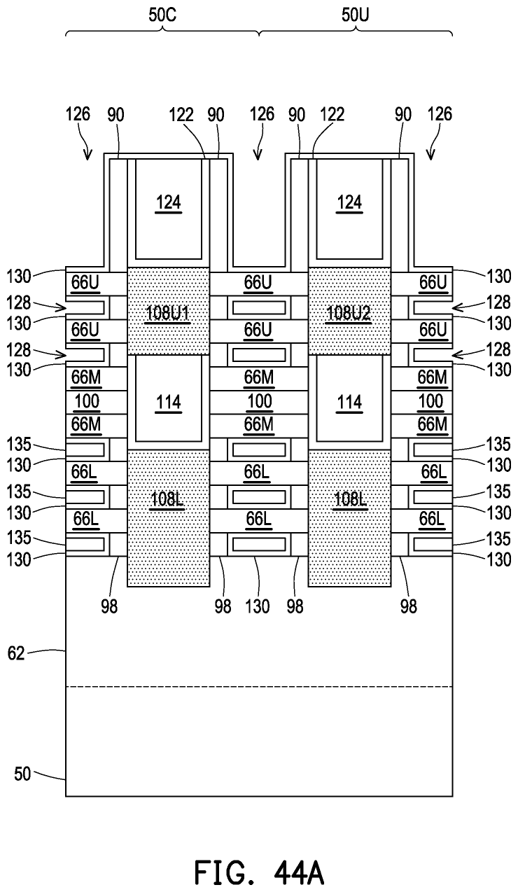

In FIGS. 43A-43B, a liner layer 135 is conformally deposited over the gate dielectric layer 130, and in the opening 128 between the semiconductor nanostructures 66. The liner layer 135 may be made of any suitable material. In an embodiment, the liner layer 135 may be a titanium nitride layer to provide etch selectivity to the other adjacent material layers. Alternative materials, such as dielectric materials, may be used so long as they have good etch selectivity to the gate dielectric layer 130 and subsequently deposited structures which contact the liner layer 135. The deposition of the liner layer 135 may be by CVD, ALD, the like, or combinations thereof.

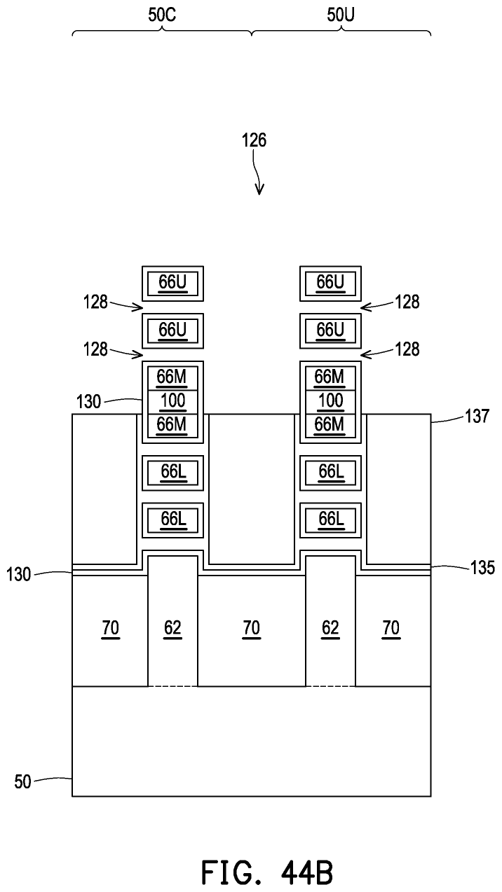

In FIGS. 44A-44B, a dummy gate electrode 137 is formed on the liner layer 135 and in the lower portion of the recesses 126. The dummy gate electrode 137 may be formed of any suitable dielectric material, such as silicon oxide, silicon nitride, silicon oxynitride, silicon carbide, the like, or combinations thereof. The dummy gate electrode 137 may be deposited by CVD or another suitable process. Following the deposition of the liner layer 135, an etch back process may be used to recess the dummy gate electrode 137 so that an upper surface of the dummy gate electrode 137 is disposed adjacent the isolation structure 100. The liner layer 135 can serve as a protection layer to protect the upper portions of the temporary fins during the etch back process. The etch back process may utilize any suitable etching techniques such as a wet or dry etch. Following the etch back process, the exposed portions of the liner layer 135 may be removed, by another etch process with an etchant suitable to etch titanium nitride.

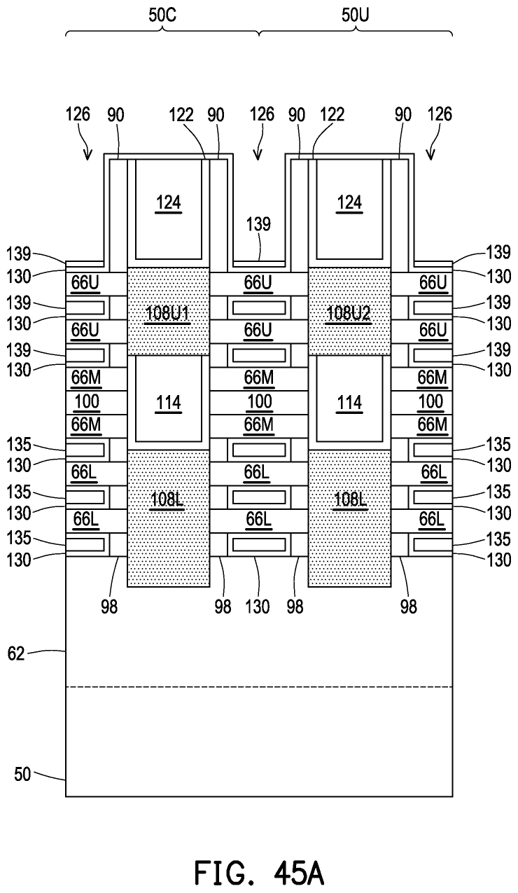

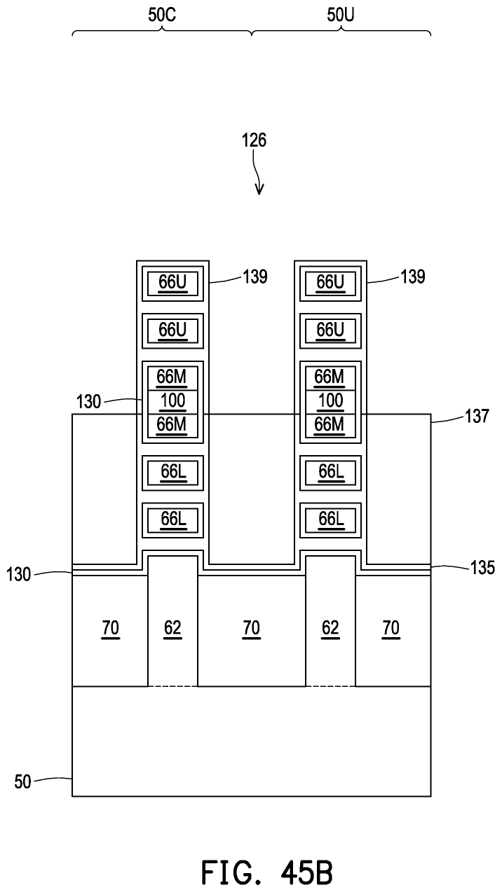

In FIGS. 45A-45B, a protection layer 139 may be conformally deposited over the exposed portions of the gate dielectric layer 130 and around the upper semiconductor nanostructures 66U. The protection layer 139 provides a conformal liner to temporarily mask some of the upper semiconductor nanostructures 66U. The protection layer 139 may be made of any suitable material. In an embodiment, the protection layer 139 may be an amorphous silicon layer to provide etch selectivity to the other adjacent material layers. Alternative materials, such as dielectric materials, may be used so long as they have good etch selectivity to the gate dielectric layer 130 and subsequently deposited structures which contact the protection layer 139. The deposition of the protection layer 139 may be by CVD, ALD, the like, or combinations thereof. Following deposition of the protection layer 139, an anisotropic etch back process may be used to recess portions of the protection layer 139 in the recesses 126.

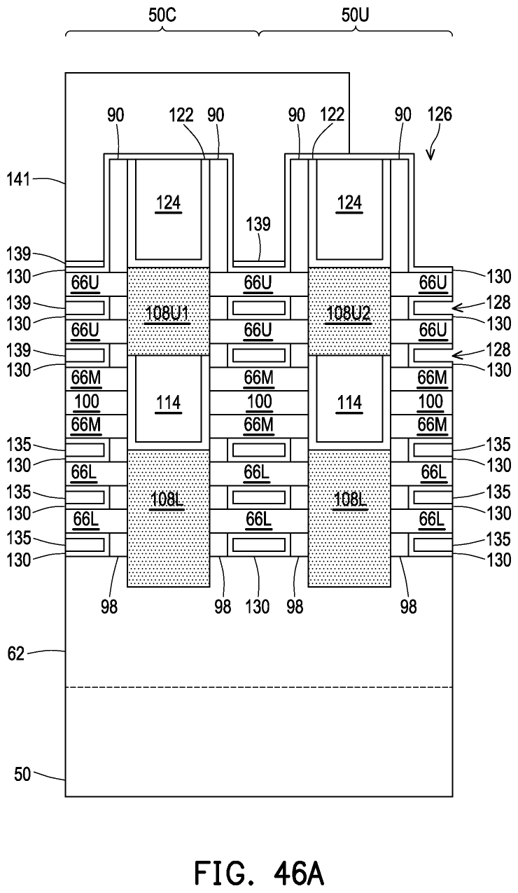

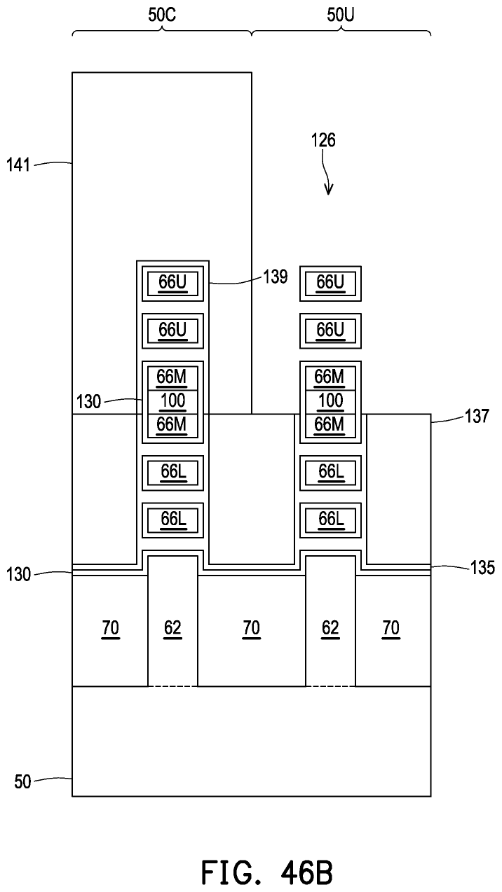

In FIGS. 46A-46B, a photoresist 141 is formed over the upper epitaxial source/drain regions 108U1 of the CFET region 50C and over a portion of the dummy gate electrode 137 in the CFET region 50C. The photoresist 141 may be formed by a spin on process or other suitable process, patterned, and developed to expose the UFET region 50U. After exposing the UFET region 50U, the exposed protection layer 139 may be removed from the UFET region 50U, for example, by an etch back process.

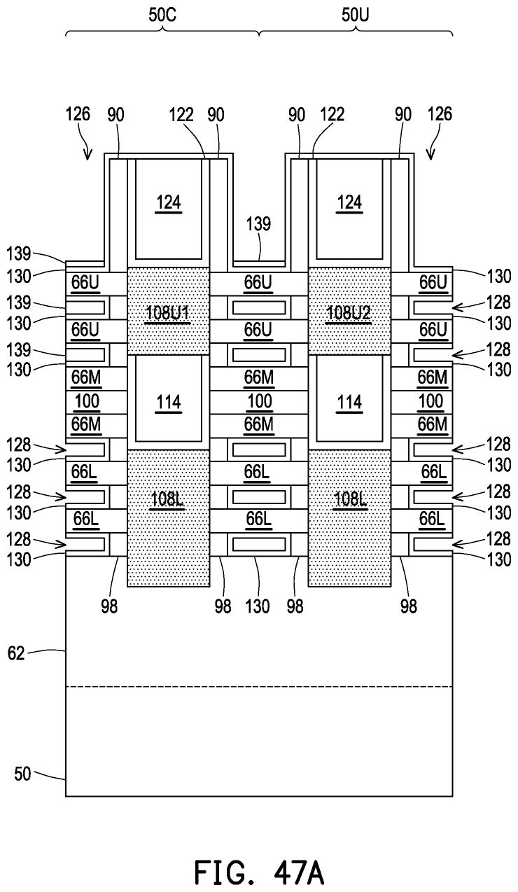

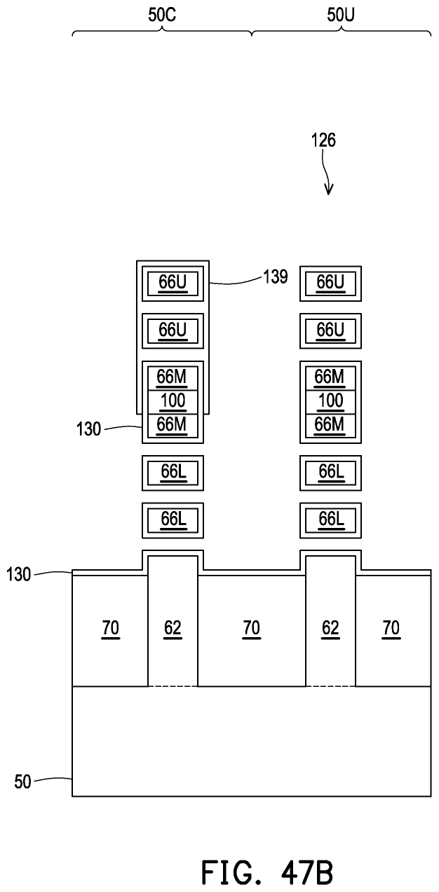

In FIGS. 47A-47B, the photoresist 141 may be removed, for example, by a suitable ashing technique. Then, the dummy gate electrode 137 and liner layer 135 may be removed by a suitable etching technique. In the CFET region 50C, the protection layer 139 remains around the upper semiconductor nanostructures 66U so that an appropriate electrode may be formed for that structure in a subsequent step.

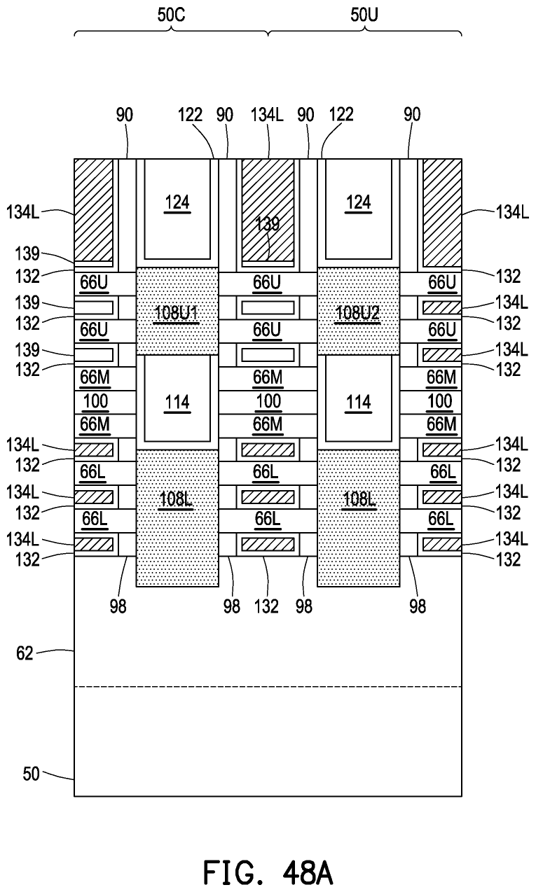

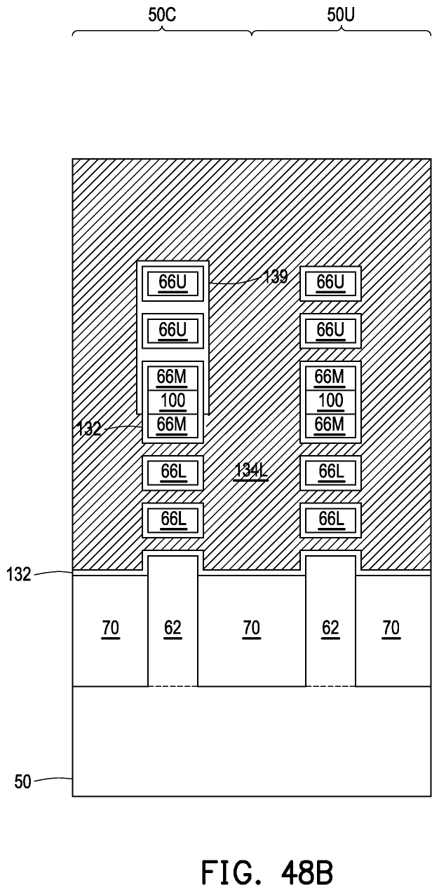

In FIGS. 48A-48B, lower gate electrodes 134L are formed on the gate dielectric layer 130 (see FIGS. 47A-47B) and the protection layer 139. The lower gate electrodes 134L are disposed in the lower portions of the recesses 126 and in the openings 128 between the lower semiconductor nanostructures 66L. Also, the lower gate electrodes 134L match the conductivity for the UFET region 50U. Accordingly, the lower gate electrodes 134L wrap around the upper semiconductor nanostructures 66U in the UFET region 50U and around the lower semiconductor nanostructures 66L in the CFET region 50C and in the UFET region 50U. Although the lower gate electrodes 134L surround the protection layer 139, this portion will be removed in a subsequent process.

The lower gate electrodes 134L may be formed of a metal-containing material such as tungsten, titanium, titanium nitride, tantalum, tantalum nitride, tantalum carbide, aluminum, ruthenium, cobalt, combinations thereof, multi-layers thereof, or the like. Although single-layered gate electrodes are illustrated, the lower gate electrodes 134L may include any number of work function tuning layers, any number of barrier layers, any number of glue layers, and a fill material.

The lower gate electrodes 134L are formed of material(s) that are suitable for the device type of the lower nanostructure-FETs. For example, the lower gate electrodes 134L may include one or more work function tuning layer(s) formed of work function tuning metal(s) that are suitable for the device type of the lower nanostructure-FETs and UFETs. In some embodiments, the lower gate electrodes 134L include an n-type work function tuning layer, which may be formed of titanium aluminum, titanium aluminum carbide, tantalum aluminum, tantalum carbide, combinations thereof, or the like. In some embodiments, the lower gate electrodes 134L include a p-type work function tuning layer, which may be formed of titanium nitride, tantalum nitride, combinations thereof, or the like. Additionally or alternatively, the lower gate electrodes 134L may include a dipole-inducing element that is suitable for the device type of the lower nanostructure-FETs. Acceptable dipole-inducing elements include lanthanum, aluminum, scandium, ruthenium, zirconium, erbium, magnesium, strontium, and combinations thereof. The lower gate electrodes 134L may be formed by conformally depositing one or more gate electrode layer(s) in the recesses 126 and in the openings 128.

Optionally, a removal process is performed to form gate dielectrics 132 and to level the top surfaces of the gate dielectrics 132 with the top surfaces of the gate spacers 90, the second ILD 124, and the lower gate electrodes 134L. The gate dielectric layer 130, after the removal process, has portions left in the recesses 126 and in the openings 128 (thus forming the gate dielectrics 132). In some embodiments, a planarization process such as a chemical mechanical polish (CMP), an etch-back process, combinations thereof, or the like may be utilized. After the planarization process, the top surfaces of the lower gate electrodes 134L, the gate dielectrics 132, the second ILD 124, and the gate spacers 90 are substantially coplanar (within process variations).

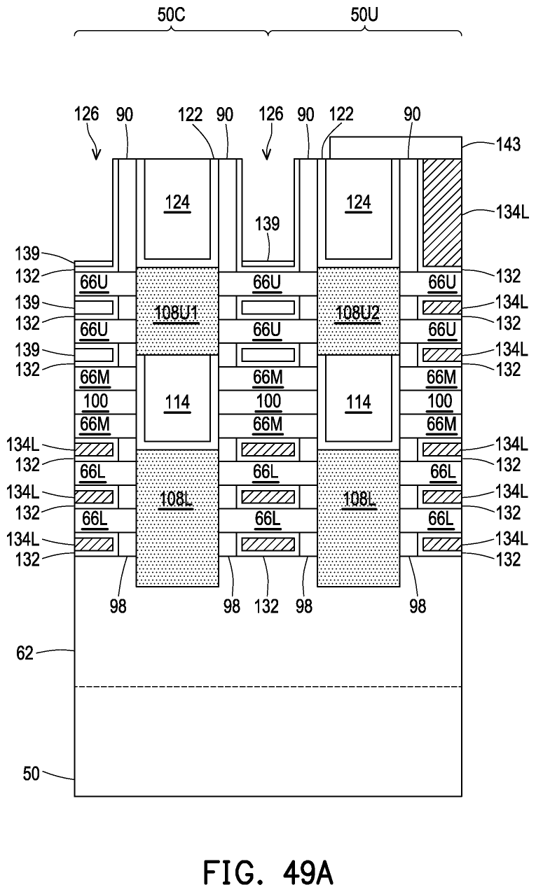

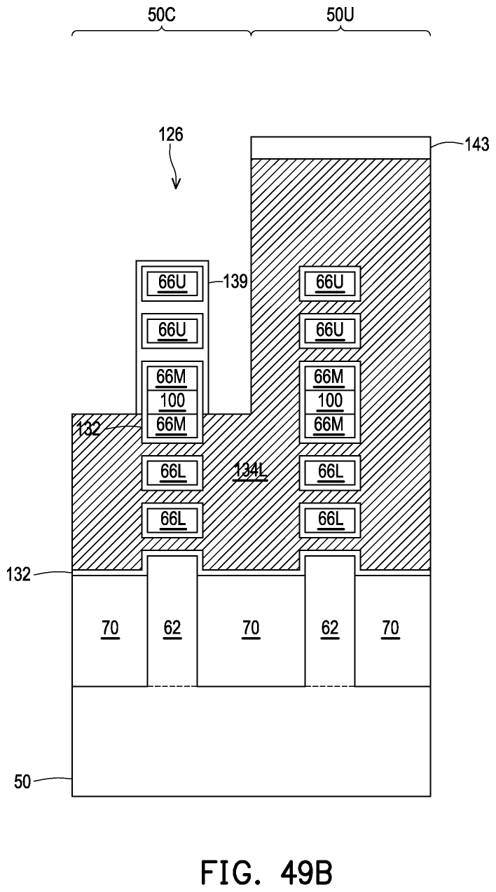

In FIG. 49A-49B, a photoresist mask 143 is formed over a portion of the lower gate electrodes 134L in the UFET region 50U. The photoresist mask 143 may be formed by spin on, patterned, and developed to leave a portion over the lower gate electrodes 134L in the UFET region 50U. Next, the gate electrodes 134L are recessed where exposed from the photoresist mask 143 (e.g., in the CFET region 50C). Any acceptable etch process, such as a dry etch, a wet etch, the like, or a combination thereof, may be performed to recess the gate electrodes 134L. The etching may be anisotropic, such as an etch-back process that removes the gate electrodes 134L from the upper portions of the recesses 126. The upper portion of the CFET region 50C is protected by the protection layer 139 during the etching.

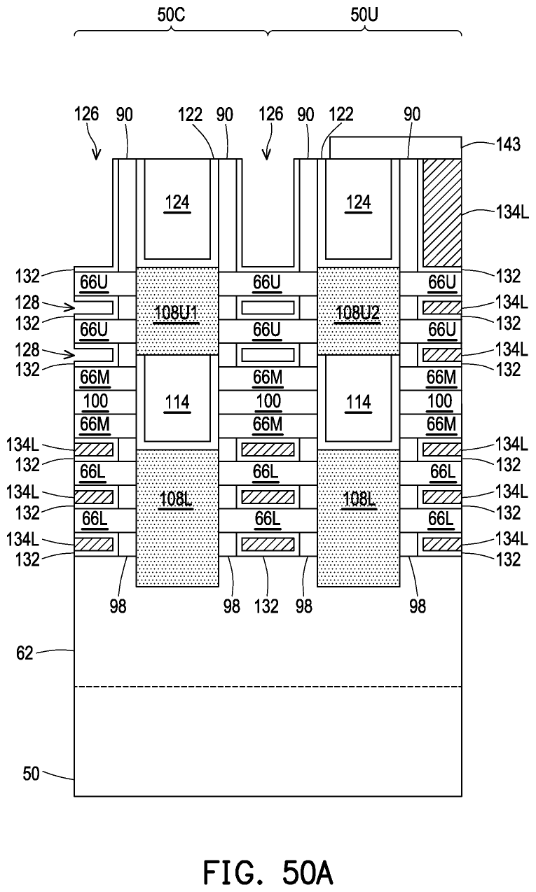

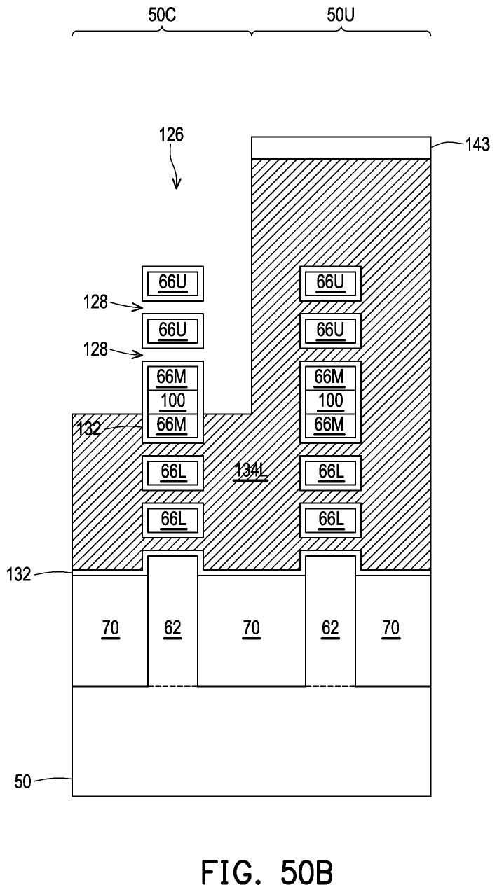

In FIGS. 50A-50B, the protection layer 139 is removed from the exposed upper portion of the CFET region 50C. The protection layer 139 may be removed utilizing any suitable etching techniques, such as the respective techniques discussed above.

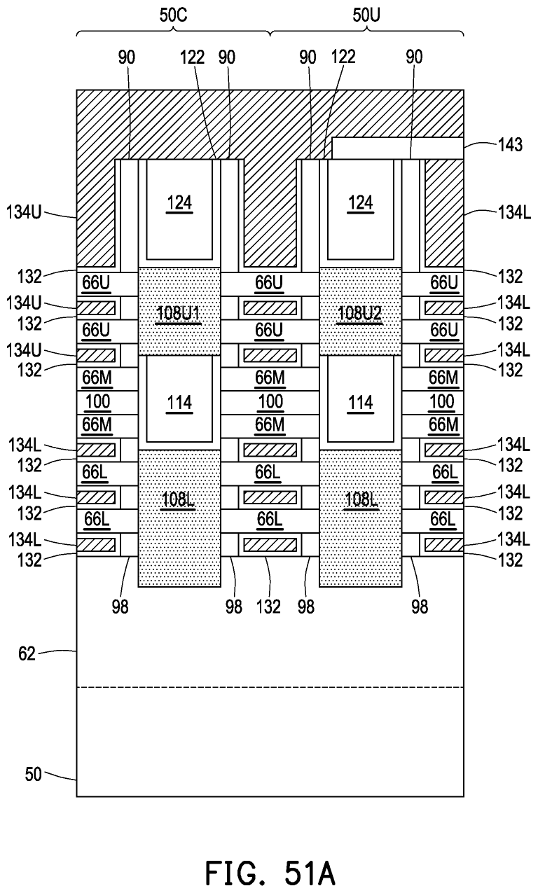

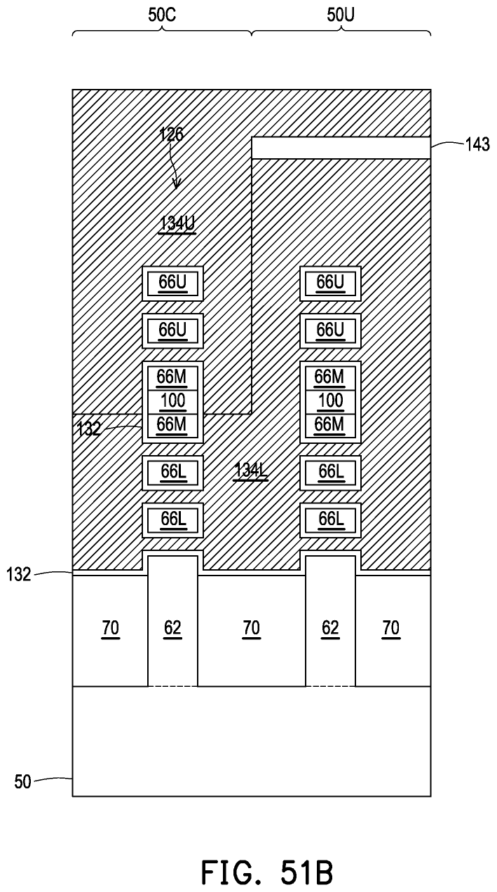

In FIGS. 51A-51B, upper gate electrodes 134U are formed on the lower gate electrodes 134L. The upper gate electrodes 134U are disposed in the upper portions of the recesses 126 in the CFET region 50C and in the openings 128 between the upper semiconductor nanostructures 66U. Accordingly, the upper gate electrodes 134U wrap around the upper semiconductor nanostructures 66U in the CFET region 50C. The upper gate electrodes 134U may be formed of a metal-containing material such as tungsten, titanium, titanium nitride, tantalum, tantalum nitride, tantalum carbide, aluminum, ruthenium, cobalt, combinations thereof, multi-layers thereof, or the like. Although single-layered gate electrodes are illustrated, the upper gate electrodes 134U may include any number of work function tuning layers, any number of barrier layers, any number of glue layers, and a fill material.

The upper gate electrodes 134U are formed of material(s) that are suitable for the device type of the upper nanostructure-FETs. For example, the upper gate electrodes 134U may include one or more work function tuning layer(s) formed of work function tuning metal(s) that are suitable for the device type of the upper nanostructure-FETs. In some embodiments, the upper gate electrodes 134U include an n-type work function tuning layer, which may be formed of titanium aluminum, titanium aluminum carbide, tantalum aluminum, tantalum carbide, combinations thereof, or the like. In some embodiments, the upper gate electrodes 134U include a p-type work function tuning layer, which may be formed of titanium nitride, tantalum nitride, combinations thereof, or the like. The work function tuning metal(s) of the upper gate electrodes 134U may be different than the work function tuning metal(s) of the lower gate electrodes 134L. Additionally or alternatively, the upper gate electrodes 134U may include a dipole-inducing element that is suitable for the device type of the upper nanostructure-FETs. Acceptable dipole-inducing elements include lanthanum, aluminum, scandium, ruthenium, zirconium, erbium, magnesium, strontium, and combinations thereof. The dipole-inducing elements the upper gate electrodes 134U may be different than the dipole-inducing elements of the lower gate electrodes 134L. The lower gate electrodes 134L may be formed by conformally depositing one or more gate electrode layer(s) in the recesses 126 and in the openings 128.

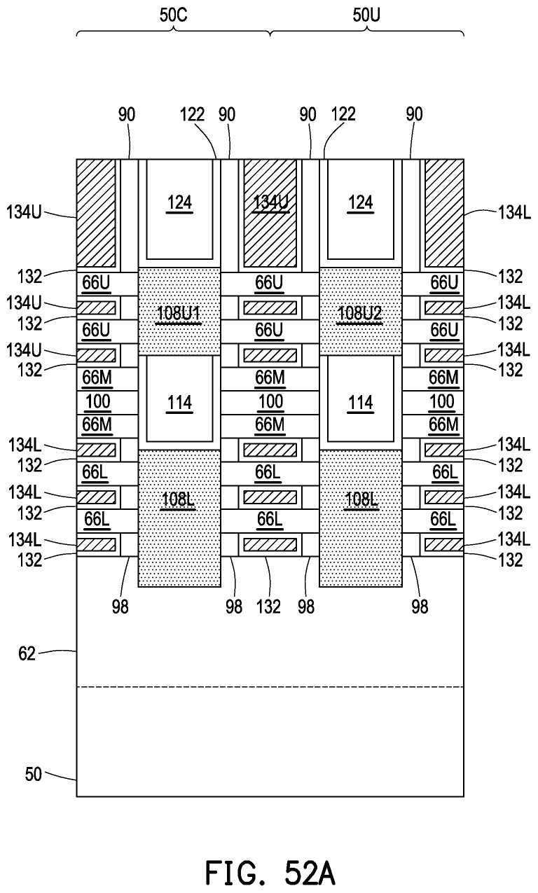

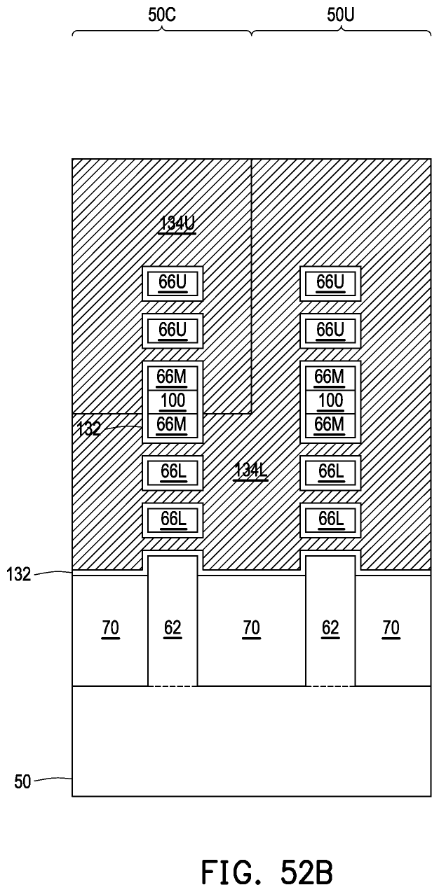

In FIGS. 52A-52B, a removal process is performed to remove the excess portions of the upper gate electrodes 134U, which excess portions are over the top surfaces of the gate spacers 90 and the second ILD 124. In some embodiments, a planarization process such as a chemical mechanical polish (CMP), an etch-back process, combinations thereof, or the like is utilized.

Each respective pair of a gate dielectric 132 and a gate electrode 134 (including an upper gate electrode 134U and/or a lower gate electrode 134L) may be collectively referred to as a “gate structure.” Each gate structure extends along three sides (e.g., a top surface, a sidewall, and a bottom surface) of a channel region of a semiconductor nanostructure 66. The gate structures may also extend along sidewalls and/or a top surface of a fin 62.

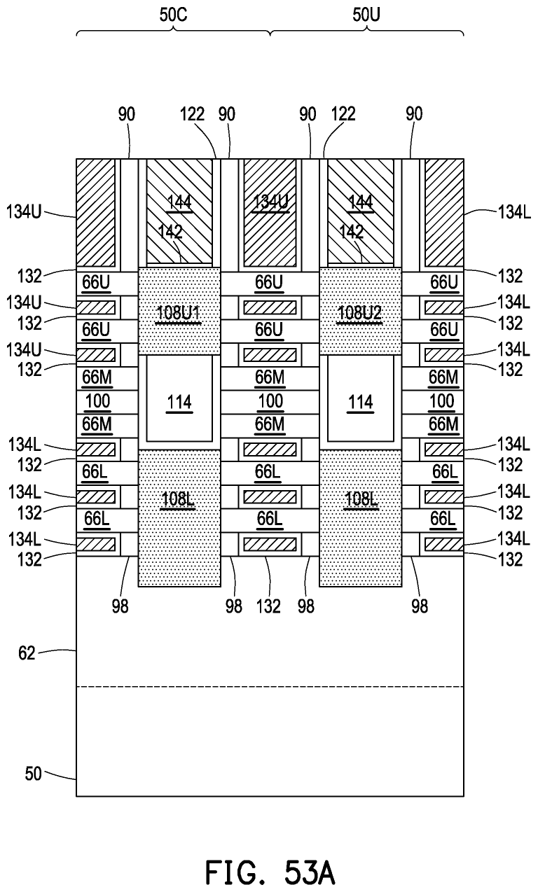

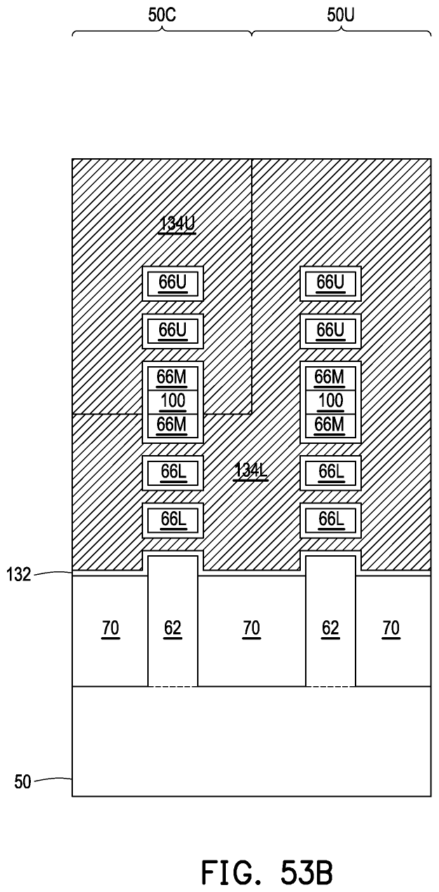

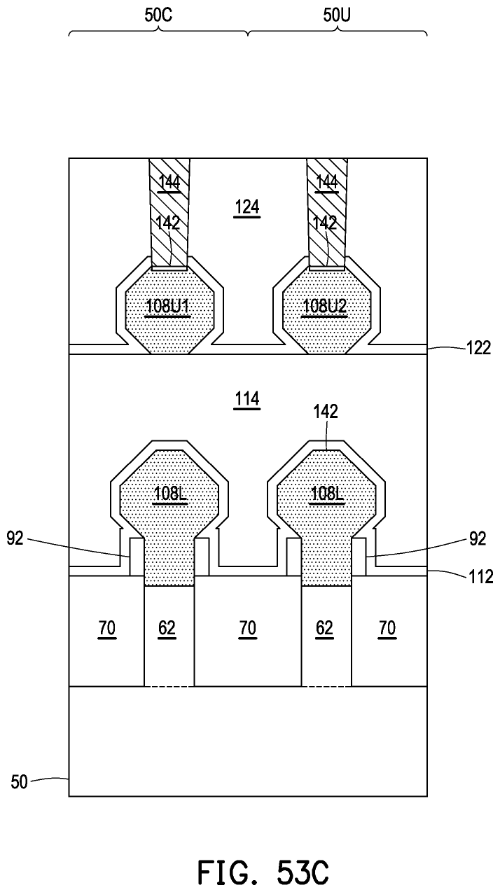

In FIGS. 53A-53C, source/drain contacts 144 are formed for the source/drain regions 108. The source/drain contacts 144 may be physically and electrically coupled to the upper epitaxial source/drain regions 108U.

As an example to form the source/drain contacts 144, openings for the source/drain contacts 144 are formed through the second ILD 124 and the second CESL 122. The openings may be formed using acceptable photolithography and etching techniques. In the illustrated embodiment, the openings are formed by a self-aligned contact (SAC) process. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A removal process may be performed to remove excess material from the top surfaces of the gate spacers 90 and the second ILD 124. The remaining liner and conductive material form the source/drain contacts 144 in the openings. In some embodiments, a planarization process such as a chemical mechanical polish (CMP), an etch-back process, combinations thereof, or the like is utilized. After the planarization process, the top surfaces of the gate spacers 90, the second ILD 124, the upper gate electrodes 134U, and the source/drain contacts 144 are substantially coplanar (within process variations).

Optionally, metal-semiconductor alloy regions 142 are formed at the interfaces between the upper epitaxial source/drain regions 108U and the source/drain contacts 144. The metal-semiconductor alloy regions 142 can be silicide regions formed of a metal silicide (e.g., titanium silicide, cobalt silicide, nickel silicide, etc.), germanide regions formed of a metal germanide (e.g. titanium germanide, cobalt germanide, nickel germanide, etc.), silicon-germanide regions formed of both a metal silicide and a metal germanide, or the like. The metal-semiconductor alloy regions 142 can be formed before the material(s) of the source/drain contacts 144 by depositing a metal in the openings for the source/drain contacts 144 and then performing a thermal anneal process. The metal can be any metal capable of reacting with the semiconductor materials (e.g., silicon, silicon-germanium, germanium, etc.) of the upper epitaxial source/drain regions 108U to form a low-resistance metal-semiconductor alloy, such as nickel, cobalt, titanium, tantalum, platinum, tungsten, other noble metals, other refractory metals, rare earth metals or their alloys. The metal can be deposited by a deposition process such as ALD, CVD, PVD, or the like. After the thermal anneal process, a cleaning process, such as a wet clean, may be performed to remove any residual metal from the openings for the source/drain contacts 144, such as from surfaces of the metal-semiconductor alloy regions 142. The material(s) of the source/drain contacts 144 can then be formed on the metal-semiconductor alloy regions 142.

In the illustrated embodiment, the source/drain contacts 144 are coupled to the upper epitaxial source/drain regions 108U. In another embodiment (not separately illustrated), some of the source/drain contacts 144 are shared source/drain contacts that are coupled to both the upper epitaxial source/drain regions 108U and the lower epitaxial source/drain regions 108L. For example, a shared source/drain contact may be formed through an upper epitaxial source/drain region 108U, the first ILD 114, and the first CESL 112 to be coupled to a lower epitaxial source/drain region 108L. When forming such a shared source/drain contact, the opening for the shared source/drain contact may also be formed through an upper epitaxial source/drain region 108U, the first ILD 114, and the first CESL 112; additionally, a metal-semiconductor alloy region 142 may be formed on a sidewall of the upper epitaxial source/drain region 108U.

In FIGS. 54A-54C, a third ILD 154 is deposited over the gate spacers 90, the second ILD 124, the upper gate electrodes 134U, and the source/drain contacts 144. In some embodiments, the third ILD 154 is a flowable film formed by a flowable CVD method, which is subsequently cured. In some embodiments, the third ILD 154 is formed of a dielectric material such as PSG, BSG, BPSG, USG, or the like, which may be deposited by any suitable method, such as CVD, PECVD, or the like.

In some embodiments, an etch stop layer (ESL) 152 is formed between the third ILD 154 and the gate spacers 90, the second ILD 124, the upper gate electrodes 134U, and the source/drain contacts 144. The ESL 152 may include a dielectric material having a high etching selectivity to the dielectric material of the third ILD 154, such as silicon nitride, silicon oxide, silicon oxynitride, or the like.

Gate contacts 156 and source/drain vias 158 are formed through the third ILD 154 to contact, respectively, the upper gate electrodes 134U and the source/drain contacts 144. The gate contacts 156 may be physically and electrically coupled to the upper gate electrodes 134U. The source/drain vias 158 may be physically and electrically coupled to the source/drain contacts 144.

As an example to form the gate contacts 156 and the source/drain vias 158, openings for the gate contacts 156 and the source/drain vias 158 are formed through the third ILD 154 and the ESL 152. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A planarization process, such as a CMP, may be performed to remove excess material from the top surface of the third ILD 154. The remaining liner and conductive material form the gate contacts 156 and the source/drain vias 158 in the openings. The gate contacts 156 and the source/drain vias 158 may be formed in distinct processes, or may be formed in the same process. Although shown as being formed in the same cross-section, it should be appreciated that each of the gate contacts 156 and the source/drain vias 158 may be formed in different cross-sections, which may avoid shorting of the contacts.

The active devices as illustrated are collectively referred to as a device layer. In some embodiments, contacts to the lower gate electrodes 134L and the lower epitaxial source/drain regions 108L may be made through a backside of the device layer (e.g., a side opposite to the source/drain contacts 144).

Embodiments may achieve advantages. By utilizing a unipolar stacked FET and complementary stacked FET in a same device, embodiments can utilize more of the available area for active transistor use. For example, in SRAM the ratio of the number of single N/P transistors to CMOS transistors to SRAM I/O is about 1:2:(3-4.5). Thus, by utilizing more of the stacked transistors as unipolar for the single N/P transistors and for the SRAM I/O, then a space savings may be achieved between about 40-50%.

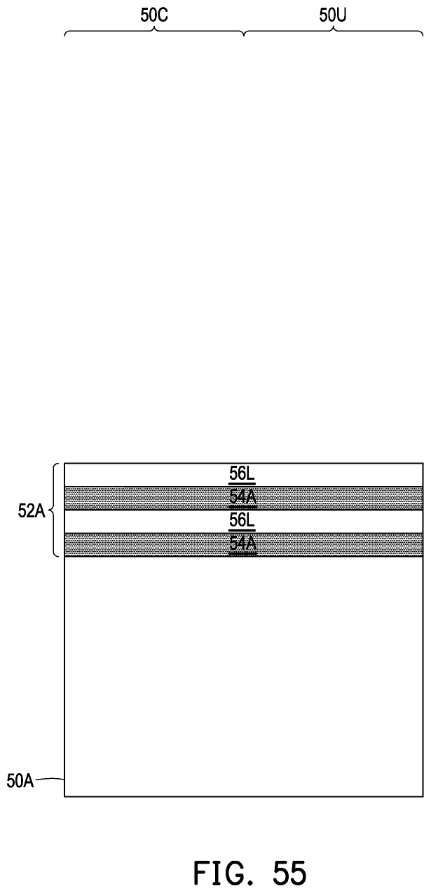

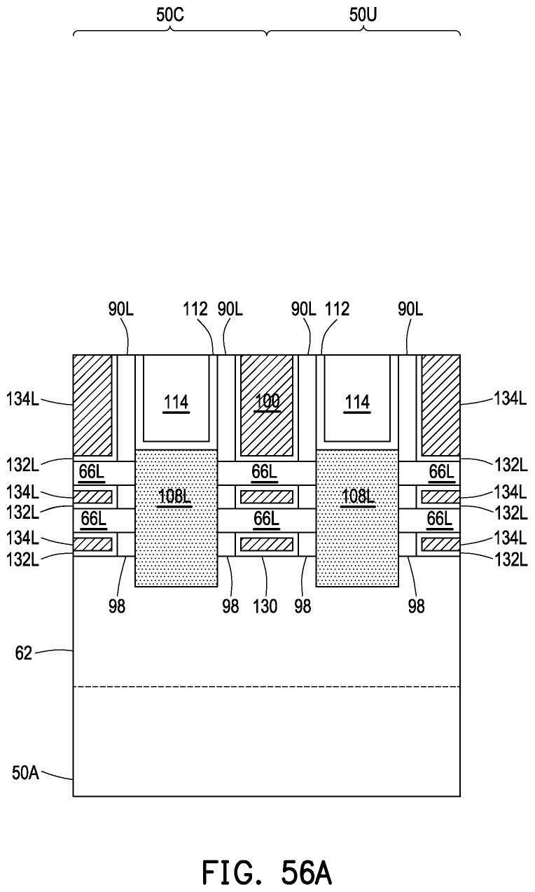

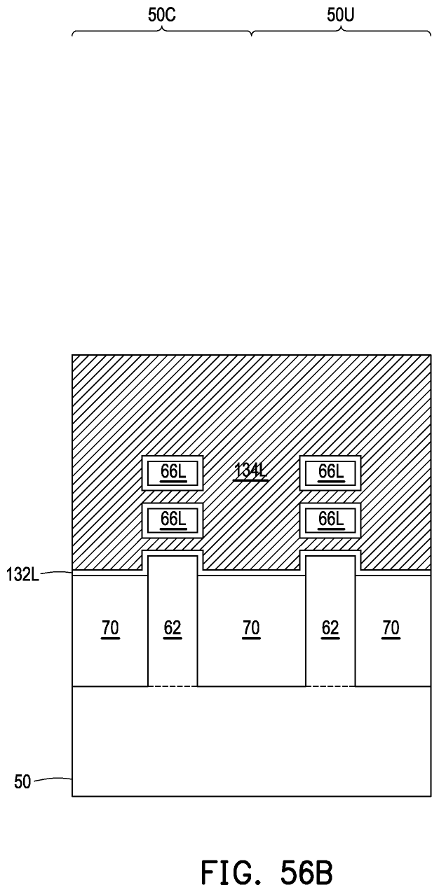

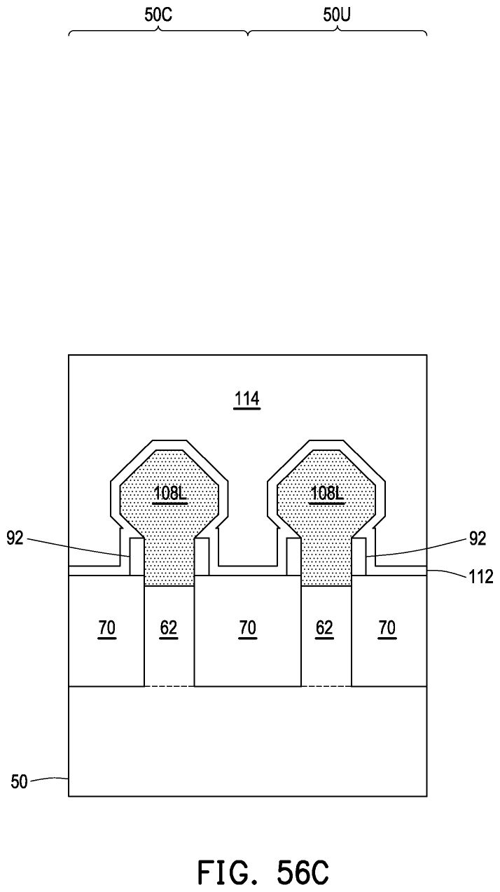

FIGS. 55-59C are views of intermediate stages in the manufacturing of CFETs and UFETs, in accordance with some other embodiments. In this embodiment, the lower nanostructure-FETs may be first formed. The upper nanostructure-FETs may then be formed over the lower nanostructure-FETs. FIGS. 55, 56A, 57A, 58A, and 59A illustrate cross-sectional views along a similar cross-section as reference cross-section A-A′ in FIGS. 1A-1B. FIGS. 56B, 57B, 58B, and 59B illustrate cross-sectional views along a similar cross-section as reference cross-section B-B′ in FIGS. 1A-1B. FIGS. 56C, 57C, 58C, and 59C illustrate cross-sectional views along a similar cross-section as reference cross-section C-C′ in FIGS. 1A-1B.

In FIG. 55, a first substrate 50A is provided. A first multi-layer stack 52A is formed over the first substrate 50A. The first multi-layer stack 52A includes first dummy layers 54A and lower semiconductor layers 56L. The first substrate 50A and the first multi-layer stack 52A may be formed in a similar manner as those previously described for FIG. 2.

In FIGS. 56A-56C, appropriate steps as discussed above are performed to form the lower nanostructure-FETs. Lower semiconductor nanostructures 66L are patterned from the lower semiconductor layers 56L. Lower epitaxial source/drain regions 108L are formed adjacent the lower semiconductor nanostructures 66L. Lower gate dielectrics 132L and lower gate electrodes 134L are formed around the lower semiconductor nanostructures 66L. A first ILD 114 is formed over the lower epitaxial source/drain regions 108L.

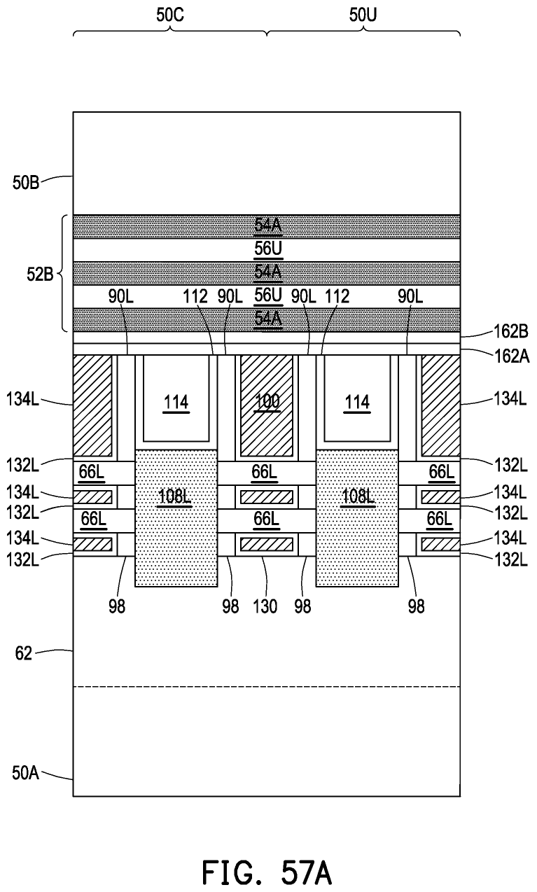

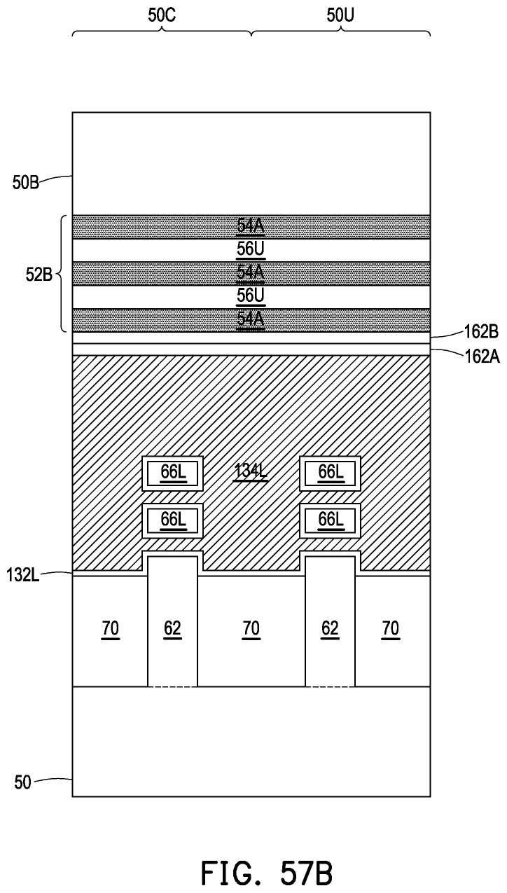

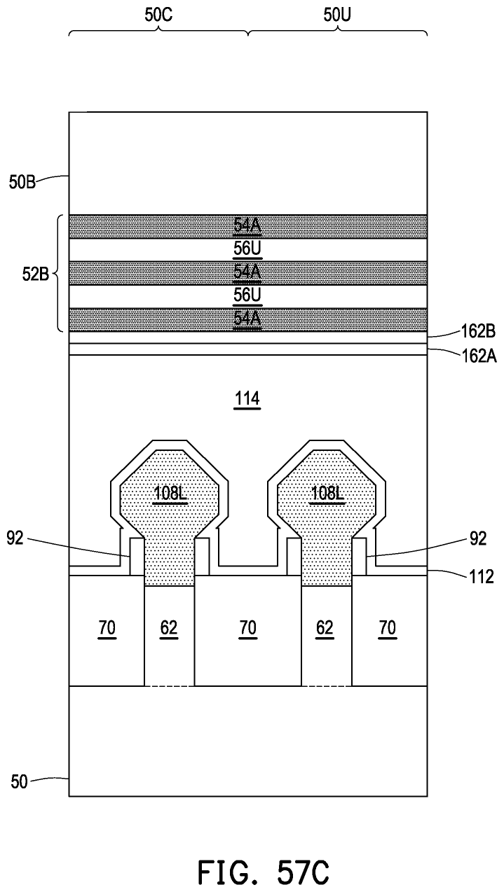

In FIGS. 57A-57C, a second substrate 50B is provided. A second multi-layer stack 52B is formed over the second substrate 50B. The second multi-layer stack 52B includes first dummy layers 54A and upper semiconductor layers 56U. The second substrate 50B and the second multi-layer stack 52B may be formed in a similar manner as those previously described for FIG. 2. The structure is then flipped, and the second multi-layer stack 52B is bonded to the structure shown in FIGS. 56A-56C.

One or more bonding layer(s) 162 may be used bond the structures to one another. For example, a first bonding layer 162A is formed over the first substrate 50A and a second bonding layer 162B is formed over the first substrate 50B. In some embodiments, the bonding layer(s) 162 are formed of silicon oxide (e.g., a high density plasma (HDP) oxide or the like) that is deposited by CVD, ALD, or the like. The bonding layer(s) 162 may likewise include oxide layers that are formed using, for example, CVD, ALD, thermal oxidation, or the like. Other suitable materials may be used for the bonding layer(s) 162.

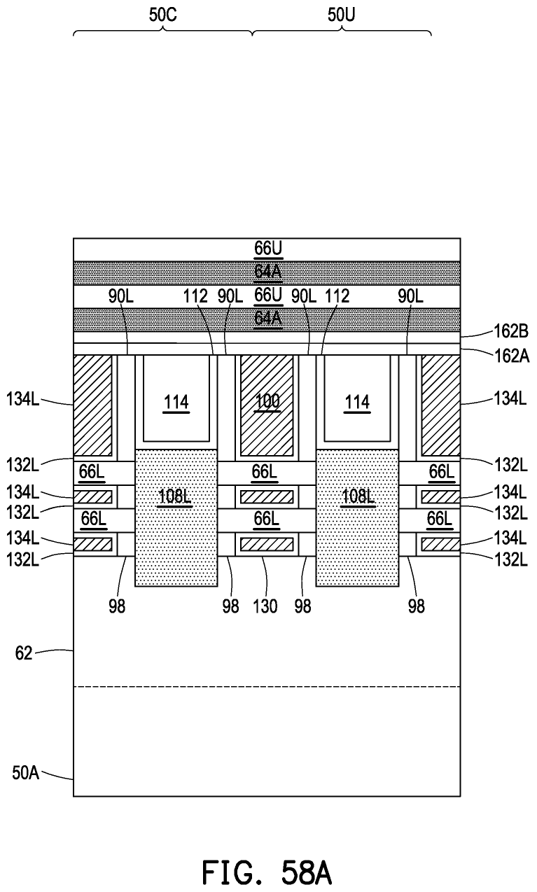

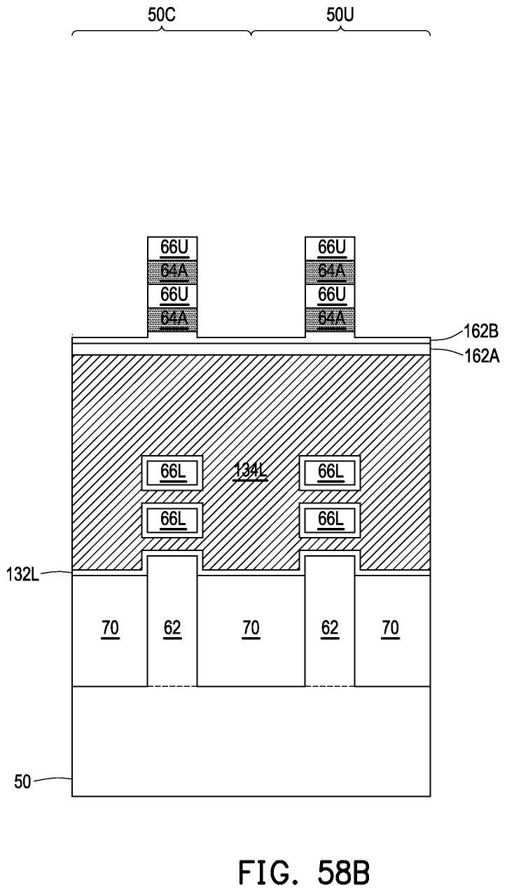

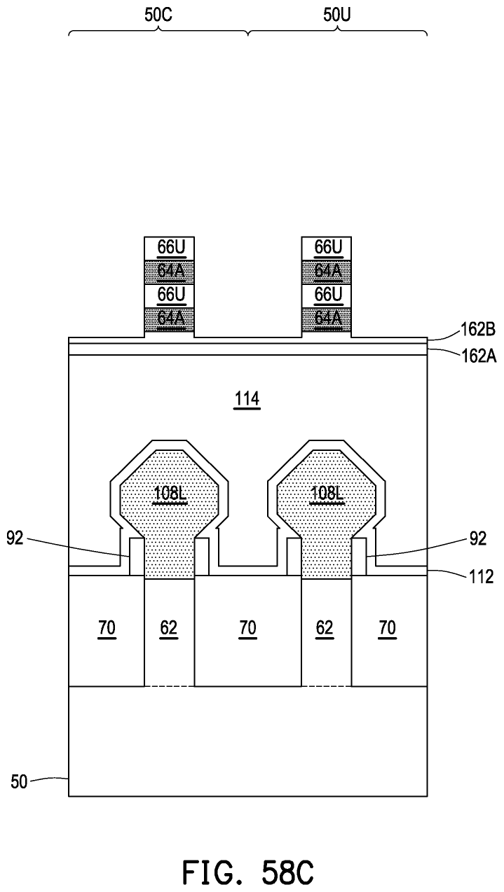

In FIGS. 58A-58C, upper semiconductor nanostructures 66U and first dummy nanostructures 64A are patterned in the second multi-layer stack 52B. The upper semiconductor nanostructures 66U and first dummy nanostructures 64A may be formed in a similar manner as those previously described for FIG. 3. The second substrate 50B may be removed before or after the patterning. One or more of the bonding layer(s) 162 may be etched during the patterning the upper semiconductor nanostructures 66U and first dummy nanostructures 64A.

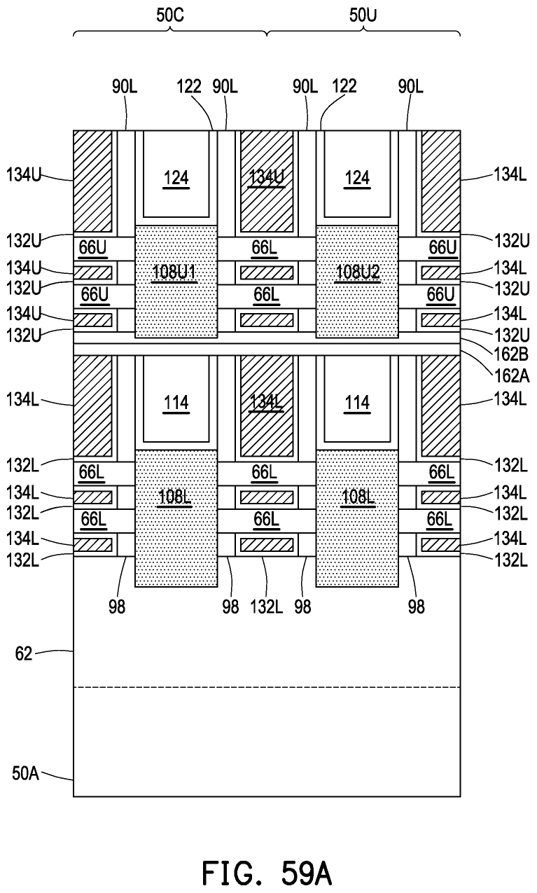

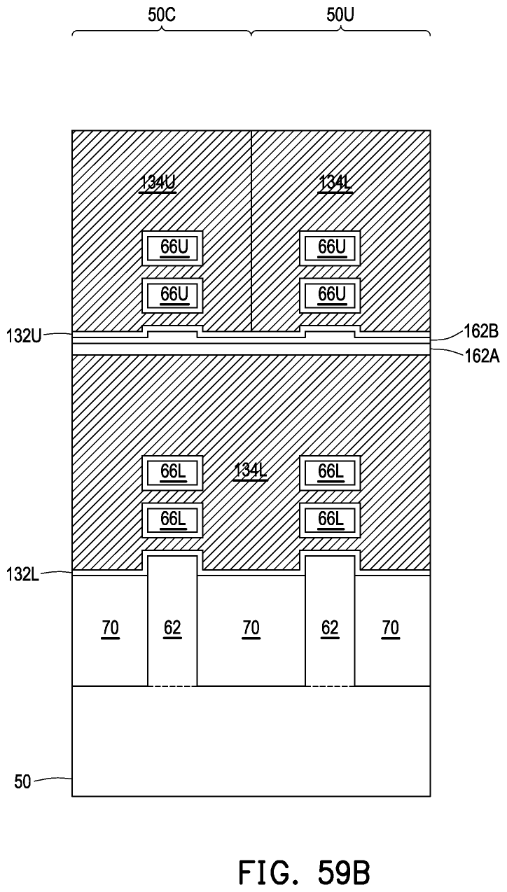

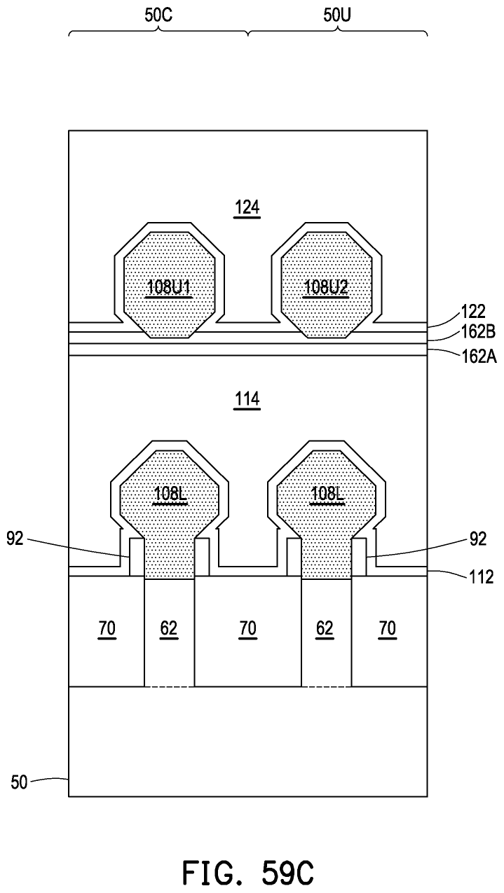

In FIGS. 59A-59C, appropriate steps as discussed above are performed to form the upper nanostructure-FETs. Upper epitaxial source/drain regions 108U are formed adjacent the upper semiconductor nanostructures 66U. Upper gate dielectrics 132U and upper gate electrodes 134U are formed around the upper semiconductor nanostructures 66U. A second ILD 124 is formed over the upper epitaxial source/drain regions 108U.

The upper nanostructure-FETs for UFETs and CFETS may be formed in the UFET region 50U and the CFET region 50C, respectively, using appropriate ones of the previously described processes. For example, the upper epitaxial source/drain regions 108U1 and the upper epitaxial source/drain regions 108U2 may be formed using any of the previously described masking and growing steps. Similarly, lower gate electrodes 134L may be formed for the upper nanostructure-FETs. Subsequently, appropriate steps as previously described may be performed to complete formation of the devices.

In the forgoing embodiments, the lower nanostructure-FETs have the same device type and the upper nanostructure-FETs have different device types. It should be appreciated that similar techniques as previously described could be utilized to form nanostructure-FETs that are stacked in an opposite manner than previously described. As a result, the upper nanostructure-FETs may have the same device type and the lower nanostructure-FETs may have different device types.

In an embodiment, a method includes: forming a fin extending vertically from a substrate, the fin including a lower semiconductor nanostructure, an upper semiconductor nanostructure, and a dummy semiconductor nanostructure disposed between the lower semiconductor nanostructure and the upper semiconductor nanostructure; etching a first recess and a second recess in the fin through the upper semiconductor nanostructure, the dummy semiconductor nanostructure, and the lower semiconductor nanostructure, the etching forming first sidewalls of the upper semiconductor nanostructure in the first recess and second sidewalls of the lower semiconductor nanostructure in the first recess, the etching forming third sidewalls of the upper semiconductor nanostructure in the second recess and fourth sidewalls of the lower semiconductor nanostructure in the second recess; replacing the dummy semiconductor nanostructure with a first isolation structure; growing a first lower semiconductor structure from the second sidewalls and a second lower semiconductor structure from the fourth sidewalls, the first lower semiconductor structure and second lower semiconductor structure having a first conductivity type; and growing a first upper semiconductor structure from the first sidewalls and a second upper semiconductor structure from the third sidewalls, the first upper semiconductor structure having a second conductivity type opposite the first conductivity type, the second upper semiconductor structure having the first conductivity type. In some embodiments of the method, growing the first lower semiconductor structure, the second lower semiconductor structure, and the second upper semiconductor structure occur at the same time. In some embodiments, the method further includes: forming the first upper semiconductor structure prior to forming the second upper semiconductor structure. In some embodiments, the method further includes: blocking the third sidewalls while growing the first upper semiconductor structure from the first sidewalls. In some embodiments, the method further includes: blocking the first sidewalls while growing the first lower semiconductor structure, the growing of the second lower semiconductor structure and the second upper semiconductor structure occurring at the same time. In some embodiments, the method further includes: removing a dummy gate that surrounds the upper semiconductor nanostructure and the lower semiconductor nanostructure; forming a gate dielectric surrounding the upper semiconductor nanostructure and the lower semiconductor nanostructure; forming a protection structure around the upper semiconductor nanostructure; depositing a first gate structure surrounding the lower semiconductor nanostructure and the protection structure; recessing the first gate structure to expose the protection structure; removing the protection structure; and depositing a second gate structure surrounding the upper semiconductor nanostructure. In some embodiments, the method further includes: masking a portion of the first gate structure prior to recessing the first gate structure, where the recessing of the first gate structure recesses an unmasked portion of the first gate structure; and depositing the second gate structure so that it is both vertically over the first gate structure and horizontally adjacent the first gate structure.

In an embodiment, a method includes: etching a first recess and a second recess in a fin-shaped multilayer semiconductor stack, each of the first recess and second recess segmenting the fin-shaped multilayer semiconductor stack into a plurality of nanostructures; growing a first source/drain region in the first recess from an exposed end of a first nanostructure of the plurality of nanostructures, the first source/drain region having a first conductivity type; growing a second source/drain region in the second recess from an exposed end of a second nanostructure of the plurality of nanostructures, the second source/drain region having the first conductivity type; growing a third source/drain region in the first recess from an exposed end of a third nanostructure of the plurality of nanostructures, the third source/drain region having the first conductivity type, the third source/drain region disposed directly over the first source/drain region; and growing a fourth source/drain region in the second recess from an exposed end of a fourth nanostructure of the plurality of nanostructures, the fourth source/drain region having a second conductivity type opposite the first conductivity type, the fourth source/drain region disposed directly over the second source/drain region. In some embodiments of the method, growing the first source/drain region and the second source/drain region occurs simultaneously. In some embodiments, the method further includes: after growing the first source/drain region, forming a first isolation structure over the first source/drain region; after forming the first isolation structure, blocking the third nanostructure, and growing the fourth source/drain region; and after growing the fourth source/drain region, blocking the fourth source/drain region, and growing the third source/drain region. In some embodiments of the method, growing the first source/drain region, the second source/drain region, and the third source/drain region occurs simultaneously. In some embodiments, the method further includes: after growing the first source/drain region, forming a first isolation structure over the first source/drain region, the second source/drain region, and the third source/drain region, the first isolation structure including a liner layer surrounding the third source/drain region, including a bottom surface of the third source/drain region, the first isolation structure covering the fourth nanostructure; recessing the first isolation structure to expose ends of the fourth nanostructure, a portion of the liner layer remaining disposed beneath the third source/drain region; growing the fourth source/drain region; and forming a second isolation structure over the third source/drain region and the fourth source/drain region, the portion of the liner layer remaining disposed beneath the third source/drain region. In some embodiments, the method further includes: removing a dummy gate to expose middle surfaces of the first nanostructure, middle surfaces of the second nanostructure, middle surfaces of the third nanostructure, and middle surfaces of the fourth nanostructure; and forming a first gate structure surrounding the middle surfaces of the first nanostructure, middle surfaces of the second nanostructure, middle surfaces of the third nanostructure, and middle surfaces of the fourth nanostructure. In some embodiments, the method further includes: prior to forming the first gate structure, forming a protection structure surrounding the fourth nanostructure; after forming the first gate structure, forming a recess in the first gate structure, the recess exposing the protection structure, the third nanostructure remaining surrounded by the first gate structure; removing the protection structure; and forming a second gate structure in the recess surrounding the fourth nanostructure. In some embodiments of the method, forming the protection structure includes: forming a first liner around the first nanostructure, the second nanostructure, the third nanostructure, and the fourth nanostructure; forming a dummy material surrounding a portion of the first liner which is around the first nanostructure and the second nanostructure; removing a portion of the first liner which is exposed from the dummy material; forming a second liner surrounding the third nanostructure and the fourth nanostructure; masking the second liner that surrounds the fourth nanostructure with a mask; removing the second liner from the third nanostructure; removing the mask and the dummy material; and removing the portion of the first liner which is around the first nanostructure and the second nanostructure, where the protection structure includes the second liner that surrounds the fourth nanostructure.

In an embodiment, a structure includes: a first semiconductor nanostructure; a second semiconductor nanostructure; a first isolation structure interposed between the first semiconductor nanostructure and the second semiconductor nanostructure; a first source/drain region extending laterally from an end of the first semiconductor nanostructure, the first source/drain region having a first conductivity type; a second source/drain region extending laterally from an end of the second semiconductor nanostructure, the second source/drain region having the first conductivity type, the second source/drain region aligned vertically with the first source/drain region; and a first gate structure surrounding the first semiconductor nanostructure and the second semiconductor nanostructure. In some embodiments of the structure, the first gate structure includes a first region surrounding the first semiconductor nanostructure and a second region surrounding the second semiconductor nanostructure, the first region and the second region each including a work function configured for the first conductivity type. In some embodiments, the structure further includes: a third semiconductor nanostructure; a fourth semiconductor nanostructure; a second isolation structure interposed between the third semiconductor nanostructure and the fourth semiconductor nanostructure; a third source/drain region extending laterally from an end of the third semiconductor nanostructure, the third source/drain region having the first conductivity type; a fourth source/drain region extending laterally from an end of the fourth semiconductor nanostructure, the fourth source/drain region having a second conductivity type opposite the first conductivity type, the fourth source/drain region aligned vertically with the third source/drain region; and a second gate structure surrounding the third semiconductor nanostructure and the fourth semiconductor nanostructure, where the second gate structure includes a third region surrounding the third semiconductor nanostructure and a fourth region surrounding the fourth semiconductor nanostructure, the third region including a work function configured for the first conductivity type, the fourth region including a work function configured for the second conductivity type. In some embodiments, the structure further includes: a third semiconductor nanostructure interposed between the first semiconductor nanostructure and the first isolation structure, the third semiconductor nanostructure having a same material composition as the first semiconductor nanostructure; and a second isolation structure interposed between the first source/drain region and the second source/drain region, where an end of the third semiconductor nanostructure abuts the second isolation structure. In some embodiments, the structure further includes: a second isolation structure interposed between the second source/drain region and the first source/drain region, the second isolation structure including a liner disposed directly under and contacting a bottom surface of the second source/drain region.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming a fin extending vertically from a substrate, the fin including a lower semiconductor nanostructure, an upper semiconductor nanostructure, and a dummy semiconductor nanostructure disposed between the lower semiconductor nanostructure and the upper semiconductor nanostructure;
etching a first recess and a second recess in the fin through the upper semiconductor nanostructure, the dummy semiconductor nanostructure, and the lower semiconductor nanostructure, the etching forming first sidewalls of the upper semiconductor nanostructure in the first recess and second sidewalls of the lower semiconductor nanostructure in the first recess, the etching forming third sidewalls of the upper semiconductor nanostructure in the second recess and fourth sidewalls of the lower semiconductor nanostructure in the second recess;
replacing the dummy semiconductor nanostructure with a first isolation structure;
growing a first lower semiconductor structure from the second sidewalls and a second lower semiconductor structure from the fourth sidewalls, the first lower semiconductor structure and second lower semiconductor structure having a first conductivity type; and
growing a first upper semiconductor structure from the first sidewalls and a second upper semiconductor structure from the third sidewalls, the first upper semiconductor structure having a second conductivity type opposite the first conductivity type, the second upper semiconductor structure having the first conductivity type.

2. The method of claim 1 wherein growing the first lower semiconductor structure, the second lower semiconductor structure, and the second upper semiconductor structure occur at the same time.

3. The method of claim 1, further comprising:
forming the first upper semiconductor structure prior to forming the second upper semiconductor structure.

4. The method of claim 1, further comprising:
blocking the third sidewalls while growing the first upper semiconductor structure from the first sidewalls.

5. The method of claim 1, further comprising:
blocking the first sidewalls while growing the first lower semiconductor structure, the growing of the second lower semiconductor structure and the second upper semiconductor structure occurring at the same time.

6. The method of claim 1, further comprising:
removing a dummy gate that surrounds the upper semiconductor nanostructure and the lower semiconductor nanostructure;
forming a gate dielectric surrounding the upper semiconductor nanostructure and the lower semiconductor nanostructure;
forming a protection structure around the upper semiconductor nanostructure;
depositing a first gate structure surrounding the lower semiconductor nanostructure and the protection structure;
recessing the first gate structure to expose the protection structure;
removing the protection structure; and
depositing a second gate structure surrounding the upper semiconductor nanostructure.

7. The method of claim 6, further comprising:
masking a portion of the first gate structure prior to recessing the first gate structure, wherein the recessing of the first gate structure recesses an unmasked portion of the first gate structure; and
depositing the second gate structure so that it is both vertically over the first gate structure and horizontally adjacent the first gate structure.

8. A method comprising:
etching a first recess and a second recess in a fin-shaped multilayer semiconductor stack, each of the first recess and second recess segmenting the fin-shaped multilayer semiconductor stack into a plurality of nanostructures;
growing a first source/drain region in the first recess from an exposed end of a first nanostructure of the plurality of nanostructures, the first source/drain region having a first conductivity type;
growing a second source/drain region in the second recess from an exposed end of a second nanostructure of the plurality of nanostructures, the second source/drain region having the first conductivity type;
growing a third source/drain region in the first recess from an exposed end of a third nanostructure of the plurality of nanostructures, the third source/drain region having the first conductivity type, the third source/drain region disposed directly over the first source/drain region; and
growing a fourth source/drain region in the second recess from an exposed end of a fourth nanostructure of the plurality of nanostructures, the fourth source/drain region having a second conductivity type opposite the first conductivity type, the fourth source/drain region disposed directly over the second source/drain region.

9. The method of claim 8, wherein growing the first source/drain region and the second source/drain region occurs simultaneously.

10. The method of claim 9, further comprising:
after growing the first source/drain region, forming a first isolation structure over the first source/drain region;
after forming the first isolation structure, blocking the third nanostructure, and growing the fourth source/drain region; and
after growing the fourth source/drain region, blocking the fourth source/drain region, and growing the third source/drain region.

11. The method of claim 8, wherein growing the first source/drain region, the second source/drain region, and the third source/drain region occurs simultaneously.

12. The method of claim 11, further comprising:
after growing the first source/drain region, forming a first isolation structure over the first source/drain region, the second source/drain region, and the third source/drain region, the first isolation structure including a liner layer surrounding the third source/drain region, including a bottom surface of the third source/drain region, the first isolation structure covering the fourth nanostructure;
recessing the first isolation structure to expose ends of the fourth nanostructure, a portion of the liner layer remaining disposed beneath the third source/drain region;
growing the fourth source/drain region; and
forming a second isolation structure over the third source/drain region and the fourth source/drain region, the portion of the liner layer remaining disposed beneath the third source/drain region.

13. The method of claim 8, further comprising:
removing a dummy gate to expose middle surfaces of the first nanostructure, middle surfaces of the second nanostructure, middle surfaces of the third nanostructure, and middle surfaces of the fourth nanostructure; and
forming a first gate structure surrounding the middle surfaces of the first nanostructure, middle surfaces of the second nanostructure, middle surfaces of the third nanostructure, and middle surfaces of the fourth nanostructure.

14. The method of claim 13, further comprising:
prior to forming the first gate structure, forming a protection structure surrounding the fourth nanostructure;
after forming the first gate structure, forming a recess in the first gate structure, the recess exposing the protection structure, the third nanostructure remaining surrounded by the first gate structure;
removing the protection structure; and
forming a second gate structure in the recess surrounding the fourth nanostructure.

15. The method of claim 14, wherein forming the protection structure comprises:
forming a first liner around the first nanostructure, the second nanostructure, the third nanostructure, and the fourth nanostructure;
forming a dummy material surrounding a portion of the first liner which is around the first nanostructure and the second nanostructure;
removing a portion of the first liner which is exposed from the dummy material;
forming a second liner surrounding the third nanostructure and the fourth nanostructure;
masking the second liner that surrounds the fourth nanostructure with a mask;
removing the second liner from the third nanostructure;
removing the mask and the dummy material; and
removing the portion of the first liner which is around the first nanostructure and the second nanostructure, wherein the protection structure comprises the second liner that surrounds the fourth nanostructure.

16. A structure comprising:
a first semiconductor nanostructure;
a second semiconductor nanostructure;
a first isolation structure interposed between the first semiconductor nanostructure and the second semiconductor nanostructure;
a first source/drain region extending laterally from an end of the first semiconductor nanostructure, the first source/drain region having a first conductivity type;
a second source/drain region extending laterally from an end of the second semiconductor nanostructure, the second source/drain region having the first conductivity type, the second source/drain region aligned vertically with the first source/drain region; and
a first gate structure surrounding the first semiconductor nanostructure and the second semiconductor nanostructure.

17. The structure of claim 16, wherein the first gate structure comprises a first region surrounding the first semiconductor nanostructure and a second region surrounding the second semiconductor nanostructure, the first region and the second region each including a work function configured for the first conductivity type.

18. The structure of claim 16, further comprising:
a third semiconductor nanostructure;
a fourth semiconductor nanostructure;
a second isolation structure interposed between the third semiconductor nanostructure and the fourth semiconductor nanostructure;
a third source/drain region extending laterally from an end of the third semiconductor nanostructure, the third source/drain region having the first conductivity type;
a fourth source/drain region extending laterally from an end of the fourth semiconductor nanostructure, the fourth source/drain region having a second conductivity type opposite the first conductivity type, the fourth source/drain region aligned vertically with the third source/drain region; and
a second gate structure surrounding the third semiconductor nanostructure and the fourth semiconductor nanostructure, wherein the second gate structure comprises a third region surrounding the third semiconductor nanostructure and a fourth region surrounding the fourth semiconductor nanostructure, the third region including a work function configured for the first conductivity type, the fourth region including a work function configured for the second conductivity type.

19. The structure of claim 16, further comprising:
a third semiconductor nanostructure interposed between the first semiconductor nanostructure and the first isolation structure, the third semiconductor nanostructure having a same material composition as the first semiconductor nanostructure; and
a second isolation structure interposed between the first source/drain region and the second source/drain region, wherein an end of the third semiconductor nanostructure abuts the second isolation structure.

20. The structure of claim 16, further comprising:
a second isolation structure interposed between the second source/drain region and the first source/drain region, the second isolation structure comprising a liner disposed directly under and contacting a bottom surface of the second source/drain region.
